(19) United States
(12) Patent Application Publication
(10) Pub. No.: US 2026/0162617 A1
(43) Pub. Date: Jun. 11, 2026

(54) Display Substrate and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Yuanjie XU, Beijing (CN); Taofeng XIE, Beijing (CN); Haodi LIU, Beijing (CN)

(21) Appl. No.: 18/709,807

(22) PCT Filed: Mar. 31, 2023
(86) PCT No.: PCT/CN2023/085346

§ 371 Date: May 13, 2024

(51) Int. Cl. G09G 3/3266

(52) U.S. Cl. CPC G09G 3/3266; G09G 2310/0286; G09G 2310/08; G09G 2330/06; G09G 2360/14

(57) ABSTRACT

Disclosed are a display substrate and a display apparatus, the display substrate includes a base substrate (10) and a drive structure layer disposed on the base substrate (10), the base substrate includes a display region (100) and a non-display region (200), the drive structure layer includes multiple pixel circuits located in the display region (100), and a gate drive circuit and an electrostatic release circuit (ER) located in the non-display region (200), the gate drive circuit is configured to provide a drive signal to a pixel circuit, the gate drive circuit includes multiple drive circuits, the multiple drive circuits and the electrostatic release circuit (ER) are arranged along a direction close to the display region (100); the electrostatic release circuit (ER) is disposed between two adjacent drive circuits and is electrically connected with at least one signal line of any one of the two adjacent drive circuits.

### CROSS-REFERENCE TO RELATED APPLICATION

The present application is a U.S. National Phase Entry of International Application No. PCT/CN2023/085346 having an international filing date of Mar. 31, 2023, contents of which should be regarded as being incorporated herein by reference.

### TECHNICAL FIELD

The present disclosure relates to, but is not limited to, the field of display technologies, in particular to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. The summary is not intended to limit the protection scope of claims.

In a first aspect, the present disclosure provides a display substrate, including a base substrate and a drive structure layer disposed on the base substrate, wherein the base substrate includes a display region and a non-display region, the drive structure layer includes a plurality of pixel circuits located in the display region, and a gate drive circuit and an electrostatic release circuit located in the non-display region, the gate drive circuit is configured to provide a drive signal to a pixel circuit, the gate drive circuit includes a plurality of drive circuits, and the plurality of drive circuits and the electrostatic release circuit are arranged along a direction close to the display region; the electrostatic release circuit is disposed between two adjacent drive circuits and is electrically connected with at least one signal line of any one of the two adjacent drive circuits.

In an exemplary implementation mode, the electrostatic release circuit includes at least a first release transistor and a second release transistor; a gate electrode and a second electrode of the first release transistor are connected with a first signal terminal, and a first electrode of the first release transistor is connected with a second signal terminal; a gate electrode and a first electrode of the second release transistor are connected with a third signal terminal, and a second electrode of the second release transistor is connected with the first signal terminal.

In an exemplary implementation mode, the plurality of drive circuits include: a light emitting drive circuit and a scan drive circuit, wherein the scan drive circuit is located at a side of the light emitting drive circuit close to the display region; the drive structure layer further includes: a light emitting initial signal line, a first light emitting clock signal line, a second light emitting clock signal line, a first light emitting power supply line, a second light emitting power supply line, a scan initial signal line, a first scan clock signal line, a second scan clock signal line, a first scan power supply line, and a second scan power supply line located in the non-display region; any one of the light emitting initial signal line, the first light emitting clock signal line, the second light emitting clock signal line, the first light emitting power supply line, the second light emitting power supply line, the scan initial signal line, the first scan clock signal line, the second scan clock signal line, the first scan power supply line, and the second scan power supply line extending along a first direction; the light emitting drive circuit is electrically connected with the light emitting initial signal line, the first light emitting clock signal line, the second light emitting clock signal line, the first light emitting power supply line, and the second light emitting power supply line, respectively; the scan drive circuit is electrically connected with the scan initial signal line, the second scan clock signal line, the first scan clock signal line, the first scan power supply line, and the second scan power supply line, respectively; the light emitting initial signal line, the first light emitting clock signal line, the second light emitting clock signal line, the first light emitting power supply line, the second light emitting power supply line, the first scan power supply line, the first scan clock signal line, the second scan clock signal line, the scan initial signal line, and the second scan power supply line are sequentially arranged along a direction close to the display region.

In an exemplary implementation mode, an orthographic projection of the electrostatic release circuit on the base substrate is partially overlapped with the first scan power supply line and the second light emitting power supply line, and at least a portion of the electrostatic release circuit is located between the second light emitting power supply line and the first scan power supply line.

In an exemplary implementation mode, the drive structure layer further includes: a light emitting output signal line and a scan output signal line located in the non-display region, and a light emitting signal line and a scan signal line at least partially located in the display region; any one of the scan output signal line, the light emitting signal line, and the scan signal line at least partially extends along a second direction, the first direction intersecting with the second direction; the pixel circuit is respectively connected with the light emitting signal line and the scan signal line; the light emitting drive circuit includes a plurality of cascaded light emitting shift registers, and the scan drive circuit includes a plurality of cascaded scan shift registers; the light emitting output signal line is electrically connected with a light emitting shift register and at least one light emitting signal line, respectively; the scan output signal line is electrically connected with a scan shift register and the scan signal line respectively.

In an exemplary implementation mode, a first signal terminal of the electrostatic release circuit is electrically connected with the light emitting output signal line, a second signal terminal of the electrostatic release circuit is electrically connected with the second light emitting power supply line, and a third signal terminal of the electrostatic release circuit is electrically connected with the first scan power supply line.

In an exemplary implementation mode, a distance between the second light emitting power supply line and the first scan power supply line is about 8 microns to 15 microns.

In an exemplary implementation mode, the light emitting shift register includes a plurality of light emitting transistors and a plurality of light emitting capacitors, the scan shift register includes a plurality of scan transistors and a plurality of scan capacitors, the light emitting capacitors and the scan capacitors each includes a first electrode plate and a second electrode plate, the drive structure layer includes a semiconductor layer, a first conductive layer, a second conductive layer, a third conductive layer, and a fourth conductive layer sequentially stacked, the first scan clock signal line includes a first sub-clock signal line and a second sub-clock signal line electrically connected with each other, the second scan clock signal line includes a third sub-clock signal line and a fourth sub-clock signal line electrically connected with each other; the semiconductor layer at least includes: active layers of the plurality of light emitting transistors, active layers of the plurality of scan transistors, an active layer of the first release transistor, and an active layer of the second release transistor; the first conductive layer at least includes: a light emitting signal line, a scan signal line, gate electrodes of the plurality of light emitting transistors, first electrode plates of the plurality of light emitting capacitors, gate electrodes of the plurality of scan transistors, first electrode plates of the plurality of scan capacitors, a gate electrode of the first release transistor, and a gate electrode of the second release transistor; the second conductive layer at least includes: second electrode plates of the plurality of light emitting capacitors, second electrode plates of the plurality of scan capacitors, the scan output signal line, and the light emitting output signal line; the third conductive layer at least includes: the light emitting initial signal line, the first light emitting clock signal line, the second light emitting clock signal line, the first light emitting power supply line, the second light emitting power supply line, the scan initial signal line, the first sub-clock signal line of the first scan clock signal line, the third sub-clock signal line of the second scan clock signal line, the first scan power supply line, the second scan power supply line, first electrodes and second electrodes of the plurality of light emitting transistors, first electrodes and second electrodes of the plurality of scan transistors, the first electrode and the second electrode of the first release transistor, and the first electrode and the second electrode of the second release transistor; the fourth conductive layer includes at least the second sub-clock signal line of the first scan clock signal line and the fourth sub-clock signal line of the second scan clock signal line.

In an exemplary implementation mode, the first electrodes and second electrodes of the plurality of light emitting transistors are located between the first light emitting power supply line and the second light emitting power supply line, the first electrode and the second electrode of the first release transistor to the first electrode and the second electrode of the second release transistor are located between the second light emitting power supply line and the first scan power supply line, first electrodes and second electrodes of one portion of the scan transistors are located between the scan initial signal line and the second scan power supply line, and first electrodes and second electrodes of the other portion of the scan transistors may be located at a side of the second scan power supply line close to the display region.

In an exemplary implementation mode, at least one light emitting output signal line includes an output connection portion extending along the first direction and at least one output line arranged along the first direction; the output connection portion is respectively electrically connected with the light emitting shift register and at least one output line, and the output line is in one-to-one correspondence with a light emitting signal line connected with the light emitting output signal line, and is electrically connected with the corresponding light emitting signal line.

In an exemplary implementation mode, the output line includes an output main body portion extending at least partially along the second direction and an output connection portion extending along the first direction, the output main body portion is electrically connected with the output connection portion; the second electrode of the first release transistor and the second electrode of the second release transistor are of an integral structure, and an orthographic projection thereof on the base substrate is at least partially overlapped with an orthographic projection of the output connection portion on the base substrate; the integral structure of the second electrode of the first release transistor and the second electrode of the second release transistor is electrically connected with the output connection portion.

In an exemplary implementation mode, the active layer of the first release transistor and the active layer of the second release transistor are of an integral structure and extend along the second direction; the orthographic projection of the output connection portion on the base substrate is not overlapped with an orthographic projection of the integral structure of the active layer of the first release transistor and the active layer of the second release transistor on the base substrate.

In an exemplary implementation mode, the active layer of the first release transistor and the active layer of the second release transistor are of an integral structure, and include an active main body portion and an active connection portion, the active main body portion and the active connection portion are electrically connected, and the active main body portion and the active connection portion are arranged along the first direction; the active main body portion extends along the second direction, and the active connection portion at least partially extends along the first direction; the active connection portion is in a shape of a polyline.

In an exemplary implementation mode, the output line at least partially extends along the second direction; the second electrode of the first release transistor and the second electrode of the second release transistor are of an integral structure; an orthographic projection of the active connection portion on the base substrate is at least partially overlapped with orthographic projections of the integral structure of the second electrode of the first release transistor and the second electrode of the second release transistor and the output line on the base substrate, and the active connection portion is electrically connected with the integral structure of the second electrode of the first release transistor and the second electrode of the second release transistor and the output line, respectively.

In an exemplary implementation mode, a width of the active connection portion is smaller than a width of the active main body portion.

In an exemplary implementation mode, the scan shift register includes a first scan capacitor, a second electrode plate of the first scan capacitor is electrically connected with the first scan power supply line, and the second electrode plate of the first scan capacitor extends along the second direction; an orthographic projection of the second electrode plate of the first scan capacitor on the base substrate is at least partially overlapped with orthographic projections of the first scan power supply line, the second scan power supply line, the first scan clock signal line, the second scan clock signal line, and the scan initial signal line on the base substrate.

In an exemplary implementation mode, the display region includes a first display region and a second display region located on at least one side of the first display region, wherein the display substrate further includes a light emitting device and an anode connection line located in the display region, a pixel circuit is electrically connected with the light emitting device; the pixel circuit includes: a first pixel circuit and a second pixel circuit located in the second display region, the light emitting device includes: a first light emitting device located in the first display region and a second light emitting device located in the second display region, the first pixel circuit is electrically connected with the first light emitting device, and the second pixel circuit is electrically connected with the second light emitting device; an orthographic projection of the first pixel circuit on the base substrate is at least partially overlapped with an orthographic projection of the first light emitting device with which the first pixel circuit is connected on the base substrate; the anode connection line is electrically connected with the second light emitting device and the second pixel circuit with which the second light emitting device is connected, respectively.

In an exemplary implementation mode, the drive structure layer further includes: a first power supply line, a data signal line, and a data connection line at least partially located in the display region; the first power supply line and the data signal line at least partially extend along a first direction, and the data connection line at least partially extends along a second direction; the drive structure layer further includes: a fourth conductive layer and a fifth conductive layer stacked on a third conductive layer sequentially; the third conductive layer at least includes: the data connection line; the fourth conductive layer at least includes: the first power supply line and the data signal line; the fifth conductive layer at least includes: the anode connection line; the fifth conductive layer is a transparent conductive layer.

In an exemplary implementation mode, the drive structure layer further includes a planarization layer located between the third conductive layer and the fourth conductive layer, the planarization layer is provided with a groove; an orthographic projection of the electrostatic release circuit on the base substrate is at least partially overlapped with an orthographic projection of the groove on the base substrate.

In an exemplary implementation mode, the drive structure layer further includes at least one initial power supply line located in the non-display region and at least one initial signal line at least partially located in the display region; the initial power supply line is located at a side of a scan drive circuit close to the display region, the initial power supply line at least partially extends along the first direction, and the initial signal line at least partially extends along the second direction; the initial power supply line includes a first sub-initial power supply line and a second sub-initial power supply line electrically connected with each other; the at least one initial signal line is in one-to-one correspondence with the at least one initial power supply line, and the initial signal line is electrically connected with the pixel circuit and the corresponding initial power supply line, respectively; the second conductive layer at least includes: the initial signal line; the third conductive layer at least includes: the first sub-initial power supply line of the initial power supply line; the fourth conductive layer at least includes: the second sub-initial power supply line of the initial power supply line.

In a second aspect, the present disclosure also provides a display apparatus, including: the above-mentioned display substrate and a photosensitive sensor, wherein the photosensitive sensor is located in the display substrate.

Other aspects may be comprehended after drawings and detailed description are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display substrate.

FIG. 2 is another schematic diagram of a display substrate.

FIG. 3A is an equivalent circuit diagram of a pixel circuit.

FIG. 3B is a working timing diagram of the pixel circuit provided in FIG. 3A.

FIG. 4 is a schematic diagram of a structure of a display substrate.

FIG. 5A is a partial schematic view of a display substrate according to an embodiment of the present disclosure.

FIG. 5B is a cross-sectional view taken along an A-A direction in the display substrate provided in FIG. 5A.

FIG. 6A is another partial schematic view of a display substrate according to an embodiment of the present disclosure.

FIG. 6B is a cross-sectional view taken along an A-A direction in the display substrate provided by FIG. 6A.

FIG. 7A is a schematic diagram of a structure of a pixel circuit.

FIG. 7B is a schematic diagram of a structure of another pixel circuit.

FIG. 7C is a schematic diagram of a structure of yet another pixel circuit.

FIG. 8 is an equivalent circuit diagram of an electrostatic release circuit.

FIG. 9A is an equivalent circuit diagram of a scan shift register.

FIG. 9B is a timing diagram of the scan shift register provided in FIG. 9A.

FIG. 10A is an equivalent circuit diagram of a light emitting shift register.

FIG. 10B is a timing diagram of the light emitting shift register provided in FIG. 10A.

FIG. 11 is a schematic diagram of structures of a semiconductor layer and a second conductive layer in FIG. 5A.

FIG. 12 is a schematic diagram of structures of a semiconductor layer and a second conductive layer in FIG. 6A.

FIG. 13 is a schematic diagram of another structure of a display substrate.

FIG. 14 is a schematic diagram after a pattern of a semiconductor layer is formed in FIG. 5A.

FIG. 15 is a schematic diagram after a pattern of a semiconductor layer is formed in FIG. 6A.

FIG. 16 is a schematic diagram of a pattern of a first conductive layer in FIG. 5A and FIG. 6A.

FIG. 17 is a schematic diagram after the pattern of the first conductive layer is formed in FIG. 5A.

FIG. 18 is a schematic diagram after the pattern of the first conductive layer is formed in FIG. 6A.

FIG. 19 is a schematic diagram after a pattern of a second insulation layer is formed in FIG. 6A.

FIG. 20 is a schematic diagram of a pattern of a second conductive layer in FIG. 5A.

FIG. 21 is a schematic diagram after the pattern of the second conductive layer is formed in FIG. 5A.

FIG. 22 is a schematic diagram of a pattern of a second conductive layer in FIG. 6A.

FIG. 23 is a schematic diagram after the pattern of the second conductive layer is formed in FIG. 6A.

FIG. 24 is a schematic diagram after a pattern of a third insulation layer is formed in FIG. 5A.

FIG. 25 is a schematic diagram after a pattern of a third insulation layer is formed in FIG. 6A.

FIG. 26 is a schematic diagram of a pattern of a third conductive layer in FIG. 5A and FIG. 6A.

FIG. 27 is a schematic diagram after the pattern of the third conductive layer is formed in FIG. 5A.

FIG. 28 is a schematic diagram after the pattern of the third conductive layer is formed in FIG. 6A.

FIG. 29 is a schematic diagram after a pattern of a planarization layer is formed in FIG. 5A.

FIG. 30 is a schematic diagram after a pattern of a planarization layer is formed in FIG. 6A.

FIG. 31 is a schematic diagram of a pattern of a fourth conductive layer in FIG. 5A and FIG. 6A.

FIG. 32 is a schematic diagram after the pattern of the fourth conductive layer is formed in FIG. 5A.

FIG. 33 is a schematic diagram after the pattern of the fourth conductive layer is formed in FIG. 6A.

FIG. 34 is a schematic diagram after a pattern of a semiconductor layer is formed in FIG. 7B.

FIG. 35 is a schematic diagram after a pattern of a semiconductor layer is formed in FIG. 7C.

FIG. 36 is a schematic diagram of a pattern of a first conductive layer in FIG. 7B.

FIG. 37 is a schematic diagram after the pattern of the first conductive layer is formed in FIG. 7B.

FIG. 38 is a schematic diagram of a pattern of a first conductive layer in FIG. 7C.

FIG. 39 is a schematic diagram after the pattern of the first conductive layer is formed in FIG. 7C.

FIG. 40 is a schematic diagram of a pattern of a second conductive layer in FIG. 7B.

FIG. 41 is a schematic diagram after the pattern of the second conductive layer is formed in FIG. 7B.

FIG. 42 is a schematic diagram of a pattern of a second conductive layer in FIG. 7C.

FIG. 43 is a schematic diagram after the pattern of the second conductive layer is formed in FIG. 7C.

FIG. 44 is a schematic diagram after a pattern of a third insulation layer is formed in FIG. 7B.

FIG. 45 is a schematic diagram after a pattern of a third insulation layer is formed in FIG. 7C.

FIG. 46 is a schematic diagram of a pattern of a third conductive layer in FIG. 7B.

FIG. 47 is a schematic diagram after the pattern of the third conductive layer is formed in FIG. 7B.

FIG. 48 is a schematic diagram of a pattern of a third conductive layer in FIG. 7C.

FIG. 49 is a schematic diagram after the pattern of the third conductive layer is formed in FIG. 7C.

FIG. 50 is a schematic diagram after a pattern of a fourth insulation layer is formed in FIG. 7B.

FIG. 51 is a schematic diagram after the pattern of the fourth insulation layer is formed in FIG. 7C.

FIG. 52 is a schematic diagram of a pattern of a fourth conductive layer in FIG. 7B.

FIG. 53 is a schematic diagram after the pattern of the fourth conductive layer is formed in FIG. 7B.

FIG. 54 is a schematic diagram of a pattern of a fourth conductive layer in FIG. 7C.

FIG. 55 is a schematic diagram after the pattern of the fourth conductive layer is formed in FIG. 7C.

### DETAILED DESCRIPTION

To make the objectives, the technical solutions, and advantages of the present disclosure clearer, the embodiments of the present disclosure will be described in detail below in combination with the accompany drawings. It is to be noted that implementation modes may be implemented in multiple different forms. Those of ordinary skills in the art may easily understand such a fact that modes and contents may be transformed into various forms without departing from the purpose and scope of the present disclosure. Therefore, the present disclosure should not be explained as being limited to contents recorded in following implementation modes only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings of the embodiments of the present disclosure only involve structures involved in the embodiments of the present disclosure, and for other structures, reference may be made to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the constituent elements, not to indicate or imply that a referred apparatus or element must have a specific orientation and be structured and operated with the specific orientation but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a connection of constituent elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “disposed in a same layer” refers to a structure formed by patterning two (or more than two) structures through a same patterning process, and their materials may be the same or different. For example, materials of precursors for forming multiple structures disposed in a same layer are the same, and materials finally formed may be the same or different.

In the present disclosure, “about” refers to that a boundary is not defined so strictly and numerical values within a range of process and measurement errors are allowed.

A display substrate has advantages of a high resolution, a high reaction speed, high brightness, and a high aperture ratio, etc., and has a wide application prospect. A drive circuit is disposed in the display substrate to drive a pixel circuit to emit light, thereby achieving display. The display substrate is generally in a shape of a rounded rectangle, and four corners of the rounded rectangle are referred to as rounded regions. Drive circuits are placed in a rounded region in accordance with an arc trend of the rounded regions, which will result in some blank regions between the drive circuits. If a blank region is too large, etching will be uneven, which will affect stability of transmission of an output signal of a drive circuit and affect a display effect adversely.

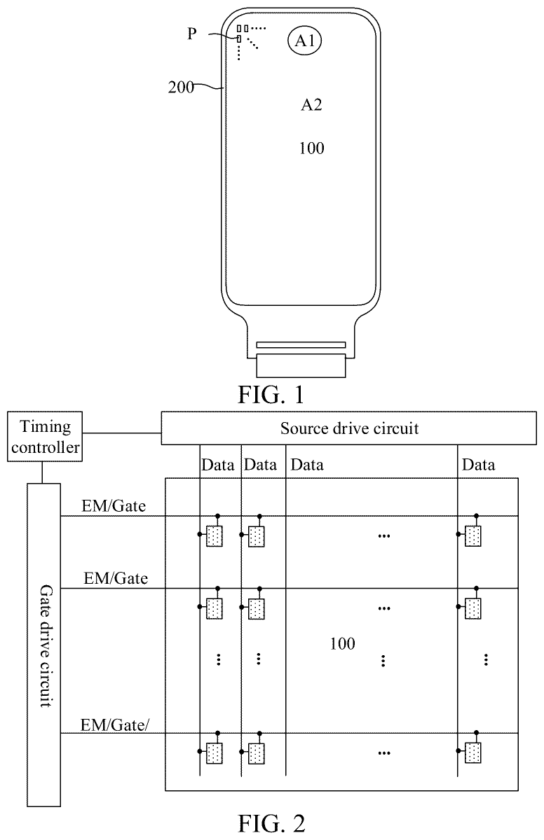

FIG. 1 is a schematic diagram of a structure of a display substrate, and FIG. 2 is another schematic diagram of a display substrate. As shown in FIGS. 1 and 2, the display substrate may include a display region 100 and a non-display region 200. The display region 100 of the display substrate may include a first display region A1 and a second display region A2 located on at least one side of the first display region A1. In some examples, the first display region A1 is a light-transmitting display region, and the first display region A1 may also be referred to as an Under Display Camera (UDC) region. The second display region A2 is a non-light-transmitting display region, and the second display region A2 may also be referred to as a normal display region. For example, an orthographic projection of hardware such as a photosensitive sensor (such as a camera and an infrared sensor) on the display substrate may be located in the first display region A1 of the display substrate.

In an exemplary implementation mode, as shown in FIG. 1, the first display region A1 may be circular, and a size of an orthographic projection of the photosensitive sensor on the display substrate may be smaller than or equal to a size of the first display region A1. However, the embodiment is not limited thereto. In some other examples, the first display region A1 may be rectangular, and the size of the orthographic projection of the photosensitive sensor on the display substrate may be less than or equal to a size of an inscribed circle of the first display region.

In an exemplary implementation mode, as shown in FIG. 1, the first display region A1 may be located at a center position of top of the display region 100. The second display region A2 may surround a periphery of the first display region A1. However, the embodiment is not limited thereto. For example, the first display region A1 may be located at another position such as an upper left corner or an upper right corner of the display region 100.

In some exemplary implementation, as shown in FIG. 1, the display region may be a rectangle, e.g., a rounded rectangle. The first display region A1 may be circular or elliptical. However, the embodiment is not limited thereto. For example, the first display region may be rectangular, pentagonal, hexagonal or in another shape. The display substrate according to the present disclosure may achieve a function of bending four sides at a large angle, thus improving a wrinkling problem of module attaching and improving a yield of products.

In an exemplary implementation mode, as shown in FIGS. 1 and 2, the display region may include pixel units arranged in an array, at least one pixel unit includes at least three sub-pixels P, and at least one sub-pixel includes a pixel circuit and a light emitting device. A pixel circuit located in a same sub-pixel is electrically connected with a light emitting device and is configured to drive the light emitting device to emit light.

In an exemplary implementation mode, the pixel unit may include a red (R) sub-pixel, a green (G) sub-pixel, and a blue (B) sub-pixel, or may include a red sub-pixel, a green sub-pixel, a blue sub-pixel, and a white sub-pixel, which is not limited in the present disclosure.

In an exemplary implementation mode, a shape of a sub-pixel in a pixel unit may be a rectangle, a rhombus, a pentagon, or a hexagon. When the pixel unit includes three sub-pixels, the three sub-pixels may be arranged side by side horizontally, side by side vertically, or in a manner like a Chinese character “fin”. When the pixel unit includes four sub-pixels, the four sub-pixels may be arranged side by side horizontally, side by side vertically, or in a manner to form a square, which is not limited in the present disclosure.

In an exemplary implementation mode, the light emitting device may be an Organic Light Emitting Diode (OLED) or a Quantum dot Light Emitting Diode (QLED). Among them, the OLED may include a first electrode (anode), an organic emitting layer, and a second electrode (cathode) that are stacked.

In an exemplary implementation mode, the organic emitting layer may include a Hole Injection Layer (HIL), a Hole Transport Layer (HTL), an Electron Block Layer (EBL), an Emitting Layer (EML), a Hole Block Layer (HBL), an Electron Transport Layer (ETL), and an Electron Injection Layer (EIL) that are stacked. In an exemplary implementation mode, hole injection layers of all sub-pixels may be connected together to be a common layer, electron injection layers of all the sub-pixels may be connected together to be a common layer, hole transport layers of all the sub-pixels may be connected together to be a common layer, electron transport layers of all the sub-pixels may be connected together to be a common layer, hole block layers of all the sub-pixels may be connected together to be a common layer, emitting layers of adjacent sub-pixels may be overlapped slightly or may be isolated, and electron block layers of adjacent sub-pixels may be overlapped slightly or may be isolated.

In an exemplary implementation mode, as shown in FIG. 1, the non-display region 200 may include a bonding region located on a side of the display region 100 and a bezel region located on another side of the display region 100.

In an exemplary implementation mode, the bonding region may include a lead region, a bending region, and a composite circuit region which are disposed sequentially along a direction away from the display region, the lead region is connected to the display region 100, the bending region is connected to the lead region, and the composite circuit region is connected to the bending region.

In an exemplary implementation, the lead region may be provided with a plurality of lead-out lines. Ends of a part of the plurality of lead-out lines are correspondingly connected with a plurality of data fanout lines in the display region 100, and ends of another part of the plurality of lead-out lines are correspondingly connected with a plurality of data lines in the display region 100, and the other ends of the plurality of lead-out lines span the bending region to be connected with an integrated circuit of the composite circuit region, so that the integrated circuit applies data signals to the data lines through the lead-out lines and the data fanout lines.

In an exemplary implementation mode, the bending region may be bent with a curvature, so that a surface of the composite circuit region may be turned over, that is, a surface of the composite circuit region facing upwards may be converted to face downwards through bending of the bending region. In an exemplary implementation mode, when the bending region is bent, the compound circuit region may be overlapped with the display region 100.

In an exemplary implementation mode, the compound circuit region may include an antistatic region, a drive chip region, and a bonding pin region. An Integrated Circuit (IC) may be bonded and connected in the drive chip region, and a Flexible Printed Circuit (FPC) may be bonded and connected in the bonding pin region.

In an exemplary implementation mode, the integrated circuit may generate a drive signal required for driving a sub-pixel, and may provide a drive signal to a sub-pixel in the display region 100. For example, the drive signal may be a data signal that drives luminance of the sub-pixel. In an exemplary implementation mode, the integrated circuit may be bonded and connected in the drive chip region through an anisotropic conductive film or other ways. In an exemplary implementation mode, the bonding pin region may be provided with a bonding pad including multiple pins, and the flexible circuit board may be bonded and connected to the bonding pad.

In an exemplary implementation mode, as shown in FIG. 2, the display substrate may include a timing controller, a data drive circuit, a gate drive circuit, and a pixel array, the timing controller is respectively connected with the data drive circuit and the gate drive circuit, the data drive circuit is connected with a data signal line Data, respectively, and the gate drive circuit is connected with a gate line, the gate line may include one or more of a light emitting signal line EM and a scan signal line Gate. The pixel circuit is connected with the gate line and the data signal line, respectively.

In an exemplary implementation mode, the timing controller may supply a gray-scale value and a control signal suitable for a specification of the data drive circuit to the data drive circuit, may supply a clock signal, a start signal, and the like suitable for a specification of the gate drive circuit to the gate drive circuit, and may supply a clock signal, an emission stop signal, and the like suitable for a specification of the light emitting drive circuit to the light emitting drive circuit. The data drive circuit may generate a data voltage to be provided to a data signal line by using the gray-scale value and the control signal received from the timing controller. For example, the data drive circuit may sample the gray-scale value using a clock signal, and apply a data voltage corresponding to the gray-scale value to the data signal line by taking a pixel row as a unit.

In an exemplary implementation mode, the gate drive circuit may generate a scan signal to be provided to the gate line by receiving a clock signal, a start signal, and the like from the timing controller. For example, the gate drive circuit may sequentially provide a signal with an on-level pulse to gate lines. For example, the gate drive circuit may be constructed in a form of a shift register and may generate a scan signal by sequentially transmitting a start signal provided in a form of an on-level pulse to a next stage circuit under control of the clock signal.

In an exemplary implementation mode, the pixel circuit may have a structure of 3T1C, 4T1C, 5T1C, 5T2C, 6T1C, 7T1C, or 8T1C.

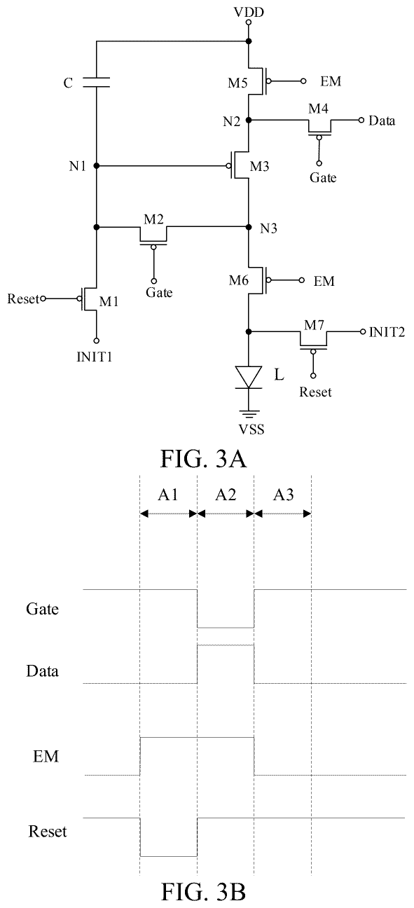

In an exemplary implementation mode, FIG. 3A is an equivalent circuit diagram of a pixel circuit. As shown in FIG. 3A, the pixel circuit may include seven transistors (a first transistor M1 to a seventh transistor M7), one capacitor C, and eight signal lines (a data signal line Data, a scan signal line Gate, a reset signal line Reset, a light emitting signal line EM, a first initial signal line INIT1, a second initial signal line INIT2, a high-level power supply line VDD, and a low-level power supply line VSS).

In an exemplary implementation mode, as shown in FIG. 3A, a first electrode plate of the capacitor C is connected with the high-level power supply line VDD and a second electrode plate of the capacitor C is connected with a first node N1. A gate electrode of the first transistor M1 is connected with the reset signal line Reset, a first electrode of the first transistor M1 is connected with the first initial signal line INIT1, and a second electrode of the first transistor is connected with the first node N1; a gate electrode of the second transistor M2 is connected with the scan signal line Gate, a first electrode of the second transistor M2 is connected with the first node N1, and a second electrode of the second transistor M2 is connected with a second node N2. A gate electrode of the third transistor M3 is connected with the first node N1, a first electrode of the third transistor M3 is connected with the second node N2, and a second electrode of the third transistor M3 is connected with a third node N3. A gate electrode of the fourth transistor M4 is connected with the scan signal line Gate, a first electrode of the fourth transistor M4 is connected with the data signal line Data, and a second electrode of the fourth transistor M4 is connected with the second node N2. A gate electrode of the fifth transistor M5 is connected with the light emitting signal line EM, a first electrode of the fifth transistor M5 is connected with the high-level power supply line VDD, and a second electrode of the fifth transistor M5 is connected with the second node N2; a gate electrode of the sixth transistor M6 is connected with the light emitting signal line EM, a first electrode of the sixth transistor M6 is connected with the third node N3, and a second electrode of the sixth transistor M6 is connected with a first electrode of a light emitting device L. A gate electrode of the seventh transistor M7 is connected with the reset signal line Reset or the scan signal line Gate, a first electrode of the seventh transistor M7 is connected with the second initial signal line INIT2, a second electrode of the seventh transistor M7 is connected with the first electrode of the light emitting device L, and a second electrode of the light emitting device is connected with the low-level power supply line VSS. FIG. 3A is illustrated by taking the gate electrode of the seventh transistor M7 and the reset signal line Reset as an example.

In an exemplary implementation mode, the first transistor M1 may be referred to as a node reset transistor, and when an effective level signal is input to the reset signal line Reset, the first transistor M1 transmits an initialization voltage to the first node N1 to initialize a charge amount of the first node N1.

In an exemplary implementation mode, the second transistor M2 may be referred to as a compensation transistor, and when an effective level signal is input to a control signal line SL, the second transistor M2 transmits a signal of the second node N2 to the first node N1 to compensate a signal of the first node N1.

In an exemplary implementation mode, the third transistor M3 may be referred to as a drive transistor, and the third transistor M3 determines a drive current which flows between the high-level power supply line VDD and the low-level power supply line VSS according to a potential difference between the gate electrode and the first electrode.

In an exemplary implementation mode, the fourth transistor M4 may be referred to as a writing transistor or the like, when an effective level signal is input to the scan signal line Gate, the fourth transistor M4 enables a data voltage of the data signal line Data to be input to the third node N3.

In an exemplary implementation mode, the fifth transistor M5 and the sixth transistor M6 may be referred to as light emitting transistors. When an effective level signal is input to the light emitting signal line EM, the fifth transistor M5 and the sixth transistor M6 enable the light emitting device to emit light by forming a drive current path between the high-level power supply line VDD and the low-level power supply line VSS.

In an exemplary implementation mode, the seventh transistor M7 may be referred to as an anode reset transistor, when an effective level signal is input to the reset signal line Reset or the scan signal line Gate, the seventh transistor M7 transmits an initialization voltage to the first electrode of the light emitting device L to initialize a charge amount of the first electrode of the light emitting device L.

In an exemplary implementation mode, a signal of the high-level power supply line VDD is a high-level signal continuously provided, and a signal of the low-level power supply line VSS is a low-level signal.

Transistors may be divided into N-type transistors and P-type transistors according to their characteristics. When a transistor is a P-type transistor, its turn-on voltage is a low-level voltage (e.g., 0 V, −5 V, −10 V, or another suitable voltage), and its turn-off voltage is a high-level voltage (e.g., 5 V, 10 V, or another suitable voltage). When a transistor is an N-type transistor, its turn-on voltage is a high-level voltage (e.g., 5 V, 10 V, or another suitable voltage), and its turn-off voltage is a low-level voltage (e.g., 0 V, −5 V, −10 V, or another suitable voltage).

In an exemplary implementation mode, the first transistor M1 to the seventh transistor M7 may be P-type transistors, or may be N-type transistors. Adopting a same type of transistors in the pixel circuit may simplify a process flow, reduce process difficulties of a display panel, and improve a yield of products. In some possible implementation modes, the first transistor M1 to the seventh transistor M7 may include a P-type transistor and an N-type transistor.

In an exemplary implementation mode, for the first transistor M1 to the seventh transistor M7, low temperature poly silicon thin film transistors may be used, or oxide thin film transistors may be used, or both a low temperature poly silicon thin film transistor and an oxide thin film transistor may be used. An active layer of a low temperature poly silicon thin film transistor may be made of Low Temperature Poly Silicon (LTPS for short), and an active layer of an oxide thin film transistor may be made of an oxide semiconductor (Oxide). A Low temperature poly silicon thin film transistor has advantages such as a high migration rate and fast charging, and an oxide thin film transistor has advantages such as a low leakage current. The low temperature poly silicon thin film transistor and the oxide thin film transistor are integrated on one display substrate to form a Low Temperature Polycrystalline Oxide (LTPO for short) display substrate, so that advantages of both the low temperature poly silicon thin film transistor and the oxide thin film transistor may be utilized, low-frequency drive may be achieved, power consumption may be decreased, and display quality may be improved.

In an exemplary implementation mode, when the display substrate is an LTPO display substrate, the first transistor T1 and the second transistor T2 may be N-type transistors, and remaining transistors are P-type transistors. When the display substrate is an LTPS display substrate, the first transistor M1 to the seventh transistor M7 are P-type transistors.

FIG. 3B is a working timing diagram of the pixel circuit provided in FIG. 3A. FIG. 3B is illustrated by taking a case that transistors in FIG. 3A are all P-type transistors as an example. An exemplary embodiment of the present disclosure will be described below through a working process of the pixel circuit illustrated in FIG. 3B. In an exemplary implementation mode, the working process of the pixel circuit may include following stages.

In a first stage A1, referred to as a reset stage, signals of the scan signal line Gate and the light emitting signal line EM are both high-level signals, and a signal of the reset signal line Reset is a low-level signal. The signal of the reset signal line Reset is the high-level signal, the first transistor M1 is turned on, a signal of the first initial signal line INIT1 is provided to the first node N1 to initialize the capacitor C and clear an original data voltage in the capacitor C, the seventh transistor M7 is turned on, an initial voltage of the second initial signal line INIT2 is provided to the first electrode of the light emitting device L, to initialize (reset) the first electrode of the light emitting device L and empty a pre-stored voltage therein, and initialization is completed. The signals of the scan signal line Gate and the light emitting signal line EM are high-level signals, the second transistor M2, the fourth transistor M4, the fifth transistor M5, and the sixth transistor M6 are turned off, and the light emitting device L does not emit light in this stage.

In a second stage A2, referred to as a data writing stage or a threshold compensation stage, a signal of the scan signal line Gate is a low-level signal, signals of the light emitting signal line EM and the reset signal line Reset are high-level signals, and the data signal line Data outputs a data voltage. In this stage, since a signal of the first node N1 is a low-level signal, the third transistor M3 is turned on. The signal of the scan signal line Gate is the low-level signal, the second transistor T2 and the fourth transistor M4 are turned on, so that a data voltage output by the data signal line Data is provided to the first node N1 through the second node N2, the turned-on third transistor M3, the second node N3, and the turned-on second transistor M2, and a difference between the data voltage output by the data signal line Data and a threshold voltage of the third transistor M3 is charged into the capacitor C until a voltage of the first node N1 is Vd−|Vth|, Vd is the data voltage output by the data signal line Data, Vth is the threshold voltage of the third transistor M3, ensuring that the light emitting device L does not emit light. A signal of the reset signal line Reset is a high-level signal, and the first transistor M1 is turned off. A signal of the light emitting signal line EM is a high-level signal, and the fifth transistor M5 and the sixth transistor M6 are turned off.

In a third stage A3, referred to as a light emitting stage, signals of the scan signal line Gate and the reset signal line Reset are high-level signals, and a signal of the light emitting signal line EM is a low-level signal. The signal of the light emitting signal line EM is the low-level signal, the fifth transistor M5 and the sixth transistor M6 are turned on, and a power supply voltage output by the high-level power supply line VDD provides a drive voltage to the first electrode of the light emitting device L through the turned-on fifth transistor M5, the third transistor M3, and the sixth transistor M6, to drive the light emitting device L to emit light.

In a drive process of the pixel circuit, a drive current flowing through the third transistor M3 (drive transistor) is determined by a voltage difference between the gate electrode and the first electrode. Since the voltage of the first node N1 is Vd−|Vth|, the drive current of the third transistor M3 is as follows.

$$I = K * {( Vgs - Vth )}^{2} = K * {[ ( Vdd - Vd + \vert Vth \vert ) - Vth ]}^{2} = K * {[ ( Vdd - Vd ]}^{2}$$

Among them, I is the drive current flowing through the third transistor M3, that is, a drive current for driving the light emitting device L, K is a constant, Vgs is the voltage difference between the gate electrode and the first electrode of the third transistor M3, Vth is the threshold voltage of the third transistor M3, Vd is the data voltage output by the data signal line Data, and Vdd is the power supply voltage output by the high-level power supply line VDD.

In an exemplary implementation mode, a base substrate may be a rigid base substrate or a flexible base substrate, wherein the rigid base substrate may be, but is not limited to, one or more of glass and metal foil; the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation mode, the display substrate may be an LTPO display substrate or an LTPS display substrate.

In an exemplary implementation mode, gate drive circuits in the display substrate may be of two, three, or more types, depending on a structure of the display substrate, which is not limited in the present disclosure.

Some metal conductive layers in FDC display products include a plurality of isolated block structures, which makes the metal conductive layers have poor electrostatic conduction ability, and failure to release static electricity will cause some transistors to be burned, thereby affecting a display effect adversely and reducing reliability of the display substrate.

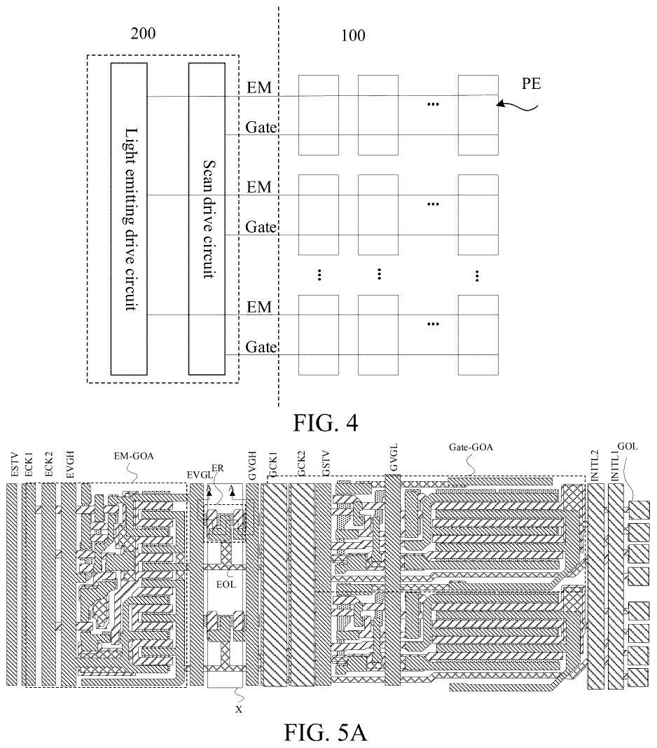

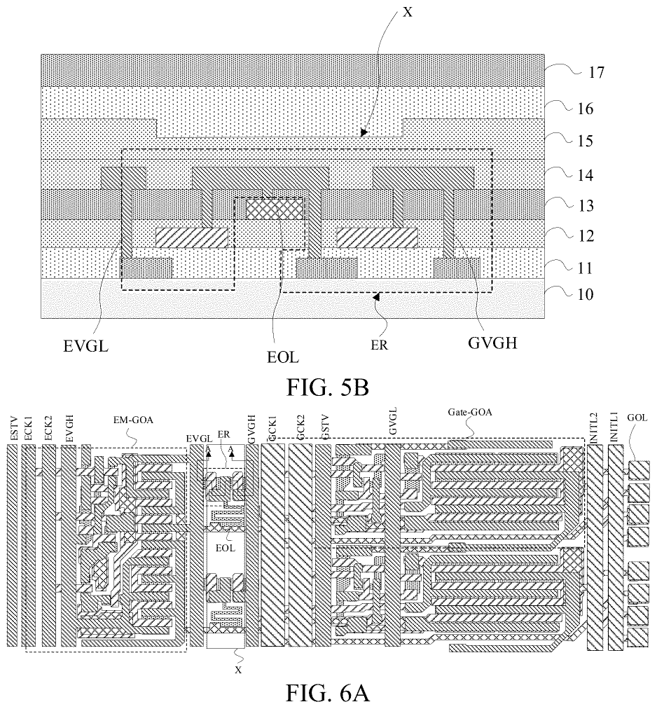

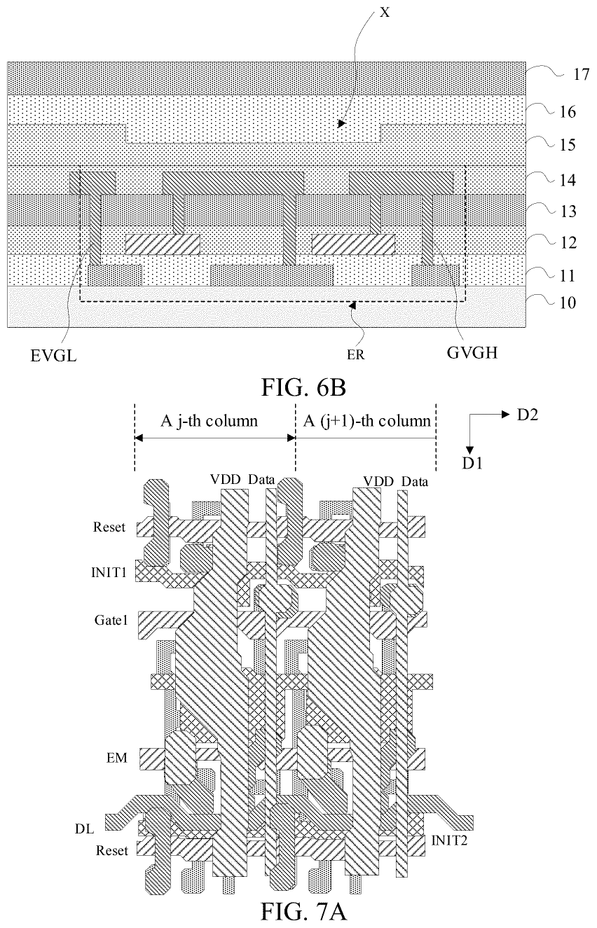

FIG. 4 is a schematic diagram of a structure of a display substrate, FIG. 5A is a partial schematic view of a display substrate according to an embodiment of the present disclosure, FIG. 5B is a cross-sectional view taken along an A-A direction in FIG. 5A, FIG. 6A is another partial schematic view of a display substrate according to an embodiment of the present disclosure, and FIG. 6B is a cross-sectional view taken along an A-A direction in FIG. 6A. As shown in FIGS. 4, 5A, 5B, 6A, and 6B, the display substrate according to the embodiment of the present disclosure may include a base substrate 10 and a drive structure layer disposed on the base substrate 10, the base substrate includes a display region 100 and a non-display region 200, the drive structure layer includes a plurality of pixel circuits located in the display region, and a gate drive circuit and an electrostatic release circuit ER located in the non-display region, the gate drive circuit is configured to provide a drive signal to a pixel circuit, and the gate drive circuit includes a plurality of drive circuits. The plurality of drive circuits and the electrostatic release circuit are arranged along a direction close to the display region. The electrostatic release circuit ER is disposed between two adjacent drive circuits and is electrically connected with at least one signal line of any one of the two adjacent drive circuits.

In an exemplary implementation, the display substrate may further include a light emitting structure layer disposed on a side of the drive structure layer away from the base substrate, and an encapsulation structure layer disposed on a side of the light emitting structure layer away from the base substrate. In some possible implementation modes, the display substrate may include another film layer, such as a touch structure layer, which is not limited here in the present disclosure.

In an exemplary implementation mode, the base substrate may be a flexible base substrate, or a rigid base substrate. The drive structure layer of each sub-pixel may include a plurality of transistors and a storage capacitor constituting the pixel circuit, and the light emitting structure layer may include an anode, a pixel definition layer, an organic emitting layer, and a cathode, the anode is connected with the pixel circuit through a via, the organic emitting layer is connected with the anode, and the cathode is connected with the organic emitting layer, and the organic emitting layer emits light of corresponding color under drive of the anode and the cathode. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting structure layer.

In an exemplary implementation mode, the touch structure layer may include a first touch insulation layer disposed on the encapsulation structure layer, a first touch metal layer disposed on the first touch insulation layer, a second touch insulation layer 43 covering the first touch metal layer, a second touch metal layer disposed on the second touch insulation layer, and a touch protective layer covering the second touch metal layer, the first touch metal layer may include a plurality of bridge electrodes, the second touch metal layer may include a plurality of first touch electrodes and second touch electrodes, and a first touch electrode or second touch electrode may be connected with a bridge electrode through a via.

The present disclosure may release static electricity in the gate drive circuit through the electrostatic release circuit disposed between adjacent drive circuits and electrically connected with the adjacent drive circuits, thereby enhancing the electrostatic conduction ability of the display substrate, and improving the display effect and the reliability of the display substrate.

In an exemplary implementation mode, when the display substrate is an LTPO display substrate, the plurality of drive circuits may include a light emitting drive circuit, a control drive circuit, and a scan drive circuit arranged sequentially along a direction close to the display region. Among them, the control drive circuit is connected with an N-type transistor in the pixel circuit, and the scan drive circuit is connected with a P-type transistor in the pixel circuit. Exemplarily, the electrostatic release circuit may be located between the light emitting drive circuit and the control drive circuit and electrically connected with at least one signal line of any one of the light emitting drive circuit and the control drive circuit, or the electrostatic release circuit may be located between the control drive circuit and the scan drive circuit and electrically connected with at least one signal line of any one of the control drive circuit and the scan drive circuit.

In an exemplary implementation mode, as shown in FIG. 4, when the display substrate is an LTPS display substrate, the plurality of drive circuits may include a light emitting drive circuit and a scan drive circuit, and the scan drive circuit is located at a side of the light emitting drive circuit close to the display region 100.

In an exemplary implementation mode, as shown in FIG. 5A and FIG. 6A, the drive structure layer may further include a light emitting initial signal line ESTV, a first light emitting clock signal line ECK1, a second light emitting clock signal line ECK2, a first light emitting power supply line EVGH, a second light emitting power supply line EVGL, a scan initial signal line GSTV, a first scan clock signal line GCK1, a second scan clock signal line GCK2, a first scan power supply line GVGH, and a second scan power supply line GVGL located in the non-display region.

In an exemplary implementation mode, as shown in FIG. 5A and FIG. 6A, any one of the light emitting initial signal line ESTV, the first light emitting clock signal line ECK1, the second light emitting clock signal line ECK2, the first light emitting power supply line EVGH, the second light emitting power supply line EVGL, the scan initial signal line GSTV, the first scan clock signal line GCK1, the second scan clock signal line GCK2, the first scan power supply line GVGH, and the second scan power supply line GVGL extends along a first direction D1.

In an exemplary implementation mode, as shown in FIG. 5A and FIG. 6A, the light emitting drive circuit may be electrically connected with the light emitting initial signal line ESTV, the first light emitting clock signal line ECK1, the second light emitting clock signal line ECK2, the first light emitting power supply line EVGH, and the second light emitting power supply line EVGL, respectively.

In an exemplary implementation mode, as shown in FIG. 5A and FIG. 6A, the scan drive circuit may be electrically connected with the scan initial signal line GSTV, the second scan clock signal line GCK2, the first scan clock signal line GCK1, the first scan power supply line GVGH, and the second scan power supply line GVGL, respectively.

In an exemplary implementation mode, as shown in FIG. 5A and FIG. 6A, at least one of the first scan clock signal line GCK1 and the second scan clock signal line GCK2 may be of a double-layer structure.

In an exemplary implementation mode, as shown in FIG. 5A and FIG. 6A, the first scan clock signal line may include a first sub-clock signal line and a second sub-clock signal line electrically connected with each other. The first sub-clock signal line and the second sub-clock signal line may be disposed in different layers.

In an exemplary implementation mode, as shown in FIG. 5A and FIG. 6A, the second scan clock signal line may include a third sub-clock signal line and a fourth sub-clock signal line electrically connected with each other. The third sub-clock signal line and the fourth sub-clock signal line may be disposed in different layers.

In an exemplary implementation mode, as shown in FIG. 5A and FIG. 6A, the light emitting initial signal line ESTV, the first light emitting clock signal line ECK1, the second light emitting clock signal line ECK2, the first light emitting power supply line EVGH, the second light emitting power supply line EVGL, the first scan power supply line GVGH, the first scan clock signal line GCK1, the second scan clock signal line GCK2, the scan initial signal line GSTV, and the second scan power supply line GVGL are sequentially arranged along a direction close to the display region.

In an exemplary implementation mode, signals of the first light emitting power supply line EVGH and the first scan power supply line GVGH are high-level signals, and signals of the second light emitting power supply line EVGL and the second scan power supply line GVGL are low-level signals.

In an exemplary implementation mode, as shown in FIG. 5A and FIG. 6A, an orthographic projection of the electrostatic release circuit ER on the base substrate is partially overlapped with the first scan power supply line GVGH and the second light emitting power supply line EVGL, and at least part of the electrostatic release circuit is located between the second light emitting power supply line EVGL and the first scan power supply line GVGH.

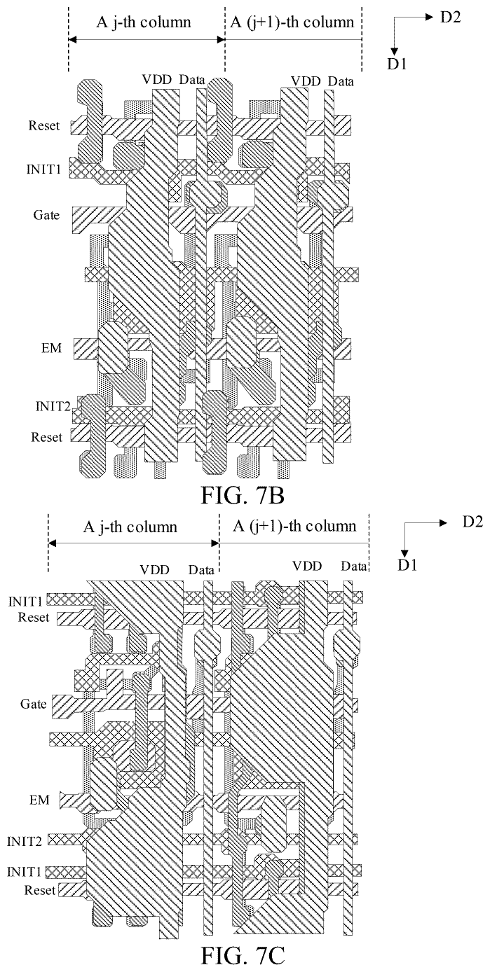

In an exemplary implementation mode, FIG. 7A is a schematic diagram of a structure of a pixel circuit, FIG. 7B is a schematic diagram of another structure of a pixel circuit, and FIG. 7C is a schematic diagram of yet another structure of a pixel circuit. As shown in FIGS. 5A, 6A, and 7A to 7C, the drive structure layer may further include a light emitting output signal line EOL and a scan output signal line GOL located in the non-display region, and a light emitting signal line EM and a scan signal line Gate at least partially located in the display region. Any one of the scan output signal line GOL, the light emitting signal line EM, and the scan signal line Gate extends at least partially along a second direction D2, and the first direction D1 intersects with the second direction D2.

In an exemplary implementation mode, the pixel circuit is connected with the light emitting signal line EM and the scan signal line Gate, respectively.

In an exemplary implementation mode, as shown in FIG. 5A and FIG. 6A, the light emitting drive circuit may include a plurality of cascaded light emitting shift registers EM-GOA, and the scan drive circuit may include a plurality of cascaded scan shift registers Gate-GOA.

In an exemplary implementation mode, the light emitting output signal line EOL is electrically connected with a light emitting shift register EM-GOA and at least one light emitting signal line, respectively. FIG. 5A and FIG. 6A are illustrated by taking a light emitting output signal line and two light emitting signal lines as an example.

In an exemplary implementation mode, the scan output signal line GOL is electrically connected with a scan shift register Gate-GOA and the scan signal line, respectively.

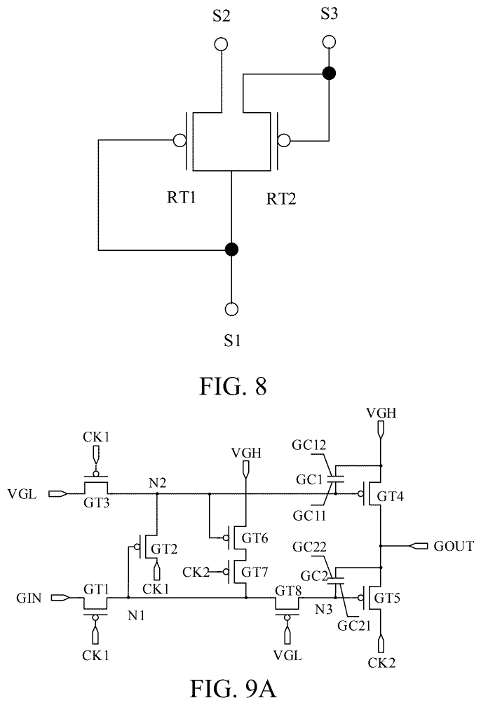

FIG. 8 is an equivalent circuit diagram of an electrostatic release circuit. As shown in FIG. 8, in an exemplary implementation mode, the electrostatic release circuit may at least include a first release transistor R1 and a second release transistor R2. A gate electrode and a second electrode of the first release transistor R1 are connected with a first signal terminal S1, and a first electrode of the first release transistor R1 is connected with a second signal terminal S2; a gate electrode and a first electrode of the second release transistor R2 are connected with a third signal terminal S3, and a second electrode of the second release transistor R2 is connected with the first signal terminal S1.

In an exemplary implementation mode, a signal of the second signal terminal S2 may be a low-level signal, and a signal of the third signal terminal S3 may be a high-level signal.

In an exemplary implementation mode, the first release transistor R1 and the second release transistor R2 may be P-type transistors, or may be N-type transistors. Adopting a same type of transistors in the electrostatic release circuit may simplify a process flow, reduce process difficulties of the display panel, and improve a yield of products. In some possible implementation modes, the first release transistor R1 and the second release transistor R2 may include a P-type transistor and an N-type transistor.

In an exemplary implementation mode, for the first release transistor R1 and the second release transistor R2, low temperature poly silicon thin film transistors may be used, or oxide thin film transistors may be used, or both a low temperature poly silicon thin film transistor and an oxide thin film transistor may be used.

In an exemplary implementation mode, a working principle of the electrostatic release circuit is as follows: when a voltage value of a signal at the first signal terminal S1 is too high (for example, higher than a voltage value of a signal at the third signal terminal S3), the second release transistor R2 is turned on, and at this time, the voltage value of the signal at the first signal terminal S1 will approach the voltage value of the signal at the third signal terminal S3 without being too high. Similarly, when the voltage value of the signal at the first signal terminal S1 is too low (for example, lower than a voltage value of a signal at the second signal terminal S2), at this time, the first release transistor R1 is turned on, and at this time, the voltage value of the signal at the first signal terminal S1 will approach the voltage value of the signal at the second signal terminal S2 without being too low.

In an exemplary implementation mode, the first signal terminal of the electrostatic release circuit may be electrically connected with the light emitting output signal line EOL, the second signal terminal of the electrostatic release circuit may be electrically connected with the second light emitting power supply line EVGL, and the third signal terminal of the electrostatic release circuit may be electrically connected with the first scan power supply line GVGH.

In an exemplary implementation mode, a distance between the second light emitting power supply line EVGL and the first scan power supply line GVGH is about 8 microns to 15 microns. For example, the distance between the second light emitting power supply line EVGL and the first scan power supply line GVGH may be 10 microns.

In an exemplary implementation mode, the pixel circuit includes a plurality of transistors and a capacitor, the light emitting shift register includes a plurality of light emitting transistors and a plurality of light emitting capacitors, the scan shift register includes a plurality of scan transistors and a plurality of scan capacitors, the light emitting capacitors and the scan capacitors each include a first electrode plate and a second electrode plate, and the drive structure layer includes a semiconductor layer, a first conductive layer, a second conductive layer, a third conductive layer, and a fourth conductive layer stacked sequentially.

In an exemplary implementation mode, the semiconductor layer may include at least active layers of the plurality of transistors, active layers of the plurality of light emitting transistors, active layers of the plurality of scan transistors, an active layer of the first release transistor, and an active layer of the second release transistor.

In an exemplary implementation mode, the first conductive layer may include at least a light emitting signal line, a scan signal line, gate electrodes of the plurality of transistors, gate electrodes of the plurality of light emitting transistors, the first electrode plate of the capacitor, first electrode plates of the plurality of light emitting capacitors, gate electrodes of the plurality of scan transistors, first electrode plates of the plurality of scan capacitors, a gate electrode of the first release transistor, and a gate electrode of the second release transistor.

In an exemplary implementation mode, the second conductive layer may include at least a second electrode plate of the capacitor, second electrode plates of the plurality of light emitting capacitors, second electrode plates of the plurality of scan capacitors, a scan output signal line, and a light emitting output signal line.

In an exemplary implementation mode, the third conductive layer may include at least a light emitting initial signal line, a first light emitting clock signal line, a second light emitting clock signal line, a first light emitting power supply line, a second light emitting power supply line, a scan initial signal line, a first sub-clock signal line of the first scan clock signal line, a third sub-clock signal line of the second scan clock signal line, a first scan power supply line, a second scan power supply line, first electrodes and second electrodes of the plurality of transistors, first electrodes and second electrodes of the plurality of light emitting transistors, first electrodes and second electrodes of the plurality of scan transistors, a first electrode and a second electrode of the first release transistor, and a first electrode and a second electrode of the second release transistor.

In an exemplary implementation mode, the fourth conductive layer may include at least a second sub-clock signal line of the first scan clock signal line and a fourth sub-clock signal line of the second scan clock signal line.

In an exemplary implementation mode, as shown in FIG. 5A and FIG. 6A, the first electrodes and second electrodes of the plurality of light emitting transistors are located between the first light emitting power supply line EVGH and the second light emitting power supply line EVGL, the first electrode and the second electrode of the first release transistor to the first electrode and the second electrode of the second release transistor are located between the second light emitting power supply line EVGL and the first scan power supply line GVGH, the first electrodes and the second electrodes of a portion of the scan transistors are located between the scan initial signal line GSTV and the second scan power supply line GVGL, and the first electrodes and the second electrodes of another portion of the scan transistors may be located at a side of the second scan power supply line GVGL close to the display region.

In an exemplary implementation mode, the scan shift register may have a circuit structure of 8T2C, and the light emitting shift register may have a circuit structure of 10T3C or 12T3C, which is not limited in the present disclosure.

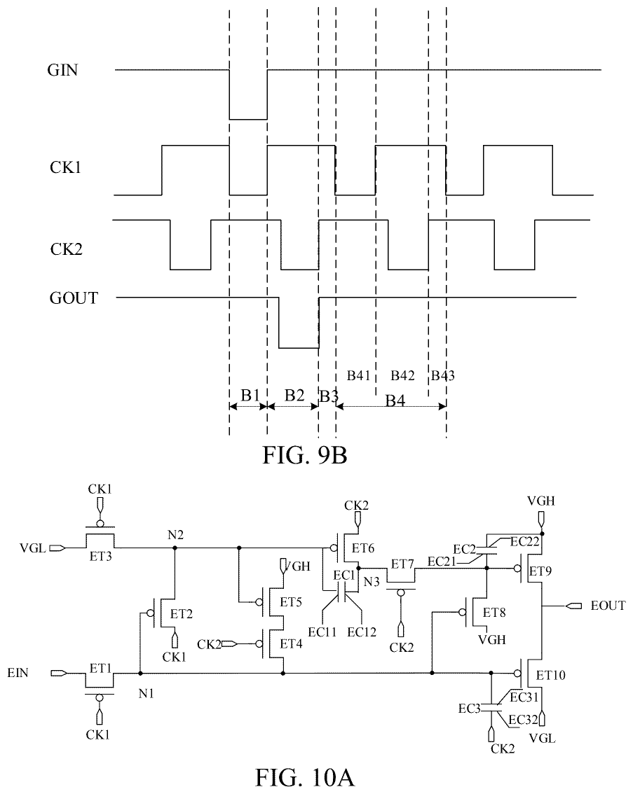

In an exemplary implementation mode, FIG. 9A is an equivalent circuit diagram of a scan shift register. As shown in FIG. 9A, the scan shift register may include a first scan transistor GT1 to an eighth scan transistor GT8, a first scan capacitor GC1, and a second scan capacitor GC2.

In an exemplary implementation mode, as shown in FIG. 9A, a gate electrode of the first scan transistor GT1 is electrically connected with the first clock signal terminal CK1, a first electrode of the first scan transistor GT1 is electrically connected with an input terminal GIN, and a second electrode of the first scan transistor GT1 is electrically connected with the first node N1; a gate electrode of the second scan transistor GT2 is electrically connected with the first node N1, a first electrode of the second scan transistor GT2 is electrically connected with the first clock signal terminal CK1, and a second electrode of the second scan transistor GT2 is electrically connected with the second node N2; a gate electrode of the third scan transistor GT3 is electrically connected with the first clock signal terminal CK1, a first electrode of the third scan transistor GT3 is electrically connected with the second power supply terminal VGL, and a second electrode of the third scan transistor GT3 is electrically connected with the second node N2; a gate electrode of the fourth scan transistor GT4 is electrically connected with the second node N2, a first electrode of the fourth scan transistor GT4 is electrically connected with the first power supply terminal VGH, and a second electrode of the fourth scan transistor GT4 is electrically connected with an output terminal GOUT; a gate electrode of the fifth scan transistor GT5 is electrically connected with the third node N3, a first electrode of the fifth scan transistor GT5 is electrically connected with the second clock signal terminal CK2, and a second electrode of the fifth scan transistor GT5 is electrically connected with the output terminal GOUT; a gate electrode of the sixth scan transistor GT6 is electrically connected with the second node N2, a first electrode of the sixth scan transistor GT6 is electrically connected with the first power supply terminal VGH, and a second electrode of the sixth scan transistor GT6 is electrically connected with a first electrode of the seventh scan transistor GT7; a gate electrode of the seventh scan transistor GT7 is electrically connected with the second clock signal terminal CK2, and a second electrode of the seventh scan transistor GT7 is electrically connected with the first node N1; a gate electrode of the eighth scan transistor GT8 is electrically connected with the second power supply terminal VGL, a first electrode of the eighth scan transistor GT8 is electrically connected with the first node N1, and a second electrode of the eighth scan transistor GT8 is electrically connected with the third node N3; a first electrode plate GC11 of the first scan capacitor GC1 is electrically connected with the second node N2, and a second electrode plate GC12 of the first scan capacitor GC1 is electrically connected with the first power supply terminal VGH; a first electrode plate GC21 of the second scan capacitor GC2 is electrically connected with the third node N3, and a second electrode plate GC22 of the second scan capacitor GC2 is electrically connected with the output terminal GOUT.

In an exemplary implementation mode, the first scan transistor GT1 to the eighth scan transistor GT8 may be P-type transistors or may be N-type transistors.

In an exemplary implementation mode, the first power supply terminal VGH continuously provides a high-level signal, and the second power supply terminal VGL continuously provides a low-level signal.

FIG. 9B is a timing diagram of the scan shift register provided in FIG. 9A, FIG. 9B is illustrated by taking a case that the first scan transistor GT1 to the eighth scan transistor GT8 are P-type transistors as an example. As shown in FIG. 9B, a working process of a scan shift register provided by an exemplary embodiment includes following stages.

In an input stage B1, signals of the first clock signal terminal CK1 and the input terminal GIN are low-level signals, and a signal of the second clock signal terminal CK2 is a high-level signal. Since a signal of the first clock signal terminal CK1 is a low-level signal, the first scan transistor GT1 is turned on, and a signal of the input terminal GIN is transmitted to the first node N1 through the first scan transistor GT1. Since the eighth scan transistor GT8 receives a low-level signal of the second power supply terminal VGL, the eighth scan transistor GT8 is in an ON state. A level of the third node N3 may turn on the fifth scan transistor GT5, and the signal of the second clock signal terminal CK2 is transmitted to the output terminal GOUT through the fifth scan transistor GT5, that is, in the input stage B1, the output terminal GOUT has the signal of the second clock signal terminal CK2 which is the high-level signal. In addition, since the signal of the first clock signal terminal CK1 is the low-level signal, the third scan transistor GT3 is turned on, and the low-level signal of the second power supply terminal VGL is transmitted to the second node N2 via the third scan transistor GT3. At this point, both the fourth scan transistor GT4 and the sixth scan transistor GT6 are turned on. Since the signal of the second clock signal terminal CK2 is the high-level signal, the seventh scan transistor GT7 is turned off.

In an output stage B2, a signal of the first clock signal terminal CK1 is a high-level signal, a signal of the second clock signal terminal CK2 is a low-level signal, and a signal of the input terminal GIN is a high-level signal. The fifth scan transistor GT5 is turned on, and the signal of the second clock signal terminal CK2 is used as a signal of the output terminal GOUT via the fifth scan transistor GT5. In the output stage B2, a signal at one end of the second scan capacitor GC2 connected with the output terminal GOUT, becomes a signal of the second power supply terminal VGL. Due to a bootstrap function of the second scan capacitor GC2, the eighth scan transistor GT8 is turned off, the fifth scan transistor GT5 may be turned on better, and the signal of the output terminal GOUT is a low-level signal. In addition, the signal of the first clock signal terminal CK1 is the high-level signal, so that both the first scan transistor GT1 and the third scan transistor GT3 are turned off. The second scan transistor GT2 is turned on, and the high-level signal of the first clock signal terminal CK1 is transmitted to the second node N2 via the second scan transistor GT2, so that both the fourth scan transistor GT4 and the sixth scan transistor GT6 are turned off. Since the signal of the second clock signal terminal CK2 is the low-level signal, the seventh scan transistor GT7 is turned on.

In a buffering stage B3, signals of the first clock signal terminal CK1 and the second clock signal terminal CK2 are both high-level signals, a signal of the input terminal GIN is a high-level signal, the fifth scan transistor GT5 is turned on, and a signal of the second clock signal terminal CK2 is used as an output signal via the fifth scan transistor GT5. A signal of the first clock signal terminal CK1 is a high-level signal, so that the first scan transistor GT1 and the third scan transistor GT3 are both turned off, the eighth scan transistor GT8 is turned on, the second scan transistor GT2 is turned on, and the high-level signal of the first clock signal terminal CK1 is transmitted to the second node N2 via the second scan transistor GT2, and thus both the fourth scan transistor GT4 and the sixth scan transistor GT6 are turned off. Since a signal of the second clock signal terminal CK2 is a high-level signal, the seventh scan transistor GT7 is turned off.

In a first sub-stage B41 of a stabilization stage B4, a signal of the first clock signal terminal CK1 is a low-level signal, and signals of the second clock signal terminal CK2 and the input terminal GIN are high-level signals. Since the signal of the first clock signal terminal CK1 is the low-level signal, the first scan transistor GT1 is turned on, a signal of the input terminal GIN is transmitted to the first node N1 via the first scan transistor GT1, and the second scan transistor GT2 is turned off. Since the eighth scan transistor GT8 is in an ON state, the fifth scan transistor GT5 is turned off. Since the signal of the first clock signal terminal CK1 is at a low level, the third scan transistor GT3 is turned on, both the fourth scan transistor GT4 and the sixth scan transistor GT6 are turned on, and a high-level signal of the first power supply terminal VGH is transmitted to the output terminal GOUT via the fourth scan transistor GT4, that is, a signal of the output terminal GOUT is a high-level signal.

In a second sub-stage B42 of the stabilization stage B4, a signal of the first clock signal terminal CK1 is a high-level signal, a signal of the second clock signal terminal CK2 is a low-level signal, and a signal of the input terminal GIN is a high-level signal. Both the fifth scan transistor GT5 and the second scan transistor GT2 are turned off. The signal of the first clock signal terminal CK1 is the high-level signal, so that both the first scan transistor GT1 and the third scan transistor GT3 are turned off. Under a holding function of the first scan capacitor GC1, both the fourth scan transistor GT4 and the sixth scan transistor GT6 are turned on, and a high-level signal is transmitted to the output terminal GOUT via the fourth scan transistor GT4, that is, a signal of the output terminal GOUT is a high-level signal.

In the second sub-stage B42, since the signal of the second clock signal terminal CK2 is the low-level signal, the seventh scan transistor GT7 is turned on, thus a high-level signal is transmitted to the third node N3 and the first node N1 via the sixth scan transistor GT6 and the seventh scan transistor GT7, so that signals of the third node N3 and the first node N1 are kept as high-level signals.

In a third sub-stage B43, signals of the first clock signal terminal CK1 and the second clock signal terminal CK2 are both high-level signals, and a signal of the input terminal GIN is a high-level signal. The fifth scan transistor GT5 and the second scan transistor GT2 are turned off. A signal of the first clock signal terminal CK1 is a high-level signal, so that both the first scan transistor GT1 and the third scan transistor GT3 are turned off, and both the fourth scan transistor GT4 and the sixth scan transistor GT6 are turned on. A high-level signal is transmitted to the output terminal GOUT via the fourth scan transistor GT4, that is, a signal of the output terminal GOUT is a high-level signal.

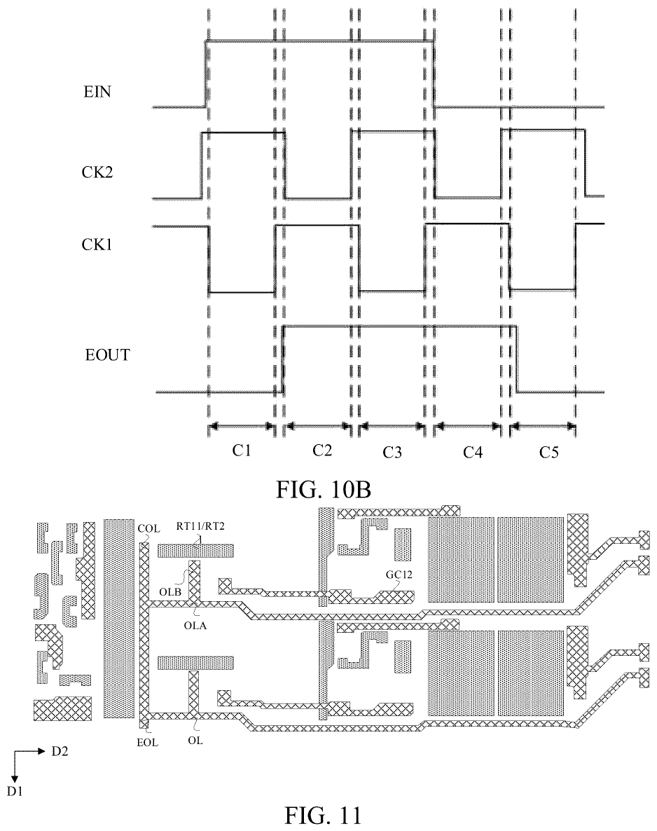

FIG. 10A is an equivalent circuit diagram of a light emitting shift register. As shown in FIG. 10A, the light emitting shift register may include a first light emitting transistor ET1 to a tenth light emitting transistor ET10 and a first light emitting capacitor EC1 to a third light emitting capacitor EC3.

In an exemplary implementation mode, as shown in FIG. 10A, a gate electrode of the first light emitting transistor ET1 is electrically connected with the first clock signal terminal CK1, a first electrode of the first light emitting transistor ET1 is electrically connected with the input terminal EIN, and a second electrode of the first light emitting transistor ET1 is electrically connected with the first node N1; a gate electrode of the second light emitting transistor ET2 is electrically connected with the first node N1, a first electrode of the second light emitting transistor ET2 is electrically connected with the first clock signal terminal CK1, and a second electrode of the second light emitting transistor ET2 is electrically connected with the second node N2; a gate electrode of the third light emitting transistor ET3 is electrically connected with the first clock signal terminal CK1, a first electrode of the third light emitting transistor ET3 is electrically connected with the second power supply terminal VGL, and a second electrode of the third light emitting transistor ET3 is electrically connected with the second node N2; a gate electrode of the fourth light emitting transistor ET4 is electrically connected with the second clock signal terminal CK2, a first electrode of the fourth light emitting transistor ET4 is electrically connected with the first node N1, and a second electrode of the fourth light emitting transistor ET4 is electrically connected with a first electrode of the fifth light emitting transistor ET5; a gate electrode of the fifth light emitting transistor ET5 is electrically connected with the second node N2, and a second electrode of the fifth light emitting transistor ET5 is electrically connected with the first power supply terminal VGH; a first electrode of the sixth light emitting transistor ET6 is electrically connected with the second clock signal terminal CK2, and a second electrode of the sixth light emitting transistor ET6 is electrically connected with the third node N3; a gate electrode of the seventh light emitting transistor ET7 is electrically connected with the second clock signal terminal CK2, a first electrode of the seventh light emitting transistor ET7 is electrically connected with the third node N3, and a second electrode of the seventh light emitting transistor ET7 is electrically connected with a gate electrode of the ninth light emitting transistor ET9; a gate electrode of the eighth light emitting transistor ET8 is electrically connected with the first node N1, a first electrode of the eighth light emitting transistor ET8 is electrically connected with the first power supply terminal VGH, and a second electrode of the eighth light emitting transistor ET8 is electrically connected with a gate electrode of the ninth light emitting transistor ET9; a first electrode of the ninth light emitting transistor ET9 is electrically connected with the first power supply terminal VGH, and a second electrode of the ninth light emitting transistor ET9 is electrically connected with the output terminal EOUT; a first electrode of the tenth light emitting transistor ET10 is electrically connected with the second power supply terminal VGL, and a second electrode of the tenth light emitting transistor ET10 is electrically connected with the output terminal EOUT; a first electrode plate of the first light emitting capacitor EC1 is electrically connected with a gate electrode of the sixth light emitting transistor ET6, and a second electrode plate of the first light emitting capacitor EC1 is electrically connected with the third node N3; a first electrode plate EC21 of the second light emitting capacitor EC2 is electrically connected with the gate electrode of the ninth light emitting transistor ET9, and a second electrode plate EC22 of the second light emitting capacitor EC2 is electrically connected with the first power supply terminal VGH; a first electrode plate E31 of the third light emitting capacitor EC3 is electrically connected with a gate electrode of the tenth light emitting transistor ET10, and a second electrode plate EC32 of the third light emitting capacitor EC3 is electrically connected with the second power supply terminal VGL.

In an exemplary implementation mode, the first light emitting transistor ET1 to the tenth light emitting transistor ET10 may be P-type transistors or may be N-type transistors.

In an exemplary implementation mode, the first power supply terminal VGH continuously provides a high-level signal, and the second power supply terminal VGL continuously provides a low-level signal.

FIG. 10B is a timing diagram of the light emitting shift register provided in FIG. 10A. FIG. 10B is illustrated by taking a case in which the first light emitting transistor ET1 to the tenth light emitting transistor ET10 are P-type transistors as an example, and a working process of a light emitting shift register provided by an exemplary embodiment may include following stages.

In a first stage C1, a signal of the first clock signal terminal CK1 is at a low level, so the first light emitting transistor ET1 and the third light emitting transistor ET3 are turned on. The turned-on first light emitting transistor ET1 transmits a high-level signal of the input terminal EIN to the first node N1, and a signal of the first node N1 becomes a high-level signal, so the second light emitting transistor ET2, the eighth light emitting transistor ET8, and the tenth light emitting transistor ET10 are turned off. In addition, the turned-on third light emitting transistor ET3 transmits a low-level signal of the second power supply terminal VGL to the second node N2, and a signal of the second node N2 becomes a low-level signal, so the fifth light emitting transistor ET5 and the sixth light emitting transistor ET6 are turned on. Since a signal of the second clock signal terminal CK2 is a high-level signal, the seventh light emitting transistor ET7 is turned off. In addition, the ninth light emitting transistor ET9 is turned off due to a storage function of the third light emitting capacitor EC3. In the first stage C1, since both the ninth light emitting transistor ET9 and the tenth light emitting transistor ET10 are turned off, a signal of the output terminal EOUT is kept at a previous low level.

In a second stage C2, a signal of the second clock signal terminal CK2 is at a low level, so the fourth light emitting transistor ET4 and the seventh light emitting transistor ET7 are turned on. Since a signal of the first clock signal terminal CK1 is at a high level, the first light emitting transistor ET1 and the third light emitting transistor ET3 are turned off. Due to a storage function of the first light emitting capacitor EC1, the second node N2 may continue to maintain a low level of a previous stage, so the fifth light emitting transistor ET5 and the sixth light emitting transistor ET6 are turned on. A high-level signal of the first power supply terminal VGH is transmitted to the first node N1 through the turned-on fifth light emitting transistor ET5 and the fourth light emitting transistor ET4, and a level of the first node N1 continues to maintain a high level of the previous stage, so the second light emitting transistor ET2, the eighth light emitting transistor ET8, and the tenth light emitting transistor ET10 are turned off. In addition, a low-level signal of the second clock signal terminal CK2 is transmitted to the gate electrode of the ninth light emitting transistor ET9 through the turned-on sixth light emitting transistor ET6 and the seventh light emitting transistor ET7, the ninth light emitting transistor ET9 is turned on, and the turned-on ninth light emitting transistor ET9 outputs the high-level signal of the first power supply terminal VGH, and a signal of the output terminal EOUT is at a high level.

In a third stage C3, a signal of the first clock signal terminal CK1 is at a low level, so the first light emitting transistor ET1 and the third light emitting transistor ET3 are turned on. A signal of the second clock signal terminal CK2 is at a high level, so the fourth light emitting transistor ET4 and the seventh light emitting transistor ET7 are turned off. Due to a storage function of the third light emitting capacitor EC3, the ninth light emitting transistor ET9 maintains a turned-on state, the turned-on ninth light emitting transistor ET9 outputs a high-level signal of the first power supply terminal VGH, and a signal of the output terminal EOUT still remains at a high level.

In a fourth stage C4, a signal of the first clock signal terminal CK1 is at a high level, so the first light emitting transistor ET1 and the third light emitting transistor ET3 are turned off. A signal of the second clock signal terminal CK2 is at a low level, so the fourth light emitting transistor ET4 and the seventh light emitting transistor ET7 are turned on. Due to a storage function of the second light emitting capacitor EC2, a level of the first node N1 maintains a high level of a previous stage, and the second light emitting transistor ET2, the eighth light emitting transistor ET8, and the tenth light emitting transistor ET10 are turned off. Due to a storage function of the first light emitting capacitor EC1, the second node N2 continues to maintain a low level of the previous stage, the fifth light emitting transistor ET5 and the sixth light emitting transistor ET6 are turned on. In addition, a low-level signal of the second clock signal terminal CK2 is transmitted to the gate electrode of the ninth light emitting transistor ET9 through the turned-on sixth light emitting transistor ET6 and the seventh light emitting transistor ET7, so the ninth light emitting transistor ET9 is turned on, the turned-on ninth light emitting transistor ET9 outputs a high-level signal of the first power supply terminal VGH, and a signal of the output terminal EOUT still remains at a high level.

In a fifth stage C5, a signal of the first clock signal terminal CK1 is at a low level, so the first light emitting transistor ET1 and the third light emitting transistor ET3 are turned on. A signal of the second clock signal terminal CK2 is at a high level, so the fourth light emitting transistor ET4 and the seventh light emitting transistor ET7 are turned off. The turned-on first light emitting transistor ET1 transmits a high-level signal of the input terminal EIN to the first node N1, and a signal of the first node N1 becomes a low-level signal, so the second light emitting transistor ET2, the eighth light emitting transistor ET8, and the tenth light emitting transistor ET10 are turned on. The turned-on second light emitting transistor ET2 transmits the signal of the first clock signal terminal CK1 which is at the low-level to the second node N2, a level of the second node N2 may be pulled down, so the second node N2 continues to maintain a low level of a previous stage, and the fifth light emitting transistor ET5 and the sixth light emitting transistor ET6 are turned on. In addition, the turned-on eighth light emitting transistor ET8 transmits a high-level signal of the first power supply terminal VGH to the gate electrode of the ninth light emitting transistor ET9, so the ninth light emitting transistor ET9 is turned off. The turned-on tenth light emitting transistor ET10 outputs a low-level signal of the second power supply terminal VGL, and a signal of the output terminal EOUT turns to be at a low level.

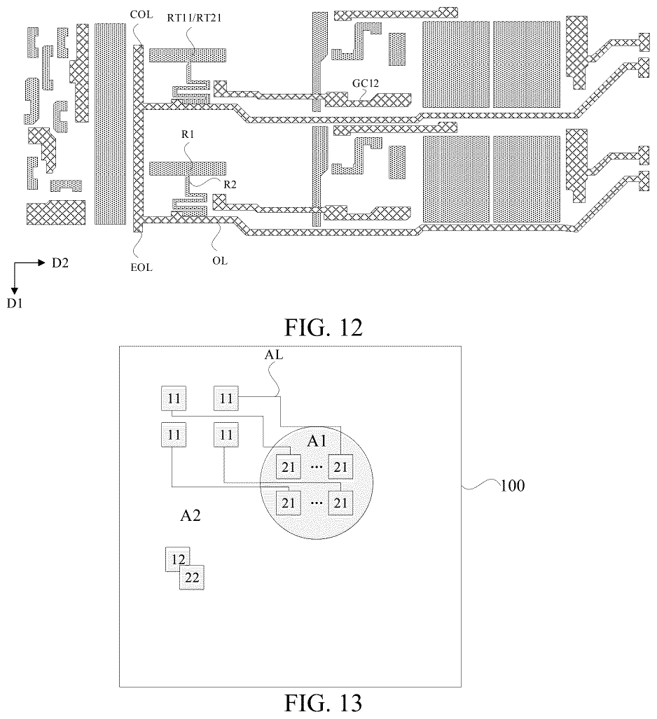

In an exemplary implementation mode, FIG. 11 is a schematic diagram of structures of a semiconductor layer and a second conductive layer in the display substrate provided in FIG. 5A, and FIG. 12 is a schematic diagram of structures of a semiconductor layer and a second conductive layer in the display substrate provided in FIG. 6A. As shown in FIGS. 11 and 12, at least one light emitting output signal line includes an output connection portion COL extending along the first direction D1 and at least one output line OL arranged along the first direction D1.

The output connection portion COL is electrically connected with the light emitting shift register and the at least one output line OL, respectively, and the output line OL is in one-to-one correspondence with a light emitting signal line with which the light emitting output signal line is connected, and is electrically connected with a corresponding light emitting signal line.

In an exemplary implementation mode, as shown in FIG. 11, in the display substrate provided in FIG. 5A, the output line OL includes an output main body portion OLA extending at least partially along the second direction D2 and an output connection portion OLB extending along the first direction D1, and the output main body portion OLA is electrically connected with the output connection portion OLB.

In an exemplary implementation mode, as shown in FIG. 5A, a second electrode of the first release transistor and a second electrode of the second release transistor are of an integral structure, and an orthographic projection thereof on the base substrate is at least partially overlapped with an orthographic projection of the output connection portion on the base substrate, and the integral structure of the second electrode of the first release transistor and the second electrode of the second release transistor is electrically connected with the output connection portion.

In an exemplary implementation mode, as shown in FIG. 11, an active layer RT11 of the first release transistor and an active layer RT21 of the second release transistor in the display substrate provided in FIG. 5A are of an integral structure and extend along the second direction D2. An orthographic projection of the output connection portion OLB on the base substrate is not overlapped with an orthographic projection of the integral structure of the active layer RT11 of the first release transistor and the active layer RT21 of the second release transistor on the base substrate.

In an exemplary implementation mode, as shown in FIG. 12, an active layer RT11 of the first release transistor and an active layer RT21 of the second release transistor in the display substrate provided in FIG. 6A are of an integral structure, and include an active main body portion R1 and an active connection portion R2, the active main body portion R1 and the active connection portion R2 are electrically connected, and the active main body portion R1 and the active connection portion R2 are arranged along the first direction D1.

In an exemplary implementation mode, as shown in FIG. 12, the active main body portion R1 extends along the second direction D2, and the active connection portion R2 extends at least partially along the first direction D1.

In an exemplary implementation mode, as shown in FIG. 12, the active connection portion R2 is in a shape of a polyline. The active connection part R2 being in the shape of the polyline may increase resistance, increase electrostatic consumption, prevent a gate drive circuit from being burned, and improve a display effect and reliability of the display substrate.

In an exemplary implementation mode, as shown in FIG. 12, the output line OL extends at least partially along the second direction D2; a second electrode of the first release transistor and a second electrode of the second release transistor are of an integral structure. An orthographic projection of the active connection portion R2 on the base substrate is at least partially overlapped with orthographic projections of the integral structure of the second electrode of the first release transistor and the second electrode of the second release transistor and the output line OL on the base substrate, and the active connection portion R2 is electrically connected with the integral structure of the second electrode of the first release transistor and the second electrode of the second release transistor and the output line OL, respectively.

In an exemplary implementation mode, as shown in FIG. 12, a width of the active connection portion R2 is smaller than a width of the active main body portion R1.

In an exemplary implementation mode, as shown in FIGS. 11 and 12, the scan shift register includes a first scan capacitor, a second electrode plate GC12 of the first scan capacitor is electrically connected with the first scan power supply line, and the second electrode plate GC21 of the first scan capacitor extends along the second direction D2.

In an exemplary implementation mode, as shown in FIGS. 5A, 6A, 11, and 12, an orthographic projection of the second electrode plate GC21 of the first scan capacitor on the base substrate is at least partially overlapped with orthographic projections of the first scan power supply line GVGH, the second scan power supply line GVGL, the first scan clock signal line GCK1, the second scan clock signal line GCK2, and the scan initial signal line GSTV on the base substrate.

In an exemplary implementation mode, FIG. 13 is a schematic diagram of another structure of the display substrate. As shown in FIG. 13, the display region may include a first display region A1 and a second display region A2 located on at least one side of the first display region A1, and the display substrate further includes a light emitting device and an anode connection line AL located in the display region 100. A pixel circuit is electrically connected with the light emitting device. The pixel circuit includes a first pixel circuit 11 and a second pixel circuit 12 located in the second display region A2, and the light emitting device includes a first light emitting device 21 located in the first display region A1 and a second light emitting device 22 located in the second display region. The first pixel circuit 11 is electrically connected with the first light emitting device 21, and the second pixel circuit is electrically connected with the second light emitting device 22.

As shown in FIG. 13, an orthographic projection of the first pixel circuit 11 on the base substrate is at least partially overlapped with an orthographic projection of the first light emitting device 21 with which the first pixel circuit 11 is connected on the base substrate.

As shown in FIG. 13, the anode connection line AL is electrically connected with the second light emitting device 22 and the second pixel circuit 12 connected with the second light emitting device 22, respectively.

In an exemplary implementation mode, the anode connection line AL may be a transparent conductive line.

In an exemplary implementation mode, as shown in FIGS. 7A to 7C, the drive structure layer may further include a first power supply line VDD and a data signal line Data at least partially located in the display region. The first power supply line VDD and the data signal line Data extend at least partially along the first direction D1.

In an exemplary implementation mode, data signal lines Data connected with columns where pixel circuits located on left and right sides of the first display region are located extend along the first direction D1.

In an exemplary implementation mode, as shown in FIG. 7B, the drive structure layer may further include a data connection line DL located in the display region, and the data connection line DL extends at least partially along the second direction D2.

In an exemplary implementation mode, in order to ensure a display effect of the first display region, data signal lines connected with columns where pixel circuits located on upper and lower sides of the first display region are located are disposed around a periphery of the first display region, that is, the data signal lines connected with the columns where the pixel circuits located on the upper and lower sides of the first display region are located are in a shape of a polyline. The data signal lines connected with the columns where the pixel circuits located on the upper and lower sides of the first display region are located include: a plurality of data main body lines which extend along the first direction and are disposed at intervals and a plurality of data connection lines which extend along the second direction and are disposed at intervals, adjacent data main body lines are connected through a data connection line, and adjacent data connection lines are connected through a data main body line. In order to ensure that there is no crosstalk between data signals, the data main body lines and the data connection lines are disposed in different layers.

In the display substrate, some of the pixel circuits are structured to include a data connection line, and some of the pixel circuits are structured not to include a data connection line. FIG. 7B is illustrated by taking a structure of a pixel circuit including a data connection line as an example, and FIGS. 7A and 7C are illustrated by taking a structure of a pixel circuit not including a data connection line as an example.

In an exemplary implementation mode, the drive structure layer further includes a fourth conductive layer and a fifth conductive layer sequentially stacked on the third conductive layer.

In an exemplary implementation mode, the third conductive layer at least includes a data connection line.

In an exemplary implementation mode, the fourth conductive layer includes at least a first power supply line and a data signal line.

In an exemplary implementation mode, the fifth conductive layer at least includes an anode connection line.

In an exemplary implementation mode, as shown in FIGS. 5A, 6A, and 7A to 7C, the drive structure layer may further include at least one initial power supply line located in the non-display region and at least one initial signal line at least partially located in the display region; the initial power supply line is located at a side of the scan drive circuit close to the display region, the initial power supply line extends at least partially along the first direction D1, and the initial signal line extends at least partially along the second direction D2. FIGS. 5 and 6 are illustrated by taking a case in which two initial power supply lines, for example, a first initial power supply line INITL1 and a second initial power supply line INITL2 are included as an example. FIGS. 7A and 7B are illustrated by taking two initial signal lines, i.e., a first initial signal line INIT1 and a second initial signal line INIT2 as an example.

In an exemplary implementation mode, the initial signal lines are in one-to-one correspondence with the initial power supply lines, and an initial signal line is electrically connected with a pixel circuit and a corresponding initial power supply line, respectively.

In an exemplary implementation mode, an initial power supply line may be of a double-layer structure. The initial power supply line may include a first sub-initial power supply line and a second sub-initial power supply line electrically connected with each other.

In an exemplary implementation mode, the second conductive layer includes at least an initial signal line.

In an exemplary implementation mode, the third conductive layer includes at least: the first sub-initial power supply line of the initial power supply line;

In an exemplary implementation mode, the fourth conductive layer includes at least the second sub-initial power supply line of the initial power supply line.

In an exemplary implementation mode, as shown in FIGS. 5B and 6B, the drive structure layer may further include a first insulation layer 11, a second insulation layer 12, a third insulation layer 13, a fourth insulation layer 14, a planarization layer 15, a fifth insulation layer 16, and a sixth insulation layer 17. The first insulation layer 11 is located between the semiconductor layer and the first conductive layer, the second insulation layer 12 is located between the first conductive layer and the second conductive layer, the third insulation layer 13 is located between the second conductive layer and the third conductive layer, the fourth insulation layer 14 and the planarization layer 15 are located between the third conductive layer and the fourth conductive layer, the fifth insulation layer 16 is located between the fourth conductive layer and the fifth conductive layer, and the sixth insulation layer 17 is located on a side of the fifth conductive layer away from the base substrate.

In an exemplary implementation mode, as shown in FIG. 5A and FIG. 6A, the planarization layer is provided with a groove X. A depth of the groove X may be less than or equal to a thickness of the planarization layer, which is not limited in the present disclosure.

In an exemplary implementation mode, an orthographic projection of the electrostatic release circuit ER on the base substrate is at least partially overlapped with an orthographic projection of the groove X on the base substrate. By providing an electrostatic release circuit at a position of the groove of the planarization layer, the present disclosure may achieve a narrow bezel without increasing a region occupied by a display bezel.

In an exemplary implementation mode, a length of the groove X along the second direction is less than or equal to a distance between the second light emitting power supply line EVGL and the first scan power supply line GVGH.

In an exemplary implementation mode, the drive structure layer may further include a second power supply connection line and a second power supply line. The second power supply line and the second power supply connection line are electrically connected with each other. The second power supply line is electrically connected with a cathode of a light emitting device.

In an exemplary implementation mode, the second power supply connection line may be located in the third conductive layer, and the second power supply line may be located in the fourth conductive layer.

In an exemplary implementation mode, an orthographic projection of the second power supply connection line on the base substrate and an orthographic projection of the second power supply line on the base substrate are at least partially overlapped. The second power supply line is connected with the second power supply connection line through a via between the fourth insulation layer and the planarization layer.

In an exemplary implementation mode, the second power supply connection line may be in a shape of a line extending along the second direction D2, and may be located at a side of the light emitting initial signal line away from the first light emitting clock signal line.

In an exemplary implementation mode, the second power supply line may be in a shape of a line extending along the second direction D2, and an orthographic projection thereof on the base substrate is also at least partially overlapped with orthographic projections of the light emitting initial signal line, the first light emitting clock signal line, the second light emitting clock signal line, and the first light emitting power supply line on the base substrate.

In an exemplary implementation mode, a plurality of vias are disposed on the second power supply line.

In an exemplary implementation mode, a distance between an orthographic projection of the second power supply line on the base substrate and an orthographic projection of the second light emitting power supply line on the base substrate is less than a distance between the first light emitting power supply line and the second light emitting power supply line.

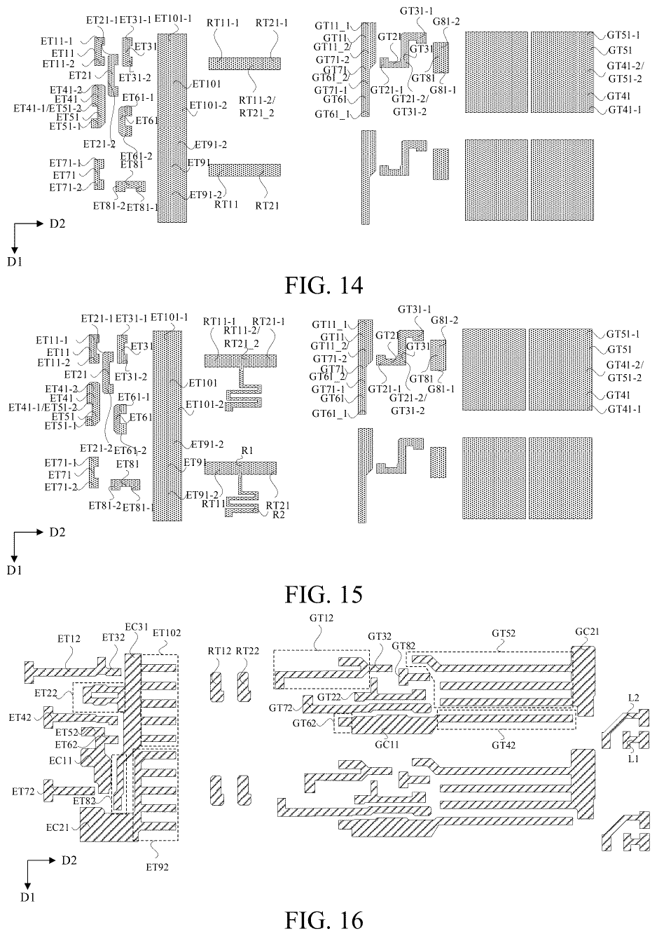

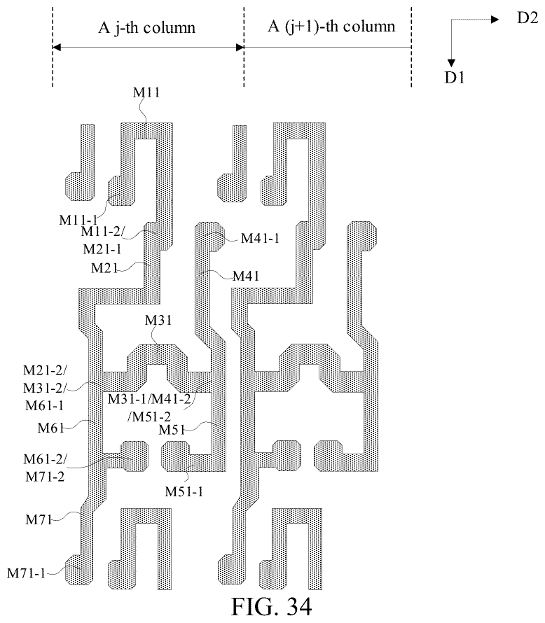

Exemplary description is made below through a preparation process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in an entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are disposed in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B. FIGS. 14 to 33 are illustrated by taking a structure located in the non-display region provided in FIG. 5A and FIG. 6A as an example, and FIGS. 34 to 55 are illustrated by taking a pixel circuit located in the display region provided in FIGS. 7B and 7C as an example.

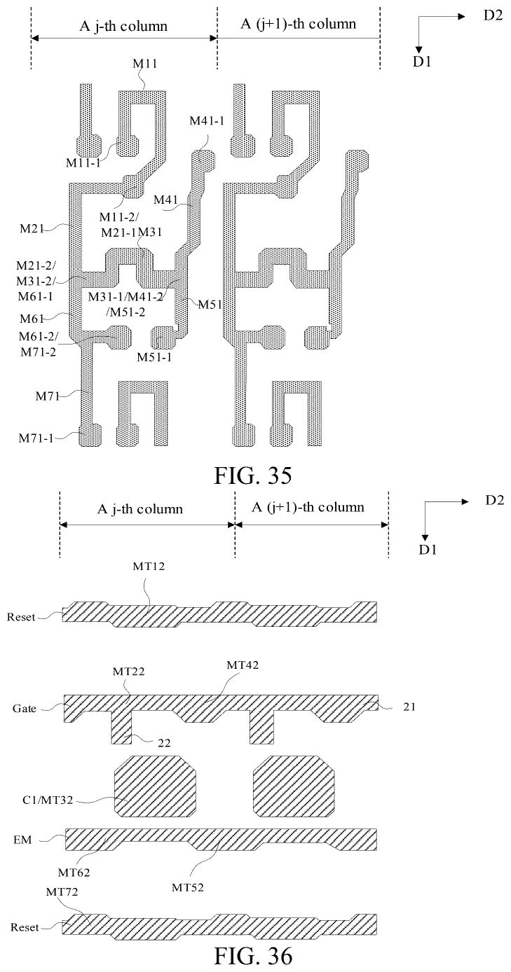

(1) Forming a pattern of a semiconductor layer on a base substrate, includes: depositing a semiconductor thin film on the base substrate, and patterning the semiconductor thin film through a patterning processes to form the pattern of the semiconductor layer. As shown in FIGS. 14, 15, 34, and 35, FIG. 14 is a schematic diagram after a pattern of a semiconductor layer is formed in FIG. 5A, FIG. 15 is a schematic diagram after a pattern of a semiconductor layer is formed in FIG. 6A, FIG. 34 is a schematic diagram after a pattern of a semiconductor layer is formed in FIG. 7B, and FIG. 35 is a schematic diagram after a pattern of a semiconductor layer is formed in FIG. 7C.

In an exemplary implementation mode, as shown in FIGS. 14, 15, 34, and 35, the pattern of the semiconductor layer may include an active layer ET11 of a first light emitting transistor to an active layer ET101 of a tenth light emitting transistor located in a light emitting shift register, an active layer RT11 of a first release transistor to an active layer RT21 of a second release transistor located in an electrostatic release circuit, an active layer GT11 of a first scan transistor to an active layer GT81 of an eighth scan transistor located in a scan shift register, and an active layer M11 of a first transistor to an active layer M71 of a seventh transistor located in a pixel circuit.

In an exemplary implementation mode, the base substrate may be a rigid base substrate or a flexible base substrate, wherein the rigid base substrate may be, but is not limited to, one or more of glass and metal foil; the flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation mode, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si). In an exemplary implementation mode, taking a stacked structure of PI1/Barrier1/a-si/PI2/Barrier2 as an example, its preparation process may include: first coating a layer of polyimide on a glass carrier board, after the layer of polyimide is cured to form a film, a first flexible (PI1) layer is formed; then depositing a layer of barrier thin film on the first flexible layer to form a first barrier (Barrier 1) layer overlaying the first flexible layer; then depositing a layer of amorphous silicon thin film on the first barrier layer to form an amorphous silicon (a-si) layer overlaying the first barrier layer; then coating another layer of polyimide on the amorphous silicon layer, after this layer of polyimide is cured to form a film, a second flexible (PI2) layer is formed; and then depositing a layer of barrier thin film on the second flexible layer to form a second barrier (Barrier 2) layer overlaying the second flexible layer, so as to complete preparation of the base substrate.

In an exemplary implementation mode, as shown in FIGS. 14 and 15, an active layer ET41 of the fourth light emitting transistor and an active layer ET51 of the fifth light emitting transistor are of an interconnected integral structure. An active layer ET91 of the ninth light emitting transistor and an active layer ET101 of the tenth light emitting transistor are of an interconnected integral structure.

In an exemplary implementation mode, as shown in FIGS. 14 and 15, in a second direction D2, an active layer ET11 of the first light emitting transistor to an active layer ET81 of the eighth light emitting transistor are located on a side of the active layer ET91 of the ninth light emitting transistor (also an active layer ET101 of the tenth light emitting transistor) away from the display region. An active layer ET71 of the seventh light emitting transistor is located on a side of an active layer ET81 of the eighth light emitting transistor away from the display region. An active layer ET11 of the first light emitting transistor and an active layer ET41 of the fourth light emitting transistor (also an active layer ET51 of the fifth light emitting transistor) are located on a side of an active layer ET21 of the second light emitting transistor away from the display region, and an active layer ET31 of the third light emitting transistor and an active layer ET61 of the sixth light emitting transistor are located on a side of an active layer ET21 of the second light emitting transistor close to the active layer ET91 of the ninth light emitting transistor (also the active layer ET101 of the tenth light emitting transistor). In a first direction D1, an active layer ET51 of a fifth light emitting transistor of a present-stage light emitting shift register is located on a side of an active layer ET41 of a fourth light emitting transistor close to a next-stage light emitting shift register, and an active layer ET11 of a first light emitting transistor to an active layer ET61 of a sixth light emitting transistor of a present-stage shift register are located on a side of an active layer ET81 of an eighth light emitting transistor close to a previous-stage light emitting shift register.

In an exemplary implementation mode, as shown in FIGS. 14 and 15, an active layer ET11 of the first light emitting transistor to an active layer ET71 of the seventh light emitting transistor, an active layer ET91 of the ninth light emitting transistor, and an active layer ET101 of the tenth light emitting transistor may have a shape of a strip extending along the first direction D1. An active layer ET81 of the eighth light emitting transistor may have a shape of a strip extending along the second direction D2.

In an exemplary implementation mode, an active layer of each light emitting transistor may include a first region, a second region, and a channel region located between the first region and the second region. In an exemplary implementation mode, a first region ET41-1 of the active layer ET41 of the fourth light emitting transistor may simultaneously serve as a second region ET51-2 of the active layer ET51 of the fifth light emitting transistor, a first region ET11-1 and a second region ET11-2 of the active layer ET11 of the first light emitting transistor, a first region ET21-1 and a second region ET21-2 of the active layer ET21 of the second light emitting transistor, a first region ET31-1 and a second region ET31-2 of the active layer ET31 of the third light emitting transistor, a second region ET41-2 of the active layer ET41 of the fourth light emitting transistor, a first region ET51-1 of the active layer ET51 of the fifth light emitting transistor, a first region ET61-1 and a second region ET61-2 of the active layer ET61 of the sixth light emitting transistor, a first region ET71-1 and a second region ET71-2 of the active layer ET71 of the seventh light emitting transistor, a first region ET81-1 and a second region ET81-2 of the active layer ET81 of the eighth light emitting transistor, a first region ET91-1 and a second region ET91-2 of the active layer ET91 of the ninth light emitting transistor, and a first region ET101-1 and a second region ET101-2 of the active layer ET101 of the tenth light emitting transistor may be separately disposed.

In an exemplary implementation mode, as shown in FIGS. 14 and 15, the active layer RT11 of the first release transistor and the active layer RT21 of the second release transistor are of an interconnected integral structure. The active layer RT11 of the first release transistor and the active layer RT21 of the second release transistor are located on a side of the active layer ET91 of the ninth light emitting transistor (also the active layer ET101 of the tenth light emitting transistor) close to the display region.

In an exemplary implementation mode, as shown in FIGS. 14 and 15, in the second direction D2, the active layer RT21 of the second release transistor is located on a side of the active layer RT11 of the first release transistor close to the display region.

In an exemplary implementation mode, as shown in FIG. 14, the active layer RT11 of the first release transistor (also the active layer RT21 of the second release transistor) in the display substrate provided in FIG. 3B may be in a shape of a strip extending along the second direction D2.

In an exemplary implementation mode, as shown in FIG. 15, the active layer RT11 of the first release transistor (also the active layer RT21 of the second release transistor) in the display substrate provided in FIG. 3C may include an active main body portion R1 and an active connection portion R2. The active main body portion R1 and the active connection portion R2 are of an interconnected integral structure and arranged along the first direction D1.

In an exemplary implementation mode, as shown in FIG. 15, the active main body portion R1 may be in a shape of a strip extending along the second direction D2, and the active connection portion R2 may be in a shape of a polyline extending at least partially along the first direction D1.

In an exemplary implementation mode, as shown in FIG. 15, a width of the active connection portion R2 may be smaller than a width of the active main body portion R1.

In an exemplary implementation mode, an active layer of each release transistor may include a first region, a second region, and a channel region located between the first region and the second region. In an exemplary implementation mode, a second region RT11-2 of the active layer RT11 of the first release transistor may simultaneously serve as a second region RT21-2 of the active layer RT21 of the second release transistor. A first region RT11-1 of the active layer RT11 of the first release transistor and a first region RT21-1 of the active layer RT21 of the second release transistor may be disposed separately.

In an exemplary implementation mode, as shown in FIG. 15, the second region RT11-2 of the active layer RT11 of the first release transistor (the second region RT21-2 of the active layer RT21 of the second release transistor) includes a middle section of the active main body portion and the active connection portion R2.

In an exemplary implementation mode, as shown in FIGS. 14 and 15, the active layer GT11 of the first scan transistor, the active layer GT61 of the sixth scan transistor, and the active layer GT71 of the seventh scan transistor are of an interconnected integral structure. The active layer GT21 of the second scan transistor and the active layer GT31 of the third scan transistor are of an interconnected integral structure. The active layer GT41 of the fourth scan transistor and the active layer GT51 of the fifth scan transistor are of an interconnected integral structure.

In an exemplary implementation mode, as shown in FIGS. 14 and 15, in the second direction D2, the active layer GT11 of the first scan transistor to the active layer GT31 of the third scan transistor, the active layer GT51 of the fifth scan transistor to the active layer GT81 of the eighth scan transistor are located on a side of the active layer GT41 of the fourth scan transistor (also the active layer GT51 of the fifth transistor) away from the display region, and located on a side of the active layer RT11 of the first release transistor (also the active layer RT21 of the second release transistor) close to the display region. The active layer GT21 of the second scan transistor (also the active layer GT31 of the third scan transistor) is located between the active layer GT11 of the first scan transistor (the active layer GT61 of the sixth scan transistor and the active layer GT71 of the seventh scan transistor) and the active layer GT81 of the eighth scan transistor. The active layer GT11 of the first scan transistor (the active layer GT61 of the sixth scan transistor and the active layer GT71 of the seventh scan transistor) is located on a side of the active layer GT21 of the second scan transistor (also the active layer GT31 of the third scan transistor) close to the active layer RT11 of the first release transistor (also the active layer RT21 of the second release transistor), and the active layer GT81 of the eighth scan transistor is located on a side of the active layer GT21 of the second scan transistor (also the active layer GT31 of the third scan transistor) close to the active layer GT41 of the fourth scan transistor (also the active layer GT51 of the fifth transistor). In the first direction D1, an active layer GT41 of a fourth scan transistor of a present-stage scan shift register is located on a side of an active layer GT51 of a fifth transistor close to a next-stage scan shift register.

In an exemplary implementation mode, as shown in FIGS. 14 and 15, the active layer GT11 of the first scan transistor, the active layer GT41 of the fourth scan transistor, the active layer GT51 of the fifth scan transistor, the active layer GT61 of the sixth scan transistor, the active layer GT71 of the seventh scan transistor, and the active layer GT81 of the eighth scan transistor may have a shape of a line extending along the first direction D1. The active layer GT21 of the second scan transistor may be in a shape of a line extending along the second direction D2. The active layer GT31 of the third scan transistor may have a shape of a horizontally reversed “7”.

In an exemplary implementation mode, an active layer of each scan transistor may include a first region, a second region, and a channel region located between the first region and the second region. In an exemplary implementation mode, a second region GT11-2 of the active layer GT11 of the first scan transistor may serve as a second region GT71-2 of the active layer GT71 of the seventh scan transistor, a second region GT21-2 of the active layer GT21 of the second scan transistor may serve as a second region GT31-2 of the active layer GT31 of the third scan transistor, and a second region GT41-2 of the active layer GT41 of the fourth scan transistor may simultaneously serve as a second region GT51-2 of the active layer GT51 of the fifth scan transistor. A second region GT61-2 of the active layer GT61 of the sixth scan transistor may serve as a second region GT71-1 of the active layer GT71 of the seventh scan transistor.

In an exemplary implementation mode, as shown in FIGS. 34 and 35, an active layer M11 of a first transistor to an active layer M71 of a seventh transistor in a same sub-pixel are of an interconnected integral structure.

In an exemplary implementation mode, as shown in FIGS. 34 and 35, in the second direction D2, an active layer M21 of a second transistor and an active layer M61 of a sixth transistor may be located on a same side of an active layer M31 of a third transistor in a present sub-pixel, an active layer M41 of a fourth transistor and an active layer M51 of a fifth transistor may be located on a same side of the active layer M31 of the third transistor in the present sub-pixel, and the active layer M21 of the second transistor and the active layer M41 of the fourth transistor may be located on different sides of the active layer M31 of the third transistor in the present sub-pixel. In the first direction D1, an active layer M11 of a first transistor, the active layer M21 of the second transistor, and the active layer M41 of the fourth transistor in a present row of sub-pixels may be located on a side of the active layer M31 of the third transistor in the present sub-pixel away from a previous row of sub-pixels, and the active layer M51 of the fifth transistor, the active layer M61 of the sixth transistor, and an active layer M71 of a seventh transistor in the present row of sub-pixels may be located on a side of the active layer M31 of the third transistor in the present sub-pixel close to the previous row of sub-pixels.

In exemplary implementation mode, as shown in FIGS. 34 and 35, the active layer M11 of the first transistor may be in an “n” shape, the active layer M51 of the fifth transistor and the active layer M61 of the sixth transistor may be in an “L” shape, the active layer M31 of the third transistor may be shaped in an “Ω” shape, and the active layer M41 of the fourth transistor and the active layer M71 of the seventh transistor may be in an “I” shape.

In an exemplary implementation mode, as shown in FIG. 34, the active layer M21 of the second transistor may be in a shape of a polyline including two bends.

In an exemplary implementation mode, as shown in FIG. 35, the active layer M21 of the second transistor may be in an “L” shape.

In an exemplary implementation mode, as shown in FIGS. 34 and 35, an active layer of each transistor may include a first region, a second region, and a channel region located between the first region and the second region. In an exemplary implementation mode, a second region M11-2 of the active layer M11 of the first transistor may serve as a first region M21-1 of the active layer M21 of the second transistor, a first region M31-1 of the active layer M31 of the third transistor may simultaneously serve as a second region M41-2 of the active layer M41 of the fourth transistor and a second region M51-2 of the active layer M51 of the fifth transistor, a second region M31-2 of the active layer M31 of the third transistor may simultaneously serve as a second region M21-2 of the active layer M21 of the second transistor and a first region M61-1 of the active layer M61 of the sixth transistor, a second region M61-2 of the active layer M61 of the sixth transistor may serve as a second region M71-2 of the active layer M71 of the seventh transistor, and a first region M11-1 of the active layer of the first transistor, a first region M41-1 of the active layer M41 of the fourth transistor, a first region M51-1 of the active layer M51 of the fifth transistor, and a first region M71-1 of the active layer M71 of the seventh transistor may be disposed separately.

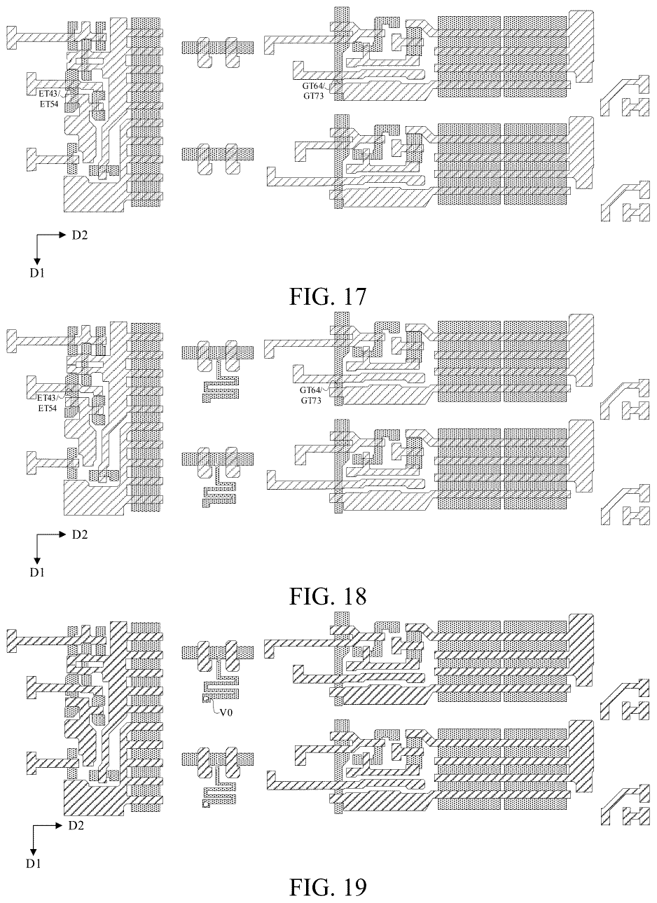

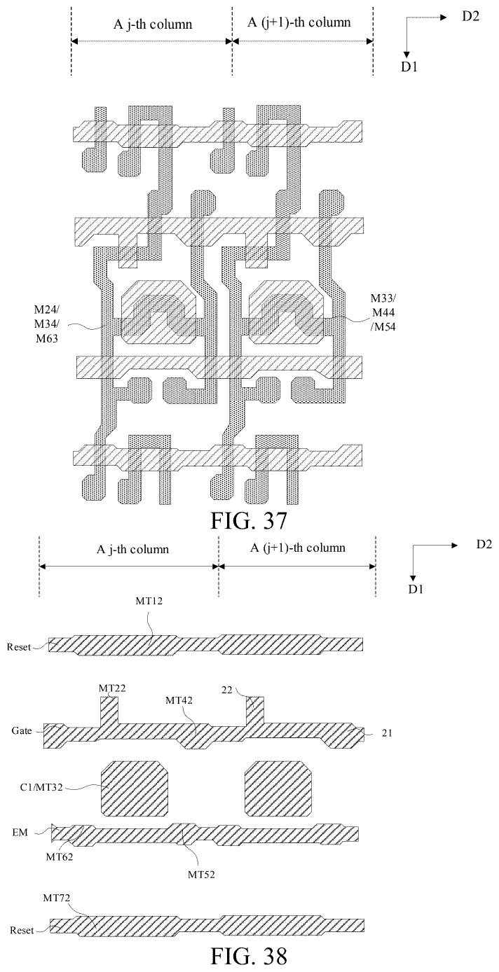

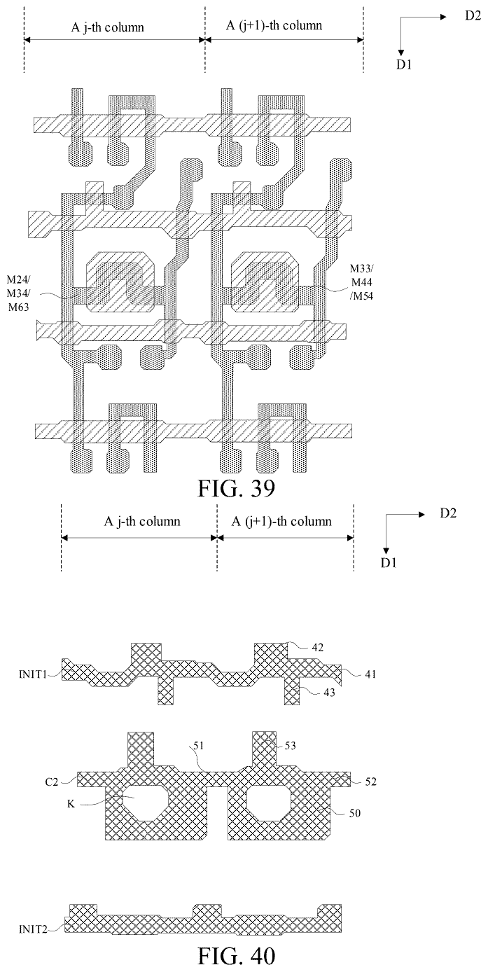

(2) Forming a pattern of a first conductive layer, includes: depositing a first insulation thin film and a first conductive thin film on the base substrate on which the above-mentioned patterns are formed, patterning the first insulation thin film and the first conductive thin film through a patterning process to form a pattern of a first insulation layer and a pattern of a first conductive layer disposed on the pattern of the first insulation layer, as shown in FIGS. 16 to 18 and FIGS. 36 to 39, FIG. 16 is a schematic diagram of a pattern of a first conductive layer in FIG. 5A and FIG. 6A, FIG. 17 is a schematic diagram after the pattern of the first conductive layer is formed in FIG. 5A, FIG. 18 is a schematic diagram of the display substrate provided in FIG. 6A after the pattern of the first conductive layer is formed, FIG. 36 is a schematic diagram of a pattern of a first conductive layer in FIG. 7B, FIG. 37 is a schematic diagram after the pattern of the first conductive layer is formed in FIG. 7B, FIG. 38 is a schematic diagram of a pattern of a first conductive layer in FIG. 7C, FIG. 39 is a schematic diagram after the pattern of the first conductive layer is formed in FIG. 7C. In an exemplary implementation mode, the first conductive layer may be referred to as a first gate metal (GATE1) layer.

In an exemplary implementation mode, as shown in FIGS. 16 to 18 and FIGS. 36 to 39, the pattern of the first conductive layer may at least include a gate electrode ET12 of a first light emitting transistor to a gate electrode ET102 of a tenth light emitting transistor and a first electrode plate EC11 of a first light emitting capacitor to a first electrode plate EC31 of a third light emitting capacitor located in a light emitting shift register, a gate electrode RT12 of a first release transistor and a gate electrode RT22 of a second release transistor located in an electrostatic release circuit, a gate electrode GT12 of a first scan transistor to a gate electrode GT82 of a scan light emitting transistor and a first electrode plate GC11 of a first scan capacitor and a first electrode plate GC21 of a second scan capacitor located in a scan shift register, a first signal connection line L1 and a second signal connection line L2, a reset signal line Reset, a scan signal line Gate, a light emitting signal line EM, a gate electrode M11 of a first transistor to a gate electrode M71 of a seventh transistor, and a first electrode plate C1 of a capacitor.

In an exemplary implementation mode, as shown in FIGS. 16 to 18, a gate electrode ET12 of a first light emitting transistor and a gate electrode ET32 of a third light emitting transistor are of an interconnected integral structure. A gate electrode ET22 of a second light emitting transistor, a gate electrode ET82 of an eighth light emitting transistor, a gate electrode ET102 of a tenth light emitting transistor, and a first electrode plate EC31 of a third light emitting capacitor are of an interconnected integral structure. A gate electrode ET52 of a fifth light emitting transistor, a gate electrode ET62 of a sixth light emitting transistor, and a first electrode plate EC11 of a first light emitting capacitor are of an interconnected integral structure. A gate electrode ET2 of a ninth light emitting transistor and a first electrode plate EC21 of a second light emitting capacitor are of an interconnected integral structure. A gate electrode ET42 of a fourth light emitting transistor and a gate electrode ET72 of a seventh light emitting transistor may be disposed separately.

In an exemplary implementation mode, as shown in FIGS. 16 to 18, in the second direction D2, the first electrode plate EC31 of the third light emitting capacitor is located on a side of the first electrode plate EC11 of the first light emitting capacitor close to the display region, the gate electrode ET22 of the second light emitting transistor is located on a side of the first electrode plate EC31 of the third light emitting capacitor away from the display region, the gate electrode ET102 of the tenth light emitting transistor is located on a side of the first electrode plate EC31 of the third light emitting capacitor close to the display region, the gate electrode ET92 of the ninth light emitting transistor is located on a side of the first electrode plate EC21 of the second light emitting capacitor close to the display region, the gate electrode ET52 of the fifth light emitting transistor is located on a side of the first electrode plate EC11 of the first light emitting capacitor away from the display region, and the gate electrode ET62 of the sixth light emitting transistor is located on a side of the first electrode plate EC11 of the first light emitting capacitor close to the display region. In the first direction D1, a gate electrode ET82 of an eighth light emitting transistor of a present-stage light emitting shift register is located on a side of a first electrode plate EC31 of a third light emitting capacitor close to a next-stage light emitting shift register. A first electrode plate EC11 of a first light emitting capacitor and the first electrode plate EC31 of the third light emitting capacitor of the present-stage light emitting shift register are located on a side of a first electrode plate EC21 of a second light emitting capacitor close to a previous-stage light emitting shift register.

In an exemplary implementation mode, as shown in FIGS. 16 to 18, the gate electrode ET12 of the first light emitting transistor, the gate electrode ET42 of the fourth light emitting transistor, the gate electrode ET52 of the fifth light emitting transistor, the gate electrode ET62 of the sixth light emitting transistor, and the gate electrode ET72 of the seventh light emitting transistor may be in a shape of a strip extending at least partially along the second direction D2.

In an exemplary implementation mode, as shown in FIGS. 16 to 18, the gate electrode ET22 of the second light emitting transistor may be in a shape of a rectangle, the gate electrode ET22 of the second light emitting transistor may be provided with an opening which may be in a shape of a rectangle, and the opening may be located in a middle of the gate electrode ET22 of the second light emitting transistor, so that the gate electrode ET22 of the second light emitting transistor forms an annular structure.

In an exemplary implementation mode, as shown in FIGS. 16 to 18, the gate electrode ET32 of the third light emitting transistor may be in a shape of an inverted “T”.

In an exemplary implementation mode, as shown in FIGS. 16 to 18, the gate electrode ET82 of the eighth light emitting transistor may be in a shape of a strip extending at least partially along the first direction D1, and may be in a shape of a polyline.

In an exemplary implementation mode, as shown in FIGS. 16 to 18, a shape of the gate electrode ET92 of the ninth light emitting transistor may include a first connection section extending along the first direction D1 and a plurality of first branch sections extending along the second direction D2, the first connection section is connected with a first electrode plate of a second capacitor, a first branch section is located at a side of the first connection section close to the display region, the gate electrode ET92 of the ninth light emitting transistor may be in a shape of a comb, with the first connection section serving as a back of the comb and the first branch sections serving as teeth of the comb.

In an exemplary implementation mode, as shown in FIGS. 16 to 18, a shape of the gate electrode ET102 of the tenth light emitting transistor may include a plurality of second branch sections extending along the second direction D2, the plurality of second branch sections and the first electrode plate EC31 of the third light emitting capacitor may have a structure of a comb, with the first electrode plate of the third light emitting capacitor serving as a back of the comb, and the plurality of second branch sections serving as teeth of the comb.

In an exemplary implementation mode, as shown in FIGS. 16 to 18, the first electrode plate EC11 of the first light emitting capacitor may be in a shape of a strip extending at least partially along the first direction D1, and is provided with a protrusion on a side away from the display region.

In an exemplary implementation mode, as shown in FIGS. 16 to 18, the first electrode plate EC21 of the second light emitting capacitor may be in a shape of a strip extending along the second direction D2.

In an exemplary implementation mode, as shown in FIGS. 16 to 18, the first electrode plate EC31 of the third light emitting capacitor may be in a shape of a strip extending along the first direction D1.

In an exemplary implementation mode, as shown in FIGS. 16 to 18, the gate electrode ET12 of the first light emitting transistor is disposed across a channel region of an active layer of the first light emitting transistor, the gate electrode ET22 of the second light emitting transistor is disposed across a channel region of an active layer of the second light emitting transistor, the gate electrode ET32 of the third light emitting transistor is disposed across a channel region of an active layer of the third light emitting transistor, the gate electrode ET42 of the fourth light emitting transistor is disposed across a channel region of an active layer of the fourth light emitting transistor, two first branch sections ET55 of the gate electrode ET52 of the fifth light emitting transistor are disposed across a channel region of an active layer of the fifth light emitting transistor, the gate electrode ET62 of the sixth light emitting transistor is disposed across a channel region of the active layer of the first light emitting transistor, the gate electrode ET72 of the seventh light emitting transistor is disposed across a channel region of an active layer of the seventh light emitting transistor, and the gate electrode ET82 of the eighth light emitting transistor is disposed across a channel region of an active layer of the eighth light emitting transistor, a plurality of first branch sections of the gate electrode ET92 of the ninth light emitting transistor are disposed across a channel region of an active layer of the ninth light emitting transistor, and the gate electrode ET102 of the tenth light emitting transistor is disposed across a channel region of an active layer of the tenth light emitting transistor, that is to say, an extension direction of a gate electrode of at least one light emitting transistor is perpendicular to an extension direction of a channel region of an active layer.

In an exemplary implementation mode, as shown in FIGS. 16 to 18, since the gate electrode ET22 of the second light emitting transistor has an annular structure, the second light emitting transistor has a double-gate structure.

In an exemplary implementation mode, as shown in FIGS. 16 to 18, the gate electrode RT12 of the first release transistor and the gate electrode RT22 of the second release transistor may be in a shape of a strip extending along the first direction D1.

In an exemplary implementation mode, as shown in FIGS. 16 to 18, the gate electrode RT12 of the first release transistor is disposed across a channel region of an active layer of the first transistor, and the gate electrode RT22 of the second release transistor is disposed across a channel region of the active layer of the second transistor, that is to say, an extension direction of a gate electrode of at least one release transistor is perpendicular to an extension direction of an active layer.

In an exemplary implementation mode, as shown in FIGS. 16 to 18, the gate electrode GT12 of the first scan transistor and the gate electrode GT32 of the third scan transistor are of an interconnected integral structure. The gate electrode GT42 of the fourth scan transistor, the gate electrode GT62 of the sixth scan transistor, and the first electrode plate GC31 of the first scan capacitor are of an interconnected integral structure. The gate electrode GT52 of the fifth scan transistor and the first electrode plate EC21 of the second scan capacitor are of an interconnected integral structure. The gate electrode GT22 of the second scan transistor, the gate electrode GT72 of the seventh scan transistor, and the gate electrode GT82 of the eighth scan transistor may be disposed separately.

In an exemplary implementation mode, as shown in FIGS. 16 to 18, in the second direction D2, the first electrode plate GC11 of the first scan capacitor is located at a side of the first electrode plate GC21 of the second scan capacitor away from the display region, the gate electrode GT52 of the fifth scan transistor is located at a side of the first electrode plate EC21 of the second scan capacitor away from the display region, the gate electrode GT42 of the fourth scan transistor is located at a side of the first electrode plate GC31 of the first scan capacitor close to the display region, and the gate electrode GT62 of the sixth scan transistor is located at a side of the first electrode plate GC31 of the first scan capacitor away from the display region.

In an exemplary implementation mode, as shown in FIGS. 16 to 18, a shape of the gate electrode GT12 of the first scan transistor may include a second connection section and two third branch sections, the third branch sections are located at a side of the second connection section away from the display region, the second connection section is connected with the gate electrode GT32 of the third scan transistor. Among them, the two branch sections have different lengths.

In an exemplary implementation mode, as shown in FIGS. 16 to 18, a shape of the gate electrode GT22 of the second scan transistor may include a gate main body portion extending along the second direction D2 and a gate connection portion extending along the first direction D1.

In an exemplary implementation mode, as shown in FIGS. 16 to 18, the gate electrode GT32 of the third scan transistor, the gate electrode GT42 of the fourth scan transistor, the gate electrode GT62 of the sixth scan transistor, the gate electrode GT72 of the seventh scan transistor, and the gate electrode GT82 of the eighth scan transistor may be in a shape of a strip extending at least partially along the second direction D2.

In an exemplary implementation mode, as shown in FIGS. 16 to 18, a shape of the gate electrode GT52 of the fifth scan transistor may include a plurality of fourth branch sections extending along the second direction D2, the gate electrode GT52 of the fifth scan transistor may be in a shape of a comb, with the first electrode plate GC21 of the second scan capacitor serving as a back of the comb, and the plurality of fourth branch sections serving as teeth of the comb.

In an exemplary implementation mode, as shown in FIGS. 16 to 18, the first electrode plate GC11 of the first scan capacitor may be in a shape of a strip extending at least partially along the second direction D2.

In an exemplary implementation mode, as shown in FIGS. 16 to 18, the first electrode plate ECG1 of the second scan capacitor may be in a shape of a strip extending along the first direction D1.

In an exemplary implementation mode, as shown in FIGS. 16 to 18, two third branch sections of the gate electrode GT12 of the first scan transistor are disposed across a channel region of the active layer of the first scan transistor, the gate connection portion of the gate electrode GT22 of the second scan transistor is disposed across a channel region of the active layer of the second scan transistor, the gate electrode GT32 of the third scan transistor is disposed across a channel region of the active layer of the third scan transistor, the gate electrode GT42 of the fourth scan transistor is disposed across a channel region of the active layer of the fourth scan transistor, two first branch sections GT55 of the gate electrode GT52 of the fifth scan transistor are disposed across a channel region of the active layer of the fifth scan transistor, the gate electrode GT62 of the sixth scan transistor is disposed across a channel region of the active layer of the first scan transistor, the gate electrode GT72 of the seventh scan transistor is disposed across a channel region of the active layer of the seventh scan transistor, and the gate electrode GT82 of the eighth scan transistor is disposed across a channel region of the active layer of the eighth scan transistor, that is to say, an extension direction of a gate electrode of at least one scan transistor is perpendicular to an extension direction of a channel region of an active layer.

In an exemplary implementation mode, as shown in FIGS. 16 to 18, two third branch sections of the gate electrode GT12 of the first scan transistor are disposed across the channel region of the active layer of the first scan transistor, and the first scan transistor has a double-gate structure.

In an exemplary implementation mode, as shown in FIGS. 16 and 17, the first signal connection line L1 and the second signal connection line L2 may extend at least partially along the second direction D2.

In an exemplary implementation mode, as shown in FIG. 36 to FIG. 39, the first electrode plate C1 of the capacitor may be in a shape of a rectangle, corners of the rectangle may be provided with chamfers, and an orthographic projection of the first electrode plate C1 of the capacitor on the base substrate is at least partially overlapped with an orthographic projection of an active layer of a third transistor on the base substrate. In an exemplary implementation mode, the first electrode plate C1 of the capacitor may simultaneously serve as a gate electrode M32 of the third transistor.

In an exemplary implementation mode, as shown in FIGS. 36 to 39, the reset signal line Reset may be in a shape of a line in which a main body portion extends along the second direction D2. A reset signal line Reset connected with a present row of sub-pixels may be located at a side of a first electrode plate C1 of a present sub-pixel close to a previous row of sub-pixels. A region where the reset signal line Reset is overlapped with an active layer of a first transistor serves as a gate electrode MT12 of the first transistor with a double-gate structure.

In an exemplary implementation mode, as shown in FIGS. 36 to 39, the scan signal line Gate may be in a shape of a line in which a main body portion extends along the second direction D2. A scan signal line Gate connected with a present row of sub-pixels may be located at a side of a reset signal line Reset connected with a present sub-pixel close to a first electrode plate C1, a region where the scan signal line Gate is overlapped with an active layer of a second transistor of the present sub-pixel serves as a gate electrode MT22 of the second transistor with a double-gate structure, and a region where the scan signal line Gate is overlapped with an active layer of a fourth transistor serves as a gate electrode MT42 of the fourth transistor.

In an exemplary implementation mode, as shown in FIGS. 36 to 39, the scan signal line Gate includes a signal main body portion 21 and a signal connection portion 22. One end of the signal connection portion 22 is electrically connected with the signal main body portion 21. The signal main body portion 21 extends along the second direction D2, and the signal connection portion 22 extends along the first direction D1.

In an exemplary implementation mode, as shown in FIGS. 36 and 37, the signal connection portion 22 is located on a side of the signal main body portion 21 close to the first electrode plate of the capacitor.

In an exemplary implementation mode, as shown in FIGS. 38 and 39, the signal connection portion 22 is located on a side of the signal main body portion 21 away from the first electrode plate of the capacitor.

In an exemplary implementation mode, the light emitting signal line EM may be in a shape of a line in which a main body portion extends along the second direction D2, the light emitting signal line EM may be located at a side of a first electrode plate C1 of a capacitor of a present sub-pixel close to a next row of sub-pixels, a region where the light emitting signal line EM is overlapped with an active layer of a fifth transistor of the present sub-pixel serves as a gate electrode MT52 of the fifth transistor, and a region where the light emitting signal line EM is overlapped with an active layer of a sixth transistor of the present sub-pixel serves as a gate electrode MT62 of the sixth transistor.

In an exemplary implementation mode, the reset signal line Reset, the scan signal line Gate, and the light emitting signal line EM may be designed with equal widths, or may be designed with unequal widths, may be straight lines, or may be polylines, which may not only facilitate a layout of a pixel structure, but also reduce parasitic capacitance between signal lines, which is not limited here in the present disclosure.

In an exemplary implementation mode, after the pattern of the first conductive layer is formed, the semiconductor layer may be subjected to a conductive treatment by using the first conductive layer as a shield. The semiconductor layer, in a region which is shielded by the first conductive layer, forms channel regions of the first light emitting transistor to the tenth light emitting transistor, channel regions of the first release transistor to the second release transistor, and channel regions of the first scan transistor to the eighth scan transistor, and the semiconductor layer, in a region which is not shielded by the first conductive layer, is made be conductive, that is, first and second regions of active layers of the first light emitting transistor to the tenth transistor, first and second regions of active layers of the first release transistor to the second release transistor, and first and second regions of active layers of the first scan transistor to the eighth scan transistor are all made be conductive. In an exemplary implementation mode, as shown in FIGS. 16 and 17, a first region of the active layer of the fourth light emitting transistor (which is also a second region of the active layer of the fifth light emitting transistor) is multiplexed as a first electrode of the fourth light emitting transistor (which is also a second electrode of the fifth light emitting transistor), a second region of the active layer of the sixth transistor (which is also a first region of the active layer of the seventh scan transistor) is multiplexed as a second electrode of the sixth scan transistor (which is also a first electrode of the seventh scan transistor), a second region of the active layer of the second transistor (also a second region of the active layer of the third transistor and a first region of the active layer of the sixth transistor) is multiplexed as a second electrode of the second transistor (which is also a second electrode of the third transistor and a first electrode of the sixth transistor), and a first region of the active layer of the third transistor (which is also a second region of the active layer of the fourth transistor and a second electrode of the active layer of the fifth transistor) is multiplexed as a first electrode of the third transistor (also a second electrode of the fourth transistor and a second electrode of the fifth transistor).

(3) Forming a pattern of a second insulation layer, includes: in an exemplary implementation mode, forming a pattern of a second insulation layer may include: depositing a second insulation thin film on the base substrate on which the above-mentioned patterns are formed, patterning the second insulation thin film using a patterning process to form a second insulation layer covering the first conductive layer, wherein the second insulation layer is provided with a via, as shown in FIG. 19, FIG. 19 is a schematic diagram of the display substrate provided in FIG. 6A after a pattern of a second insulation layer is formed.

In an exemplary implementation mode, the via includes at least a via V0 located in at least the electrostatic release circuit. An orthographic projection of the via V0 on the base substrate is located within a range of an orthogonal projection of an active connection portion on the base substrate, a surface of the active connection portion is exposed, and the via V0 is configured such that a light emitting output signal line formed subsequently is connected with the active connection portion through the via.

In an exemplary implementation mode, the second insulation layer is also formed in FIGS. 5A, 7B, and 7C, but no via is disposed on the second insulation layer.

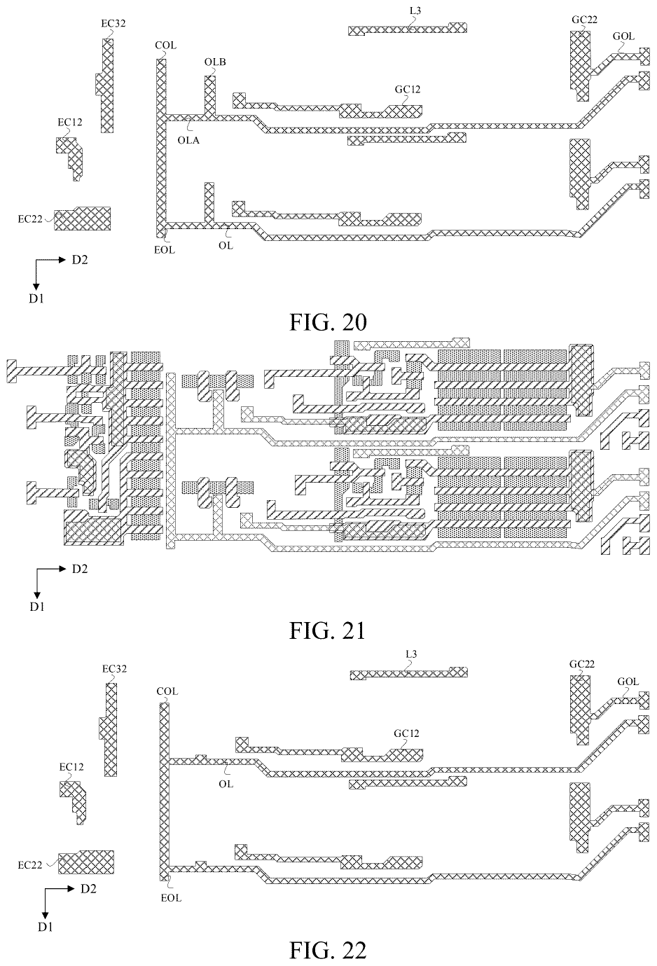

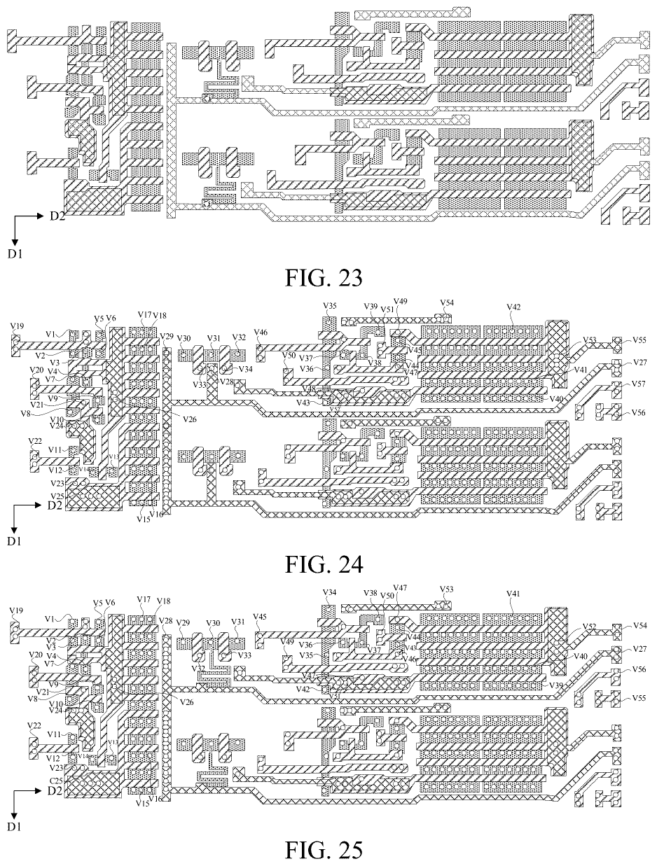

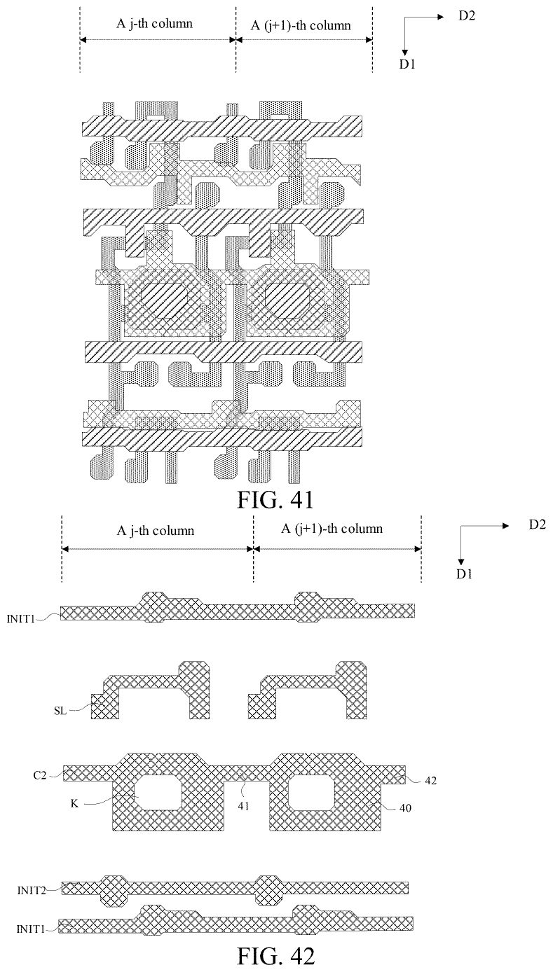

(4) Forming a pattern of a second conductive layer, including: depositing a second conductive thin film on the base substrate on which the above-mentioned patterns are formed, patterning the second conductive thin film through a patterning process to form a pattern of a second conductive layer located on the pattern of the second insulation layer, as shown in FIGS. 20 to 23 and FIGS. 40 to 43, FIG. 20 is a schematic diagram of a pattern of a second conductive layer in FIG. 5A, FIG. 21 is a schematic diagram after the pattern of the second conductive layer is formed in FIG. 5A, FIG. 22 is a schematic diagram of a second conductive layer in FIG. 6A, FIG. 23 is a schematic diagram after the pattern of the second conductive layer is formed in FIG. 6A, FIG. 40 is a schematic diagram of a pattern of a second conductive layer in FIG. 7B, FIG. 41 is a schematic diagram after the pattern of the second conductive layer is formed in FIG. 7B, FIG. 42 is a schematic diagram of a pattern of a second conductive layer in FIG. 7C, and FIG. 43 is a schematic diagram after the pattern of the second conductive layer is formed in FIG. 7C. In an exemplary implementation mode, the second conductive layer may be referred to as a second gate metal (GATE2) layer.

In an exemplary implementation mode, as shown in FIGS. 20 to 23 and FIGS. 40 to 43, the pattern of the second conductive layer may include at least the second electrode plate EC12 of the first light emitting capacitor to the second electrode plate EC32 of the third light emitting capacitor located in the light emitting shift register, the first electrode plate GC12 of the first scan capacitor and the second electrode plate GC22 of the second scan capacitor located in the scan shift register, the second electrode plate C2 of the capacitor located in the pixel circuit, the scan signal output line GOL, the light emitting signal output line EOL, a third signal connection line L3, the first initial signal line INIT1, and the second initial signal line INIT2.

In an exemplary implementation mode, as shown in FIGS. 42 and 43, the pattern of the second conductive layer may further include a shielding electrode SL.

In an exemplary implementation mode, as shown in FIGS. 20 to 23, an orthographic projection of the second electrode plate EC12 of the first light emitting capacitor on the base substrate is at least partially overlapped with an orthographic projection of the first electrode plate of the first light emitting capacitor on the base substrate. An orthographic projection of the second electrode plate EC22 of the second light emitting capacitor on the base substrate is at least partially overlapped with an orthographic projection of the first electrode plate of the second light emitting capacitor on the base substrate. An orthographic projection of the second electrode plate EC32 of the third light emitting capacitor on the base substrate is at least partially overlapped with an orthographic projection of the first electrode plate of the third light emitting capacitor on the base substrate.

In an exemplary implementation mode, as shown in FIGS. 20 to 23, the scan output signal line GOL and the second electrode plate GC22 of the second scan capacitor are of an interconnected integral structure, and are located on a side of the second electrode plate GC22 of the second scan capacitor close to the display region.

In an exemplary implementation mode, as shown in FIGS. 20 to 23, an orthographic projection of the second electrode plate GC12 of the first scan capacitor on the base substrate is at least partially overlapped with an orthographic projection of the first electrode plate of the first scan capacitor on the base substrate. An orthographic projection of the second electrode plate GC 22 of the second scan capacitor on the base substrate is at least partially overlapped with an orthographic projection of the first electrode plate of the second scan capacitor on the base substrate.

In an exemplary implementation mode, as shown in FIGS. 20 to 23, the scan output signal line GOL extends at least partially along the second direction D2.

In an exemplary implementation mode, as shown in FIGS. 20 to 23, the third signal connection line L3 is in a shape of a strip extending along the second direction D2.

In an exemplary implementation mode, as shown in FIGS. 20 to 23, the light emitting output signal line may include an output connection portion COL and at least one output line OL connected. A plurality of output lines OL are arranged along the first direction D1. At least one output line OL is located at a side of the output connection portion COL close to the display region.

In an exemplary implementation mode, as shown in FIGS. 20 to 23, the output connection portion COL extends along the first direction D1, and the output line OL extends at least partially along the second direction D2.

In an exemplary implementation mode, as shown in FIGS. 20 and 21, the output line OL in FIG. 5A includes an output main body portion OLA and an output connection portion OLB, and the output main body portion OLA and the output connection portion OLB are of an interconnected integral structure.

In an exemplary implementation mode, as shown in FIGS. 20 and 21, the output main body portion OLA extends along the second direction D2, and the output connection portion OLB extends along the first direction D1.

In an exemplary implementation mode, as shown in FIGS. 22 and 23, an orthographic projection of the output line OL in FIG. 6A on the base substrate is at least partially overlapped with an orthographic projection of the active connection portion on the base substrate, and the output line OL is connected with the active connection portion through a via.

In an exemplary implementation mode, as shown in FIGS. 40 to 43, second electrode plates C2 of capacitors of adjacent sub-pixels located in a same row are electrically connected.

In an exemplary implementation mode, as shown in FIGS. 40 and 41, the second electrode plate C2 of the capacitor includes a capacitor main body portion 50, a first capacitor connection portion 51, a second capacitor connection portion 52, and a third capacitor connection portion 53. In the second direction D2, the first capacitor connection portion 51 and the second capacitor connection portion 52 are located on two sides of the capacitor main body portion 50, respectively, and in the first direction D1, the third capacitor connection portion 53 is located on a side of the capacitor main body portion 50 close to the first initial signal line.

In an exemplary implementation mode, as shown in FIGS. 40 and 41, a contour of the capacitor main body portion 50 may be in a shape of a rectangle, corners of the rectangle may be provided with chamfers, and an orthographic projection of the capacitor main body portion 50 on the base substrate is at least partially overlapped with an orthographic projection of the first electrode plate of the capacitor on the base substrate. The capacitor main body portion 50 is provided with an opening K, the opening K may have any shape, and may be located in a middle of the capacitor main body portion 50, so that the capacitor main body portion 50 forms an annular structure. The opening K exposes the third insulation layer covering the first electrode plate, and an orthographic projection of the first electrode plate on the base substrate contains an orthographic projection of the opening K on the base substrate. In an exemplary implementation mode, the opening K is configured to expose the first electrode plate of the capacitor so that a second electrode of a first transistor (also a first electrode of a second transistor) formed subsequently is connected with the first electrode plate of the capacitor.

In an exemplary implementation mode, as shown in FIGS. 40 and 41, a first capacitor connection portion of a present sub-pixel is electrically connected with a second capacitor connection portion of one of adjacent sub-pixels located in a same row, and a second capacitor connection portion of the present sub-pixel is electrically connected with a first capacitor connection portion of another adjacent sub-pixel located in a same row.

In an exemplary implementation mode, as shown in FIGS. 40 and 41, an orthographic projection of the third capacitor connection portion on the base substrate is at least partially overlapped with an orthographic projection of the capacitor of the second transistor on the base substrate.

In an exemplary implementation mode, as shown in FIGS. 40 and 41, the first initial signal line INIT1 may be located at a side of a second electrode plate C2 of a capacitor of a present sub-pixel close to a previous row of sub-pixels. An orthographic projection of the first initial signal line INIT1 on the base substrate is located between an orthographic projection of the reset signal line on the base substrate and an orthographic projection of the scan signal line on the base substrate.

In an exemplary implementation mode, as shown in FIGS. 40 and 41, the first initial signal line INIT1 includes an initial signal main body portion 41, a first initial connection block 42, and a second initial connection block 43. The first initial connection block 42 and the second initial connection block 43 are electrically connected with the initial signal main body portion 41, respectively. The first initial connection block 42 is located on a side of the initial signal main body portion 41 away from the second electrode plate of the capacitor, and the second initial connection block 43 is located on a side of the initial signal main body portion 41 close to the second electrode plate C2 of the capacitor. The initial signal main body portion 41 may be in a shape of a line extending along the second direction D2. The first initial connection block 42 and the second initial connection block 43 may be equivalent to shielding electrodes configured to effectively shield an influence of a data voltage jump on a key node in the pixel circuit, avoid an influence of the data voltage jump on a potential of a key node in a pixel drive circuit, and improve a display effect.

In an exemplary implementation mode, as shown in FIGS. 40 and 41, the second initial signal line INIT2 may be in a shape of a line extending along the second direction D2, and a second initial signal line INIT2 connected with a present row of sub-pixels may be located at a side of a second electrode plate of a capacitor of a present sub-pixel close to a next row of sub-pixels. An orthographic projection of the second initial signal line INIT2 connected with the present row of sub-pixels on the base substrate is located between an orthographic projection of a light emitting signal line connected with the present row of sub-pixels on the base substrate and an orthographic projection of a reset signal line connected with the next row of sub-pixels on the base substrate.

In an exemplary implementation mode, as shown in FIGS. 42 and 43, the second electrode plate C2 of the capacitor includes a capacitor main body portion 50, a first capacitor connection portion 51, and a second capacitor connection portion 52. In the second direction D2, the first capacitor connection portion 51 and the second capacitor connection portion 52 are located on two sides of the capacitor main body portion 50, respectively.

In an exemplary implementation mode, as shown in FIGS. 42 and 43, a contour of the capacitor main body portion 50 may be in a shape of a rectangle, corners of the rectangle may be provided with chamfers, and an orthographic projection of the capacitor main body portion 50 on the base substrate is at least partially overlapped with an orthographic projection of the first electrode plate of the capacitor on the base substrate. The capacitor main body portion 50 is provided with an opening K, the opening K may have any shape, and may be located in a middle of the capacitor main body portion 50, so that the capacitor main body portion 50 forms an annular structure. The opening K exposes the third insulation layer covering the first electrode plate, and an orthographic projection of the first electrode plate on the base substrate contains an orthographic projection of the opening K on the base substrate. In an exemplary implementation mode, the opening K is configured to expose the first electrode plate of the capacitor, so that a second electrode of a first transistor (also a first electrode of a second transistor) formed subsequently is connected with the first electrode plate of the capacitor.

In an exemplary implementation mode, as shown in FIGS. 42 and 43, a first capacitor connection portion of a present sub-pixel is electrically connected with a second capacitor connection portion of one of adjacent sub-pixels located in a same row, and a second capacitor connection portion of the present sub-pixel is electrically connected with a first capacitor connection portion of another adjacent sub-pixel located in a same row.

In an exemplary implementation mode, as shown in FIGS. 42 and 43, the first initial signal line INIT1 may be in a shape of a line extending along the second direction D2, and the first initial signal line INIT1 may be located at a side of a second electrode plate C2 of a capacitor of a present sub-pixel close to a previous row of sub-pixels. An orthographic projection of the first initial signal line INIT1 on the base substrate is located at a side of an orthographic projection of the reset signal line on the base substrate away from an orthographic projection of the scan signal line on the base substrate.

In an exemplary implementation mode, as shown in FIGS. 42 and 43, the shielding electrode SL may be in an “n” shape. The shielding electrode SL is located between the first initial signal line INT1 and the second electrode plate C2 of the capacitor. An orthographic projection of the shielding electrode SL on the base substrate is at least partially overlapped with orthographic projections of the active layer of the first transistor and the active layer of the second transistor on the base substrate, and is located between an orthographic projection of the reset signal line on the base substrate and an orthographic projection of the scan signal line on the base substrate. The shielding electrode is configured to effectively shield an influence of a data voltage jump on a key node in the pixel circuit, avoid an influence of the data voltage jump on a potential of a key node in the pixel drive circuit, and improve a display effect.

In an exemplary implementation mode, as shown in FIGS. 42 and 43, the second initial signal line INIT2 may be in a shape of a line extending along the second direction D2, and a second initial signal line INIT2 connected with a present row of sub-pixels may be located at a side of a second electrode plate C2 of a capacitor close to a next row of sub-pixels. An orthographic projection of the second initial signal line INIT2 connected with the present row of sub-pixels on the base substrate is between an orthographic projection of a scan signal line connected with the present row of sub-pixels on the base substrate and an orthographic projection of a first initial signal line connected with the next row of sub-pixels on the base substrate.

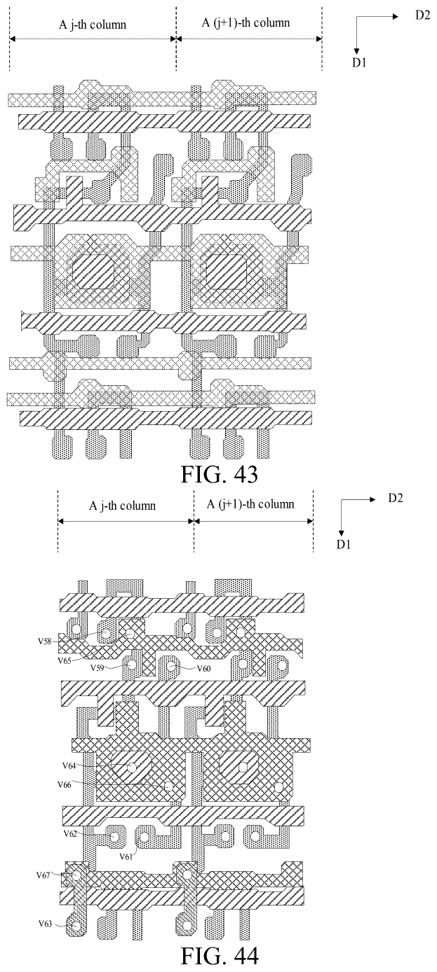

(5) Forming a pattern of a third insulation layer, including: depositing a third insulation thin film on the base substrate on which the above-mentioned patterns are formed, and patterning the third insulation thin film through a patterning process to form a pattern of a third insulation layer covering the above-mentioned structures, wherein the third insulation layer is provided with patterns of a plurality of vias, as shown in FIGS. 24, 25, 44, and 45, FIG. 24 is a schematic diagram after a pattern of a third insulation layer is formed in FIG. 5A, FIG. 25 is a schematic diagram after a pattern of a third insulation layer is formed in FIG. 6A, FIG. 44 is a schematic diagram after a pattern of a third insulation layer is formed in FIG. 7B, and FIG. 45 is a schematic diagram after a pattern of a third insulation layer is formed in FIG. 7C.

In an exemplary implementation mode, as shown in FIG. 24, patterns of the plurality of vias in FIG. 5A may include at least a first via V1 to a fifty-seventh via V57.

In an exemplary implementation mode, as shown in FIG. 24, an orthographic projection of the first via V1 on the base substrate is within a range of an orthographic projection of the first region of the active layer of the first light emitting transistor on the base substrate, the first insulation layer and the second insulation layer within the first via V1 are etched away to expose a surface of the first region of the active layer of the first light emitting transistor, and the first via V1 is configured such that a first electrode of a first light emitting transistor formed subsequently is connected with the first region of the active layer of the first light emitting transistor through the via.

In an exemplary implementation mode, as shown in FIG. 24, an orthographic projection of the second via V2 on the base substrate is within a range of an orthographic projection of the second region of the active layer of the first light emitting transistor on the base substrate, the first insulation layer and the second insulation layer within the second via V2 are etched away to expose a surface of the second region of the active layer of the first light emitting transistor, and the second via V2 is configured such that a second electrode of a first light emitting transistor (which is also a second electrode of a fourth light emitting transistor) formed subsequently is connected with the second region of the active layer of the first light emitting transistor through the via.

In an exemplary implementation mode, as shown in FIG. 24, an orthographic projection of the third via V3 on the base substrate is within a range of an orthographic projection of the first region of the active layer of the second light emitting transistor on the base substrate, the first insulation layer and the second insulation layer within the third via V3 are etched away to expose a surface of the first region of the active layer of the second light emitting transistor, and the third via V3 is configured such that a first electrode of a second light emitting transistor formed subsequently is connected with the first region of the active layer of the second light emitting transistor through the via.

In an exemplary implementation mode, as shown in FIG. 24, an orthographic projection of the fourth via V4 on the base substrate is within a range of an orthographic projection of the second region of the active layer of the second light emitting transistor on the base substrate, the first insulation layer and the second insulation layer within the fourth via V4 are etched away to expose a surface of the second region of the active layer of the second light emitting transistor, and the fourth via V4 is configured such that a second electrode of a second light emitting transistor (which is also a second electrode of a third light emitting transistor) formed subsequently is connected with the second region of the active layer of the second light emitting transistor through the via.

In an exemplary implementation mode, as shown in FIG. 24, an orthographic projection of the fifth via V5 on the base substrate is within a range of an orthographic projection of the first region of the active layer of the third light emitting transistor on the base substrate, the first insulation layer and the second insulation layer within the fifth via V5 are etched away to expose a surface of the first region of the active layer of the third light emitting transistor, and the fifth via V5 is configured such that a first electrode of a third light emitting transistor (which is also a first electrode of a tenth light emitting transistor) formed subsequently is connected with the first region of the active layer of the third light emitting transistor through the via.

In an exemplary implementation mode, as shown in FIG. 24, an orthographic projection of the sixth via V6 on the base substrate is within a range of an orthographic projection of the second region of the active layer of the third light emitting transistor on the base substrate, the first insulation layer and the second insulation layer within the sixth via V6 are etched away to expose a surface of the second region of the active layer of the third light emitting transistor, and the sixth via V6 is configured such that a second electrode of a second light emitting transistor (which is also a second electrode of a third light emitting transistor) formed subsequently is connected with the second region of the active layer of the third light emitting transistor through the via.

In an exemplary implementation mode, as shown in FIG. 24, an orthographic projection of the seventh via V7 on the base substrate is within a range of an orthographic projection of the second region of the active layer of the fourth light emitting transistor on the base substrate, the first insulation layer and the second insulation layer within the seventh via V7 are etched away to expose a surface of the second region of the active layer of the fourth light emitting transistor, and the seventh via V7 is configured such that a second electrode of a first light emitting transistor (which is also a second electrode of a fourth light emitting transistor) formed subsequently is connected with the second region of the active layer of the fourth light emitting transistor through the via.

In an exemplary implementation mode, as shown in FIG. 24, an orthographic projection of the eighth via V8 on the base substrate is within a range of an orthographic projection of the first region of the active layer of the fifth light emitting transistor on the base substrate, the first insulation layer and the second insulation layer within the eighth via V8 are etched away to expose a surface of the first region of the active layer of the fifth light emitting transistor, and the eighth via V8 is configured such that a first electrode of a fifth light emitting transistor formed subsequently is connected with the first region of the active layer of the fifth light emitting transistor through the via.

In an exemplary implementation mode, as shown in FIG. 24, an orthographic projection of the ninth via V9 on the base substrate is within a range of an orthographic projection of the first region of the active layer of the sixth light emitting transistor on the base substrate, the first insulation layer and the second insulation layer within the ninth via V9 are etched away to expose a surface of the first region of the active layer of the sixth light emitting transistor, and the ninth via V9 is configured such that a first electrode of a sixth light emitting transistor formed subsequently is connected with the first region of the active layer of the sixth light emitting transistor through the via.

In an exemplary implementation mode, as shown in FIG. 24, an orthographic projection of the tenth via V10 on the base substrate is within a range of an orthographic projection of the second region of the active layer of the sixth light emitting transistor on the base substrate, the first insulation layer and the second insulation layer within the tenth via V10 are etched away to expose a surface of the second region of the active layer of the sixth light emitting transistor, and the tenth via V10 is configured such that a second electrode of a sixth light emitting transistor (which is also a first electrode of a seventh light emitting transistor) formed subsequently is connected with the second region of the active layer of the sixth light emitting transistor through the via.

In an exemplary implementation mode, as shown in FIG. 24, an orthographic projection of the eleventh via V11 on the base substrate is within a range of an orthographic projection of the first region of the active layer of the seventh light emitting transistor on the base substrate, the first insulation layer and the second insulation layer within the eleventh via V11 are etched away to expose a surface of the first region of the active layer of the seventh light emitting transistor, and the eleventh via V11 is configured such that a second electrode of a sixth light emitting transistor (which is also a first electrode of a seventh light emitting transistor) formed subsequently is connected with the first region of the active layer of the seventh light emitting transistor through the via.

In an exemplary implementation mode, as shown in FIG. 24, an orthographic projection of the twelfth via V12 on the base substrate is within a range of an orthographic projection of the second region of the active layer of the seventh light emitting transistor on the base substrate, the first insulation layer and the second insulation layer within the twelfth via V12 are etched away to expose a surface of the second region of the active layer of the seventh light emitting transistor, and the twelfth via V12 is configured such that a second electrode of a seventh light emitting transistor (also a second electrode of an eighth light emitting transistor) formed subsequently is connected with the second region of the active layer of the seventh light emitting transistor through the via.

In an exemplary implementation mode, as shown in FIG. 24, an orthographic projection of the thirteenth via V13 on the base substrate is within a range of an orthographic projection of the first region of the active layer of the eighth light emitting transistor on the base substrate, the first insulation layer and the second insulation layer within the thirteenth via V13 are etched away to expose a surface of the first region of the active layer of the eighth light emitting transistor, and the thirteenth via V13 is configured such that a first electrode of an eighth light emitting transistor (which is also a first electrode of the ninth light emitting transistor) formed subsequently is connected with the first region of the active layer of the eighth light emitting transistor through the via.

In an exemplary implementation mode, as shown in FIG. 24, an orthographic projection of the fourteenth via V14 on the base substrate is within a range of an orthographic projection of the second region of the active layer of the eighth light emitting transistor on the base substrate, the first insulation layer and the second insulation layer within the fourteenth via V14 are etched away to expose a surface of the second region of the active layer of the eighth light emitting transistor, and the fourteenth via V14 is configured such that a second electrode of a seventh light emitting transistor (which is also a second electrode of an eighth light emitting transistor) formed subsequently is connected with the second region of the active layer of the eighth light emitting transistor through the via.

In an exemplary implementation mode, as shown in FIG. 24, an orthographic projection of the fifteenth via V15 on the base substrate is within a range of an orthographic projection of the first region of the active layer of the ninth light emitting transistor on the base substrate, the first insulation layer and the second insulation layer within the fifteenth via V15 are etched away to expose a surface of the first region of the active layer of the ninth light emitting transistor, and the fifteenth via V15 is configured such that a first electrode of an eighth light emitting transistor (which is also a first electrode of a ninth light emitting transistor) formed subsequently is connected with the first region of the active layer of the ninth light emitting transistor through the via.

In an exemplary implementation mode, as shown in FIG. 24, an orthographic projection of the sixteenth via V16 on the base substrate is within a range of an orthographic projection of the second region of the active layer of the ninth light emitting transistor on the base substrate, the first insulation layer and the second insulation layer within the sixteenth via V16 are etched away to expose a surface of the second region of the active layer of the ninth light emitting transistor, and the sixteenth via V16 is configured such that a second electrode of a ninth light emitting transistor formed subsequently is connected with the second region of the active layer of the ninth light emitting transistor through the via.

In an exemplary implementation mode, as shown in FIG. 24, an orthographic projection of the seventeenth via V17 on the base substrate is within a range of an orthographic projection of the first region of the active layer of the tenth light emitting transistor on the base substrate, the first insulation layer and the second insulation layer within the seventeenth via V17 are etched away to expose a surface of the first region of the active layer of the tenth light emitting transistor, and the seventeenth via V17 is configured such that a first electrode of a tenth light emitting transistor formed subsequently is connected with the first region of the active layer of the tenth light emitting transistor through the via.

In an exemplary implementation mode, as shown in FIG. 24, an orthographic projection of the eighteenth via V18 on the base substrate is within a range of an orthographic projection of the second region of the active layer of the tenth light emitting transistor on the base substrate, the first insulation layer and the second insulation layer within the eighteenth via V18 are etched away to expose a surface of the second region of the active layer of the tenth light emitting transistor, and the eighteenth via V18 is configured such that a second electrode of a tenth light emitting transistor formed subsequently is connected with the second region of the active layer of the tenth light emitting transistor through the via.

In an exemplary implementation mode, as shown in FIG. 24, an orthographic projection of the nineteenth via V19 on the base substrate is within a range of an orthographic projection of the gate electrode of the first light emitting transistor (also the gate electrode of the third light emitting transistor) on the base substrate, the second insulation layer within the nineteenth via V19 is etched away to expose a surface of the gate electrode of the first light emitting transistor (also the gate electrode of the third light emitting transistor), and the nineteenth via V19 is configured such that a first electrode of a second light emitting transistor formed subsequently and one of a first light emitting clock signal line and a second light emitting clock signal line that are formed subsequently are connected with a gate electrode of the first light emitting transistor (also the gate electrode of the third light emitting transistor) through the via.

In an exemplary implementation mode, as shown in FIG. 24, an orthographic projection of the twentieth via V20 on the base substrate is within a range of an orthographic projection of the gate electrode of the fourth light emitting transistor on the base substrate, the second insulation layer within the twentieth via V20 is etched away to expose a surface of the gate electrode of the fourth light emitting transistor, and the twentieth via V20 is configured such that the other of the first light emitting clock signal line and the second light emitting clock signal line that are formed subsequently is connected with the gate electrode of the fourth light emitting transistor through the via.

In an exemplary implementation mode, as shown in FIG. 24, an orthographic projection of the twenty-first via V21 on the base substrate is within a range of an orthographic projection of the gate electrode of the fifth light emitting transistor (also the gate electrode of the sixth light emitting transistor and the first electrode plate of the first light emitting capacitor) on the base substrate, the second insulation layer within the twenty-first via V21 is etched away to expose a surface of the gate electrode of the fifth light emitting transistor (also the gate electrode of the sixth light emitting transistor and the first electrode plate of the first light emitting capacitor), and the twenty-first via V21 is configured such that a second electrode of a second light emitting transistor (also a second electrode of a third light emitting transistor) formed subsequently is connected with the gate electrode of the fifth light emitting transistor (also the gate electrode of the sixth light emitting transistor and the first electrode plate of the first light emitting capacitor) through the via.

In an exemplary implementation mode, as shown in FIG. 24, an orthographic projection of the twenty-second via V22 on the base substrate is within a range of an orthographic projection of the gate electrode of the seventh light emitting transistor on the base substrate, the second insulation layer within the twenty-second via V22 is etched away to expose a surface of the gate electrode of the seventh light emitting transistor, and the twenty-second via V22 is configured such that the other of the first light emitting clock signal line and the second light emitting clock signal line formed subsequently is connected with the gate electrode of the seventh light emitting transistor through the via.

In an exemplary implementation mode, as shown in FIG. 24, an orthographic projection of the twenty-third via V23 on the base substrate is within a range of an orthographic projection of the gate electrode of the ninth light emitting transistor (also the first electrode plate of the second light emitting capacitor) on the base substrate, the second insulation layer within the twenty-third via V23 is etched away to expose a surface of the gate electrode of the ninth light emitting transistor (also the first electrode plate of the second light emitting capacitor), and the twenty-third via V23 is configured such that a second electrode of a seventh light emitting transistor formed subsequently (also a second electrode of an eighth light emitting transistor) is connected with the gate electrode of the ninth light emitting transistor (also the first electrode plate of the second light emitting capacitor) through the via.

In an exemplary implementation mode, as shown in FIG. 24, an orthographic projection of the twenty-fourth via V24 on the base substrate is within a range of an orthographic projection of the second electrode plate of the first light emitting capacitor on the base substrate to expose a surface of the second electrode plate of the first light emitting capacitor, and the twenty-fourth via V24 is configured such that a second electrode of a sixth light emitting transistor (and also a first electrode of a seventh light emitting transistor) formed subsequently is connected with the second electrode plate of the first light emitting capacitor through the via.

In an exemplary implementation mode, as shown in FIG. 24, an orthographic projection of the twenty-fifth via V25 on the base substrate is within a range of an orthographic projection of the second electrode plate of the second light emitting capacitor on the base substrate to expose a surface of the second electrode plate of the second light emitting capacitor, and the twenty-fifth via V25 is configured such that a first electrode of an eighth light emitting transistor (also a first electrode of a ninth light emitting transistor) formed subsequently is connected with the second electrode plate of the second light emitting capacitor through the via.

In an exemplary implementation mode, as shown in FIG. 24, an orthographic projection of the twenty-sixth via V26 on the base substrate is within a range of an orthographic projection of the second electrode plate of the third light emitting capacitor on the base substrate to expose a surface of the second electrode plate of the third light emitting capacitor, and the twenty-sixth via V26 is configured such that a first electrode of a sixth light emitting transistor formed subsequently is connected with the second electrode plate of the third light emitting capacitor through the via.

In an exemplary implementation mode, as shown in FIG. 24, an orthographic projection of the twenty-seventh via V27 on the base substrate is within a range of an orthographic projection of the output main body portion of the output line on the base substrate to expose a surface of the output main body portion of the output line, and the twenty-seventh via V27 is configured such that a second connection line formed subsequently is connected with the output main body portion of the output line through the via.

In an exemplary implementation mode, as shown in FIG. 24, an orthographic projection of the twenty-eighth via V28 on the base substrate is within a range of an orthographic projection of the output connection portion of the output line on the base substrate to expose a surface of the output connection portion of the output line, and the twenty-eighth via V28 is configured such that a second electrode of a first release transistor (which is also a second electrode of a second release transistor) formed subsequently is connected with the output connection portion of the output line through the via.

In an exemplary implementation mode, as shown in FIG. 24, an orthographic projection of the twenty-ninth via V29 on the base substrate is within a range of an orthographic projection of the output connection line on the base substrate to expose a surface of the output connection line, and the twenty-ninth via V29 is configured such that a second electrode of a ninth light emitting transistor formed subsequently and a second electrode of a tenth light emitting transistor formed subsequently is connected with the output connection line through the via.

In an exemplary implementation mode, as shown in FIG. 24, an orthographic projection of the thirtieth via V30 on the base substrate is within a range of an orthographic projection of the first region of the active layer of the first release transistor on the base substrate, the first insulation layer and the second insulation layer within the thirtieth via V30 are etched away to expose a surface of the first region of the active layer of the first release transistor, and the thirtieth via V30 is configured such that a first electrode of a first release transistor (also a second light emitting power supply line) formed subsequently is connected with the first region of the active layer of the first release transistor through the via.

In an exemplary implementation mode, as shown in FIG. 24, an orthographic projection of the thirty-first via V31 on the base substrate is within a range of an orthographic projection of the second region of the active layer of the first release transistor (which is also the second region of the active layer of the second release transistor) on the base substrate, the first insulation layer and the second insulation layer within the thirty-first via V31 are etched away to expose a surface of the second region of the active layer of the first release transistor (which is also the second region of the active layer of the second release transistor), and the thirty-first via V31 is configured such that a second electrode of a first release transistor (also a second electrode of a second release transistor) formed subsequently is connected with the second region of the active layer of the first release transistor (also the second region of the active layer of the second release transistor) through the via.

In an exemplary implementation mode, as shown in FIG. 24, an orthographic projection of the thirty-second via V32 on the base substrate is within a range of an orthographic projection of the first region of the active layer of the second release transistor on the base substrate, the first insulation layer and the second insulation layer within the thirty-second via V32 are etched away to expose a surface of the first region of the active layer of the second release transistor, and the thirty-second via V32 is configured such that a first electrode of a second release transistor formed subsequently is connected with the first region of the active layer of the second release transistor through the via.

In an exemplary implementation mode, as shown in FIG. 24, an orthographic projection of the thirty-third via V33 on the base substrate is within a range of an orthographic projection of the gate electrode of the first release transistor on the base substrate, the second insulation layer within the thirty-third via V33 is etched away to expose a surface of the gate electrode of the first release transistor, and the thirty-third via V33 is configured such that a second electrode of a first release transistor (which is also a second electrode of a second release transistor) formed subsequently is connected with the gate electrode of the first release transistor through the via.

In an exemplary implementation mode, as shown in FIG. 24, an orthographic projection of the thirty-fourth via V34 on the base substrate is within a range of an orthographic projection of the gate electrode of the first release transistor on the base substrate, the second insulation layer within the thirty-fourth via V34 is etched away to expose a surface of the gate electrode of the first release transistor, and the thirty-fourth via V34 is configured such that a first electrode of a second release transistor (also a first scan power supply line) formed subsequently is connected with the gate electrode of the second release transistor through the via.

In an exemplary implementation mode, as shown in FIG. 24, an orthographic projection of the thirty-fifth via V35 on the base substrate is within a range of an orthographic projection of the first region of the active layer of the first scan transistor on the base substrate, the first insulation layer and the second insulation layer within the thirty-fifth via V35 are etched away to expose a surface of the first region of the active layer of the first scan transistor, and the thirty-fifth via V35 is configured such that a first electrode of a first scan transistor formed subsequently is connected with the first region of the active layer of the first scan transistor through the via.

In an exemplary implementation mode, as shown in FIG. 24, an orthographic projection of the thirty-sixth via V36 on the base substrate is within a range of an orthographic projection of the second region of the active layer of the first scan transistor (also the second region of the active layer of the seventh scan transistor) on the base substrate, the first insulation layer and the second insulation layer within the thirty-sixth via V36 are etched away to expose a surface of the second region of the active layer of the first scan transistor (also the second region of the active layer of the seventh scan transistor), and the thirty-sixth via V36 is configured such that a second electrode of a first scan transistor (also a second electrode of a seventh scan transistor) formed subsequently is connected with the second region of the active layer of the first scan transistor (also the second region of the active layer of the seventh scan transistor) through the via.

In an exemplary implementation mode, as shown in FIG. 24, an orthographic projection of the thirty-seventh via V37 on the base substrate is within a range of an orthographic projection of the first region of the active layer of the second scan transistor on the base substrate, the first insulation layer and the second insulation layer within the thirty-seventh via V37 are etched away to expose a surface of the first region of the active layer of the second scan transistor, and the thirty-seventh via V37 is configured such that a first electrode of a second scan transistor formed subsequently is connected with the first region of the active layer of the second scan transistor through the via.

In an exemplary implementation mode, as shown in FIG. 24, an orthographic projection of the thirty-eighth via V38 on the base substrate is within a range of an orthographic projection of the second region of the active layer of the second scan transistor (also the second region of the active layer of the third scan transistor) on the base substrate, the first insulation layer and the second insulation layer within the thirty-eighth via V38 are etched away to expose a surface of the second region of the active layer of the second scan transistor (also the second region of the active layer of the third scan transistor), and the thirty-eighth via V38 is configured such that a second electrode of a second scan transistor (also a second electrode of a third scan transistor) formed subsequently is connected with the second region of the active layer of the second scan transistor (also the second region of the active layer of the third scan transistor) through the via.

In an exemplary implementation mode, as shown in FIG. 24, an orthographic projection of the thirty-ninth via V39 on the base substrate is within a range of an orthographic projection of the first region of the active layer of the third scan transistor on the base substrate, the first insulation layer and the second insulation layer within the thirty-ninth via V39 are etched away to expose a surface of the first region of the active layer of the third scan transistor, and the thirty-ninth via V39 is configured such that a first electrode of a third scan transistor (also a second scan power supply line) formed subsequently is connected with the first region of the active layer of the third scan transistor through the via.

In an exemplary implementation mode, as shown in FIG. 24, an orthographic projection of the fortieth via V40 on the base substrate is within a range of an orthographic projection of the first region of the active layer of the fourth scan transistor on the base substrate, the first insulation layer and the second insulation layer within the fortieth via V40 are etched away to expose a surface of the first region of the active layer of the fourth scan transistor, and the fortieth via V40 is configured such that a first electrode of a fourth scan transistor formed subsequently is connected with the first region of the active layer of the fourth scan transistor through the via.

In an exemplary implementation mode, as shown in FIG. 24, an orthographic projection of the forty-first via V41 on the base substrate is within a range of an orthographic projection of the second region of the active layer of the fourth scan transistor (the second region of the active layer of the fifth scan transistor) on the base substrate, the first insulation layer and the second insulation layer within the forty-first via V41 are etched away to expose a surface of the second region of the active layer of the fourth scan transistor (the second region of the active layer of the fifth scan transistor), and the forty-first via V41 is configured such that a second electrode of a fourth scan transistor (which is also a second electrode of a fifth scan transistor) formed subsequently is connected with the second region of the active layer of the fourth scan transistor (the second region of the active layer of the fifth scan transistor) through the via.

In an exemplary implementation mode, as shown in FIG. 24, an orthographic projection of the forty-second via V42 on the base substrate is within a range of an orthographic projection of the first region of the active layer of the fifth scan transistor on the base substrate, the first insulation layer and the second insulation layer within the forty-second via V42 are etched away to expose a surface of the first region of the active layer of the fifth scan transistor, and the forty-second via V42 is configured such that a first electrode of a fifth scan transistor formed subsequently is connected with the first region of the active layer of the fifth scan transistor through the via.

In an exemplary implementation mode, as shown in FIG. 24, an orthographic projection of the forty-third via V43 on the base substrate is within a range of an orthographic projection of the first region of the active layer of the sixth scan transistor on the base substrate, the first insulation layer and the second insulation layer within the forty-third via V43 are etched away to expose a surface of the first region of the active layer of the sixth scan transistor, and the forty-third via V43 is configured such that a first electrode of a sixth scan transistor formed subsequently is connected with the first region of the active layer of the sixth scan transistor through the via.

In an exemplary implementation mode, as shown in FIG. 24, an orthographic projection of the forty-fourth via V44 on the base substrate is within a range of an orthographic projection of the first region of the active layer of the eighth scan transistor on the base substrate, the first insulation layer and the second insulation layer within the forty-fourth via V44 are etched away to expose a surface of the first region of the active layer of the eighth scan transistor, and the forty-fourth via V44 is configured such that a first electrode of an eighth scan transistor formed subsequently is connected with the first region of the active layer of the eighth scan transistor through the via.

In an exemplary implementation mode, as shown in FIG. 24, an orthographic projection of the forty-fifth via V45 on the base substrate is within a range of an orthographic projection of the second region of the active layer of the eighth scan transistor on the base substrate, the first insulation layer and the second insulation layer within the forty-fifth via V45 are etched away to expose a surface of the second region of the active layer of the eighth scan transistor, and the forty-fifth via V45 is configured such that a second electrode of an eighth scan transistor formed subsequently is connected with the second region of the active layer of the eighth scan transistor through the via.

In an exemplary implementation mode, as shown in FIG. 24, an orthographic projection of the forty-sixth via V46 on the base substrate is within a range of an orthographic projection of the gate electrode of the first scan transistor (also the gate electrode of the third scan transistor) on the base substrate, the second insulation layer within the forty-sixth via V46 is etched away to expose a surface of the gate electrode of the first scan transistor (also the gate electrode of the third scan transistor), and the forty-sixth via V46 is configured such that a first electrode of a second scan transistor formed subsequently and one of a first scan clock signal line and a second scan clock signal line that are formed subsequently are connected with the gate electrode of the first scan transistor (also the gate electrode of the third scan transistor) through the via.

In an exemplary implementation mode, as shown in FIG. 24, an orthographic projection of the forty-seventh via V47 on the base substrate is within a range of an orthographic projection of the gate electrode of the second scan transistor on the base substrate, the second insulation layer within the forty-seventh via V47 is etched away to expose a surface of the gate electrode of the fourth scan transistor, and the forty-seventh via V47 is configured such that a second electrode of a first scan transistor (also a second electrode of a seventh scan transistor) formed subsequently and a first electrode of an eighth scan transistor formed subsequently are connected with the gate electrode of the second scan transistor through the via.

In an exemplary implementation mode, as shown in FIG. 24, an orthographic projection of the forty-eighth via V48 on the base substrate is within a range of an orthographic projection of the gate electrode of the fourth scan transistor (also the gate electrode of the sixth scan transistor and the first electrode plate of the first scan capacitor) on the base substrate, the second insulation layer within the forty-eighth via V48 is etched away to expose a surface of the gate electrode of the fourth scan transistor (also the gate electrode of the sixth scan transistor and the first electrode plate of the first scan capacitor), and the forty-eighth via V48 is configured such that a second electrode of a second scan transistor (also a second electrode of a third scan transistor) formed subsequently is connected with the gate electrode of the fourth scan transistor (also the gate electrode of the sixth scan transistor and the first electrode plate of the first scan capacitor) through the via.

In an exemplary implementation mode, as shown in FIG. 24, an orthographic projection of the forty-ninth via V49 on the base substrate is within a range of an orthographic projection of the gate electrode of the fifth scan transistor (also the first electrode plate of the second scan capacitor) on the base substrate, the second insulation layer within the forty-ninth via V49 is etched away to expose a surface of the gate electrode of the fifth scan transistor (also the first electrode plate of the second scan capacitor), and the forty-ninth via V49 is configured such that a second electrode of an eighth scan transistor formed subsequently is connected with the gate electrode of the fifth scan transistor (also the first electrode plate of the second scan capacitor) through the via.

In an exemplary implementation mode, as shown in FIG. 24, an orthographic projection of the fiftieth via V50 on the base substrate is within a range of an orthographic projection of the gate electrode of the seventh scan transistor on the base substrate, the second insulation layer within the fiftieth via V50 is etched away to expose a surface of the gate electrode of the seventh scan transistor, and the fiftieth via V50 is configured such that a first electrode of a fifth light emitting transistor formed subsequently and the other of the first scan clock signal line and the second scan clock signal line that are formed subsequently are connected with the gate electrode of the seventh scan transistor through the via.

In an exemplary implementation mode, as shown in FIG. 24, an orthographic projection of the fifty-first via V51 on the base substrate is within a range of an orthographic projection of the gate electrode of the eighth scan transistor on the base substrate, the second insulation layer within the fifty-first via V51 is etched away to expose a surface of the gate electrode of the eighth scan transistor, and the fifty-first via V51 is configured such that a second scan power supply line formed subsequently is connected with the gate electrode of the eighth scan transistor through the via.

In an exemplary implementation mode, as shown in FIG. 24, an orthographic projection of the fifty-second via V52 on the base substrate is within a range of an orthographic projection of the second electrode plate of the first scan capacitor on the base substrate to expose a surface of the second electrode plate of the first scan capacitor, and the fifty-second via V52 is configured such that a first electrode of a fourth scan transistor and a first electrode of a sixth scan transistor formed subsequently is connected with the second electrode plate of the first scan capacitor through the via.

In an exemplary implementation mode, as shown in FIG. 24, an orthographic projection of the fifty-third via V53 on the base substrate is within a range of an orthographic projection of the second electrode plate of the second scan capacitor on the base substrate to expose a surface of the second electrode plate of the second scan capacitor, and the fifty-third via V53 is configured such that a second electrode of a fourth scan transistor (also a second electrode of a fifth scan transistor) formed subsequently is connected with the second electrode plate of the second scan capacitor through the via.

In an exemplary implementation mode, as shown in FIG. 24, an orthographic projection of the fifty-fourth via V54 on the base substrate is within a range of an orthographic projection of the third signal connection line on the base substrate to expose a surface of the third signal connection line, and the fifty-fourth via V54 is configured such that a second electrode of a first scan transistor of a present-stage scan shift register formed subsequently and a second electrode of a fourth scan transistor (also a second electrode of a fifth scan transistor) of a previous-stage scan shift register formed subsequently are connected with the third signal connection line through the via.

In an exemplary implementation mode, as shown in FIG. 24, an orthographic projection of the fifty-fifth via V55 on the base substrate is within a range of an orthographic projection of the scan output signal line on the base substrate to expose a surface of the scan output signal line, and the fifty-fifth via V55 is configured such that a first connection line formed subsequently is connected with the scan output signal line through the via.

In an exemplary implementation mode, as shown in FIG. 24, an orthographic projection of the fifty-sixth via V56 on the base substrate is within a range of an orthographic projection of the first signal connection line on the base substrate, the second insulation layer within the fifty-sixth via V56 is etched away to expose a surface of the first signal connection line, and the fifty-sixth via V56 is configured such that a first initial power supply line formed subsequently is connected with the first signal connection line through the via.

In an exemplary implementation mode, as shown in FIG. 24, an orthographic projection of the fifty-seventh via V57 on the base substrate is within a range of an orthographic projection of the second signal connection line on the base substrate, the second insulation layer within the fifty-seventh via V57 is etched away to expose a surface of the second signal connection line, and the fifty-seventh via V57 is configured such that a second initial power supply line formed subsequently is connected with the second signal connection line through the via.

In an exemplary implementation mode, as shown in FIG. 25, patterns of a plurality of via of the display substrate provided in FIG. 6A may include at least a first via V1 to a fifty-sixth via V56.

In an exemplary implementation mode, the first via V1 to the twenty-sixth via V26 in FIG. 6A are the same as the first via V1 to the twenty-sixth via V26 in the display substrate provided in FIG. 5A, and will not be repeated here.

In an exemplary implementation mode, as shown in FIG. 25, an orthographic projection of the twenty-seventh via V27 on the base substrate is within a range of an orthographic projection of the output line on the base substrate to expose a surface of the output line, and the twenty-seventh via V27 is configured such that a second connection line formed subsequently is connected with the output line through the via.

In an exemplary implementation mode, as shown in FIG. 25, an orthographic projection of the twenty-eighth via V28 on the base substrate is within a range of an orthographic projection of the output connection line on the base substrate to expose a surface of the output connection line, and the twenty-eighth via V28 is configured such that a second electrode of a ninth light emitting transistor formed subsequently and a second electrode of a tenth light emitting transistor formed subsequently are connected with the output connection line through the via.

In an exemplary implementation mode, as shown in FIG. 25, an orthographic projection of the twenty-ninth via V29 on the base substrate is within a range of an orthographic projection of the first region of the active layer of the first release transistor on the base substrate, the first insulation layer and the second insulation layer within the twenty-ninth via V29 are etched away to expose a surface of the first region of the active layer of the first release transistor, and the twenty-ninth via V29 is configured such that a first electrode of a first release transistor (also a second light emitting power supply line) formed subsequently is connected with the first region of the active layer of the first release transistor through the via.

In an exemplary implementation mode, as shown in FIG. 25, an orthographic projection of the thirtieth via V30 on the base substrate is within a range of an orthographic projection of the second region of the active layer of the first release transistor (which is also the second region of the active layer of the second release transistor) on the base substrate, the first insulation layer and the second insulation layer within the thirtieth via V30 are etched away to expose a surface of the second region of the active layer of the first release transistor (which is also the second region of the active layer of the second release transistor), and the thirtieth via V30 is configured such that a second electrode of a first release transistor (which is also a second region of an active layer of a second release transistor) formed subsequently is connected with the second region of the active layer of the first release transistor (which is also the second region of the active layer of the second release transistor) through the via.

In an exemplary implementation mode, as shown in FIG. 25, an orthographic projection of the thirty-first via V31 on the base substrate is within a range of an orthographic projection of the first region of the active layer of the second release transistor on the base substrate, the first insulation layer and the second insulation layer within the thirty-first via V31 are etched away to expose a surface of the first region of the active layer of the second release transistor, and the thirty-first via V31 is configured such that a first electrode of a second release transistor formed subsequently is connected with the first region of the active layer of the second release transistor through the via.

In an exemplary implementation mode, as shown in FIG. 25, an orthographic projection of the thirty-second via V32 on the base substrate is within a range of an orthographic projection of the gate electrode of the first release transistor on the base substrate, the second insulation layer within the thirty-second via V32 is etched away to expose a surface of the gate electrode of the first release transistor, and the thirty-second via V32 is configured such that a second electrode of a first release transistor (which is also a second region of an active layer of a second release transistor) formed subsequently is connected with the gate electrode of the first release transistor through the via.

In an exemplary implementation mode, as shown in FIG. 25, an orthographic projection of the thirty-third via V33 on the base substrate is within a range of an orthographic projection of the gate electrode of the first release transistor on the base substrate, the second insulation layer within the thirty-third via V33 is etched away to expose a surface of the gate electrode of the first release transistor, and the thirty-third via V33 is configured such that a first electrode of a second release transistor (also a first scan power supply line) formed subsequently is connected with the gate electrode of the second release transistor through the via.

In an exemplary implementation mode, as shown in FIG. 25, an orthographic projection of the thirty-fourth via V34 on the base substrate is within a range of an orthographic projection of the first region of the active layer of the first scan transistor on the base substrate, the first insulation layer and the second insulation layer within the thirty-fourth via V34 are etched away to expose a surface of the first region of the active layer of the first scan transistor, and the thirty-fifth via V35 is configured such that a first electrode of a first scan transistor formed subsequently is connected with the first region of the active layer of the first scan transistor through the via.

In an exemplary implementation mode, as shown in FIG. 25, an orthographic projection of the thirty-fifth via V35 on the base substrate is within a range of an orthographic projection of the second region of the active layer of the first scan transistor (also the second region of the active layer of the seventh scan transistor) on the base substrate, the first insulation layer and the second insulation layer within the thirty-fifth via V35 are etched away to expose a surface of the second region of the active layer of the first scan transistor (also the second region of the active layer of the seventh scan transistor), and the thirty-fifth via V35 is configured such that a second electrode of a first scan transistor (also a second electrode of a seventh scan transistor) formed subsequently is connected with the second region of the active layer of the first scan transistor (also the second region of the active layer of the seventh scan transistor) through the via.

In an exemplary implementation mode, as shown in FIG. 25, an orthographic projection of the thirty-sixth via V36 on the base substrate is within a range of an orthographic projection of the first region of the active layer of the second scan transistor on the base substrate, the first insulation layer and the second insulation layer within the thirty-sixth via V36 are etched away to expose a surface of the first region of the active layer of the second scan transistor, and the thirty-sixth via V36 is configured such that a first electrode of a second scan transistor formed subsequently is connected with the first region of the active layer of the second scan transistor through the via.

In an exemplary implementation mode, as shown in FIG. 25, an orthographic projection of the thirty-seventh via V37 on the base substrate is within a range of an orthographic projection of the second region of the active layer of the second scan transistor (also the second region of the active layer of the third scan transistor) on the base substrate, the first insulation layer and the second insulation layer within the thirty-seventh via V37 are etched away to expose a surface of the second region of the active layer of the second scan transistor (also the second region of the active layer of the third scan transistor), and the thirty-seventh via V37 is configured such that a second electrode of a second scan transistor (also a second electrode of a third scan transistor) formed subsequently is connected with the second region of the active layer of the second scan transistor (also the second region of the active layer of the third scan transistor) through the via.

In an exemplary implementation mode, as shown in FIG. 25, an orthographic projection of the thirty-eighth via V38 on the base substrate is within a range of an orthographic projection of the first region of the active layer of the third scan transistor on the base substrate, the first insulation layer and the second insulation layer within the thirty-eighth via V38 are etched away to expose a surface of the first region of the active layer of the third scan transistor, and the thirty-eighth via V38 is configured such that a first electrode of a third scan transistor (also a second scan power supply line) formed subsequently is connected with the first region of the active layer of the third scan transistor through the via.

In an exemplary implementation mode, as shown in FIG. 25, an orthographic projection of the thirty-ninth via V39 on the base substrate is within a range of an orthographic projection of the first region of the active layer of the fourth scan transistor on the base substrate, the first insulation layer and the second insulation layer within the thirty-ninth via V39 are etched away to expose a surface of the first region of the active layer of the fourth scan transistor, and the thirty-ninth via V39 is configured such that a first electrode of a fourth scan transistor formed subsequently is connected with the first region of the active layer of the fourth scan transistor through the via.

In an exemplary implementation mode, as shown in FIG. 25, an orthographic projection of the fortieth via V40 on the base substrate is within a range of an orthographic projection of the second region of the active layer of the fourth scan transistor (the second region of the active layer of the fifth scan transistor) on the base substrate, the first insulation layer and the second insulation layer within the fortieth via V40 are etched away to expose a surface of the second region of the active layer of the fourth scan transistor (the second region of the active layer of the fifth scan transistor), and the fortieth via V40 is configured such that a second electrode of a fourth scan transistor (which is also a second electrode of a fifth scan transistor) formed subsequently is connected with the second region of the active layer of the fourth scan transistor (the second region of the active layer of the fifth scan transistor) through the via.

In an exemplary implementation mode, as shown in FIG. 25, an orthographic projection of the forty-first via V41 on the base substrate is within a range of an orthographic projection of the first region of the active layer of the fifth scan transistor on the base substrate, the first insulation layer and the second insulation layer within the forty-first via V41 are etched away to expose a surface of the first region of the active layer of the fifth scan transistor, and the forty-first via V41 is configured such that a first electrode of a fifth scan transistor formed subsequently is connected with the first region of the active layer of the fifth scan transistor through the via.

In an exemplary implementation mode, as shown in FIG. 25, an orthographic projection of the forty-second via V42 on the base substrate is within a range of an orthographic projection of the first region of the active layer of the sixth scan transistor on the base substrate, the first insulation layer and the second insulation layer within the forty-second via V42 are etched away to expose a surface of the first region of the active layer of the sixth scan transistor, and the forty-second via V42 is configured such that a first electrode of a sixth scan transistor formed subsequently is connected with the first region of the active layer of the sixth scan transistor through the via.

In an exemplary implementation mode, as shown in FIG. 25, an orthographic projection of the forty-third via V43 on the base substrate is within a range of an orthographic projection of the first region of the active layer of the eighth scan transistor on the base substrate, the first insulation layer and the second insulation layer within the forty-third via V43 are etched away to expose a surface of the first region of the active layer of the eighth scan transistor, and the forty-third via V43 is configured such that a first electrode of an eighth scan transistor formed subsequently is connected with the first region of the active layer of the eighth scan transistor through the via.

In an exemplary implementation mode, as shown in FIG. 25, an orthographic projection of the forty-fourth via V44 on the base substrate is within a range of an orthographic projection of the second region of the active layer of the eighth scan transistor on the base substrate, the first insulation layer and the second insulation layer within the forty-fourth via V44 are etched away to expose a surface of the second region of the active layer of the eighth scan transistor, and the forty-fourth via V44 is configured such that a second electrode of an eighth scan transistor formed subsequently is connected with the second region of the active layer of the eighth scan transistor through the via.

In an exemplary implementation mode, as shown in FIG. 25, an orthographic projection of the forty-fifth via V45 on the base substrate is within a range of an orthographic projection of the gate electrode of the first scan transistor (also the gate electrode of the third scan transistor) on the base substrate, the second insulation layer within the forty-fifth via V45 is etched away to expose a surface of the gate electrode of the first scan transistor (also the gate electrode of the third scan transistor), and the forty-fifth via V45 is configured such that a first electrode of a second scan transistor formed subsequently and one of a first scan clock signal line and a second scan clock signal line that are formed subsequently are connected with the gate electrode of the first scan transistor (also the gate electrode of the third scan transistor) through the via.

In an exemplary implementation mode, as shown in FIG. 25, an orthographic projection of the forty-sixth via V46 on the base substrate is within a range of an orthographic projection of the gate electrode of the second scan transistor on the base substrate, the second insulation layer within the forty-sixth via V46 is etched away to expose a surface of the gate electrode of the fourth scan transistor, and the forty-sixth via V46 is configured such that a second electrode of a first scan transistor formed subsequently (also a second electrode of a seventh scan transistor) and a first electrode of an eighth scan transistor formed subsequently are connected with the gate electrode of the second scan transistor through the via.

In an exemplary implementation mode, as shown in FIG. 25, an orthographic projection of the forty-seventh via V47 on the base substrate is within a range of an orthographic projection of the gate electrode of the fourth scan transistor (also the gate electrode of the sixth scan transistor and the first electrode plate of the first scan capacitor) on the base substrate, the second insulation layer within the forty-seventh via V47 is etched away to expose a surface of the gate electrode of the fourth scan transistor (also the gate electrode of the sixth scan transistor and the first electrode plate of the first scan capacitor), and the forty-seventh via V47 is configured such that a second electrode of a second scan transistor (also a second electrode of a third scan transistor) formed subsequently is connected with the gate electrode of the fourth scan transistor (also the gate electrode of the sixth scan transistor and the first electrode plate of the first scan capacitor) through the via.

In an exemplary implementation mode, as shown in FIG. 25, an orthographic projection of the forty-eighth via V48 on the base substrate is within a range of an orthographic projection of the gate electrode of the fifth scan transistor (also the first electrode plate of the second scan capacitor) on the base substrate, the second insulation layer within the forty-eighth via V48 is etched away to expose a surface of the gate electrode of the fifth scan transistor (also the first electrode plate of the second scan capacitor), and the forty-eighth via V48 is configured such that a second electrode of an eighth scan transistor formed subsequently is connected with the gate electrode of the fifth scan transistor (also the first electrode plate of the second scan capacitor) through the via.

In an exemplary implementation mode, as shown in FIG. 25, an orthographic projection of the forty-ninth via V49 on the base substrate is within a range of an orthographic projection of the gate electrode of the seventh scan transistor on the base substrate, the second insulation layer within the forty-ninth via V49 is etched away to expose a surface of the gate electrode of the seventh scan transistor, and the forty-ninth via V49 is configured such that a first electrode of a fifth light emitting transistor formed subsequently and the other of the first scan clock signal line and the second scan clock signal line that are formed subsequently are connected with the gate electrode of the seventh scan transistor through the via.

In an exemplary implementation mode, as shown in FIG. 25, an orthographic projection of the fiftieth via V50 on the base substrate is within a range of an orthographic projection of the gate electrode of the eighth scan transistor on the base substrate, the second insulation layer within the fiftieth via V50 is etched away to expose a surface of the gate electrode of the eighth scan transistor, and the fiftieth via V50 is configured such that a second scan power supply line formed subsequently is connected with the gate electrode of the eighth scan transistor through the via.

In an exemplary implementation mode, as shown in FIG. 25, an orthographic projection of the fifty-first via V51 on the base substrate is within a range of an orthographic projection of the second electrode plate of the first scan capacitor on the base substrate to expose a surface of the second electrode plate of the first scan capacitor, and the fifty-first via V51 is configured such that a first electrode of a fourth scan transistor formed subsequently and a first electrode of a sixth scan transistor formed subsequently are connected with the second electrode plate of the first scan capacitor through the via.

In an exemplary implementation mode, as shown in FIG. 25, an orthographic projection of the fifty-second via V52 on the base substrate is within a range of an orthographic projection of the second electrode plate of the second scan capacitor on the base substrate to expose a surface of the second electrode plate of the second scan capacitor, and the fifty-second via V52 is configured such that a second electrode of a fourth scan transistor (also a second electrode of a fifth scan transistor) formed subsequently is connected with the second electrode plate of the second scan capacitor through the via.

In an exemplary implementation mode, as shown in FIG. 25, an orthographic projection of the fifty-third via V53 on the base substrate is within a range of an orthographic projection of the third signal connection line on the base substrate to expose a surface of the third signal connection line, and the fifty-third via V53 is configured such that a second electrode of a first scan transistor of a present-stage scan shift register formed subsequently and a second electrode of a fourth scan transistor of a previous-stage scan shift register (also a second electrode of a fifth scan transistor) formed subsequently are connected with the third signal connection line through the via.

In an exemplary implementation mode, as shown in FIG. 25, an orthographic projection of the fifty-fourth via V54 on the base substrate is within a range of an orthographic projection of the scan output signal line on the base substrate to expose a surface of the scan output signal line, and the fifty-fourth via V54 is configured such that a first connection line formed subsequently is connected with the scan output signal line through the via.

In an exemplary implementation mode, as shown in FIG. 25, an orthographic projection of the fifty-fifth via V55 on the base substrate is within a range of an orthographic projection of the first signal connection line on the base substrate, the second insulation layer within the fifty-fifth via V55 is etched away to expose a surface of the first signal connection line, and the fifty-fifth via V55 is configured such that a first initial power supply line formed subsequently is connected with the first signal connection line through the via.

In an exemplary implementation mode, as shown in FIG. 25, an orthographic projection of the fifty-sixth via V56 on the base substrate is within a range of an orthographic projection of the second signal connection line on the base substrate, the second insulation layer within the fifty-sixth via V56 is etched away to expose a surface of the second signal connection line, and the fifty-sixth via V56 is configured such that a second initial power supply line formed subsequently is connected with the second signal connection line through the via.

In an exemplary implementation mode, as shown in FIGS. 44 and 45, patterns of a plurality of via in FIGS. 7B and 7C may include at least a fifty-eighth via V58 to a sixty-seventh via V67.

In an exemplary implementation mode, as shown in FIGS. 44 and 45, an orthographic projection of the fifty-eighth via V58 on the base substrate is within a range of an orthographic projection of the first region of the active layer of the first transistor on the base substrate, the first insulation layer and the second insulation layer within the fifty-eighth via V58 are etched away to expose a surface of the first region of the active layer of the first transistor, and the fifty-eighth via V58 is configured such that a first electrode of a first transistor formed subsequently is connected with the first region of the active layer of the first transistor through the via.

In an exemplary implementation mode, as shown in FIGS. 44 and 45, an orthographic projection of the fifty-ninth via V59 on the base substrate is within a range of an orthographic projection of the second region of the active layer of the first transistor (also the first region of the active layer of the second transistor) on the base substrate, the first insulation layer and the second insulation layer within the fifty-ninth via V59 are etched away to expose a surface of the second region of the active layer of the first transistor (also the first region of the active layer of the second transistor), and the fifty-ninth via V59 is configured such that a second electrode of a first transistor (also a first electrode of a second transistor) formed subsequently is connected with the second region of the active layer of the first transistor (also the first region of the active layer of the second transistor) through the via.

In an exemplary implementation mode, as shown in FIGS. 44 and 45, an orthographic projection of the sixtieth via V60 on the base substrate is within a range of an orthographic projection of the first region of the active layer of the fourth transistor on the base substrate, the first insulation layer and the second insulation layer within the sixtieth via V60 are etched away to expose a surface of the first region of the active layer of the fourth transistor, and the sixtieth via V60 is configured such that a first electrode of a fourth transistor formed subsequently is connected with the first region of the active layer of the fourth transistor through the via.

In an exemplary implementation mode, as shown in FIGS. 44 and 45, an orthographic projection of the sixty-first via V61 on the base substrate is within a range of an orthographic projection of the first region of the active layer of the fifth transistor on the base substrate, and the first insulation layer and the second insulation layer within the sixty-first via V61 are etched away to expose a surface of the second region of the active layer of the fifth transistor. The sixty-first via V61 in FIG. 44 is configured such that a first electrode of a fifth transistor formed subsequently is connected with the first region of the active layer of the fifth transistor through the via. The sixty-first via V61 in FIG. 45 is configured such that a first sub-power supply line formed subsequently is connected with the first region of the active layer of the fifth transistor through the via.

In an exemplary implementation mode, as shown in FIGS. 44 and 45, an orthographic projection of the sixty-second via V62 on the base substrate is within a range of an orthographic projection of the second region of the active layer of the sixth transistor (the second region of the active layer of the seventh transistor) on the base substrate, the first insulation layer and the second insulation layer within the sixty-second via V62 are etched away to expose a surface of the second region of the active layer of the sixth transistor (the second region of the active layer of the seventh transistor), and the sixty-second via V62 is configured such that a second electrode of a sixth transistor (also a second electrode of a seventh transistor) formed subsequently is connected with the second region of the active layer of the sixth transistor (the second region of the active layer of the seventh transistor) through the via.

In an exemplary implementation mode, as shown in FIGS. 44 and 45, an orthographic projection of the sixty-third via V63 on the base substrate is within a range of an orthographic projection of the first region of the active layer of the seventh transistor on the base substrate, and the first insulation layer and the second insulation layer within the sixty-third via V63 are etched away to expose a surface of the first region of the active layer of the seventh transistor. The sixty-third via V63 in FIG. 44 is configured such that a first electrode of a seventh transistor formed subsequently is connected with the first region of the active layer of the seventh transistor through the via. The sixty-third via V63 in FIG. 45 is configured such that a first electrode of a seventh transistor or a fourth signal connection line formed subsequently is connected with the first region of the active layer of the seventh transistor through the via.

In an exemplary implementation mode, as shown in FIG. 44, an orthographic projection of the sixty-fourth via V64 on the base substrate is within a range of an orthographic projection of the gate electrode of the third transistor (also the first electrode plate of the capacitor) on the base substrate, the second insulation layer within the sixty-fourth via V64 is etched away to expose a surface of the gate electrode of the third transistor (also the first electrode plate of the capacitor), and the sixty-fourth via V64 is configured such that a second electrode of a first transistor (also a first electrode of a second transistor) formed subsequently is connected with the gate electrode of the third transistor (also the first electrode plate of the capacitor) through the via.

In an exemplary implementation mode, as shown in FIG. 44, an orthographic projection of the sixty-fifth via V65 on the base substrate is within a range of an orthographic projection of the first initial signal line on the base substrate to expose the first initial signal line, and the sixty-fifth via V65 is configured such that a first electrode of a first transistor formed subsequently is connected with the first initial signal line through the via.

In an exemplary implementation mode, as shown in FIGS. 44 and 45, an orthographic projection of the sixty-sixth via V66 on the base substrate is within a range of an orthographic projection of the second electrode plate of the capacitor on the base substrate to expose a surface of the second electrode plate of the capacitor. The sixty-sixth via V66 in FIG. 44 is configured such that a first electrode of a fifth transistor formed subsequently is connected with the second electrode plate of the capacitor through the via. The sixty-sixth via V66 in FIG. 45 is configured such that a first sub-power supply line formed subsequently is connected with the second electrode plate of the capacitor through the via.

In an exemplary implementation mode, as shown in FIG. 44, an orthographic projection of the sixty-seventh via V67 on the base substrate is within a range of an orthographic projection of the second initial signal line on the base substrate to expose a surface of the second initial signal line, and the sixty-seventh via V67 is configured such that a first electrode of a seventh transistor formed subsequently is connected with the second initial signal line through the via.

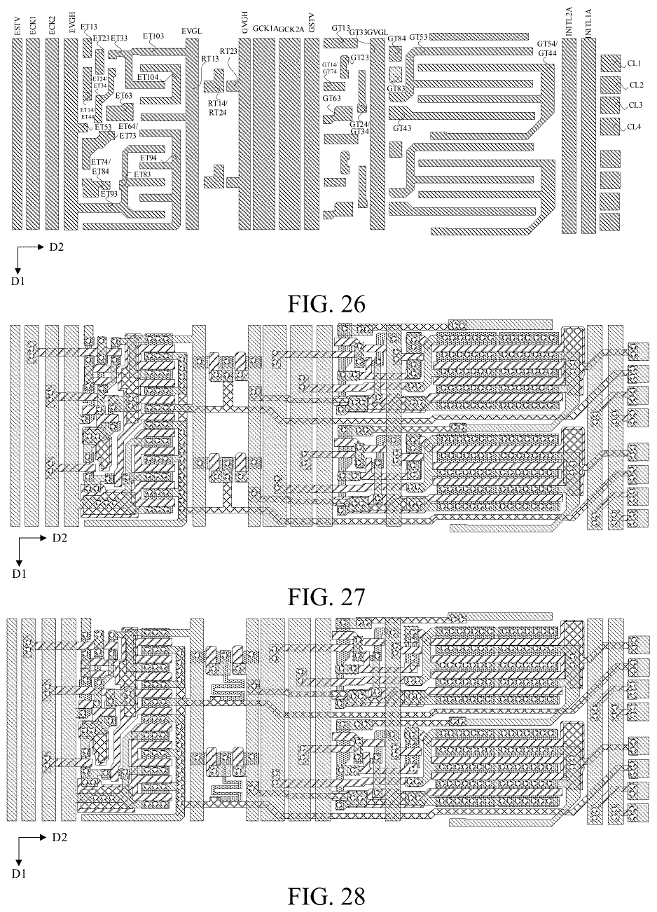

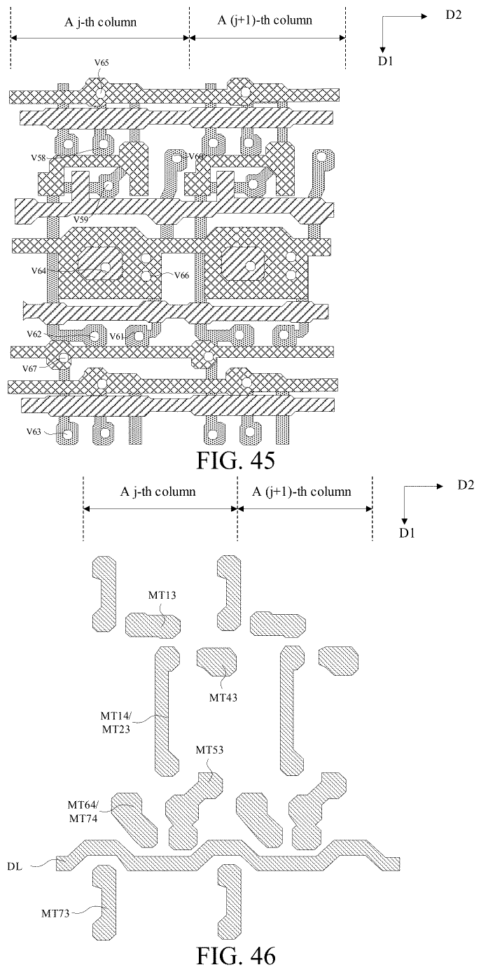

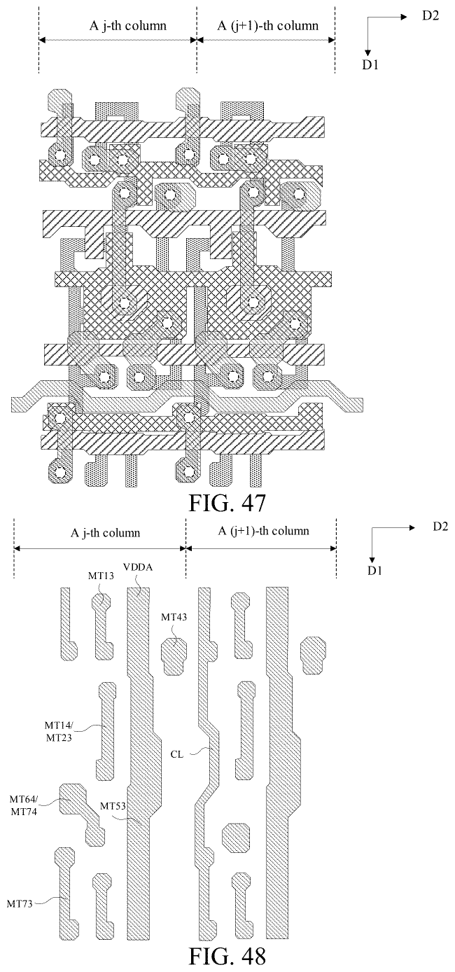

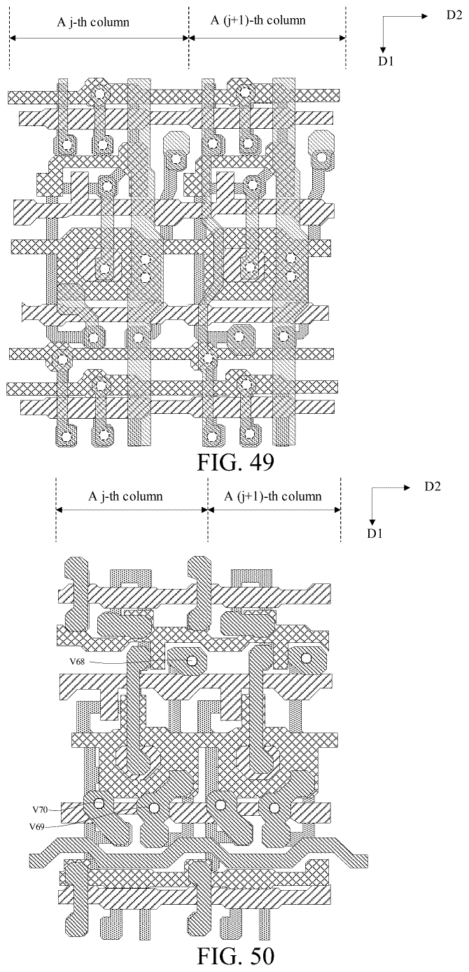

(6) Forming a pattern of a third conductive layer, includes: depositing a third conductive thin film on the base substrate on which the above-mentioned patterns are formed, and patterning the third conductive thin film through a patterning process to form a pattern of a third conductive layer, as shown in FIGS. 26 to 28 and FIGS. 46 to 49, FIG. 26 is a schematic diagram of a pattern of a third conductive layer in FIG. 5A and FIG. 6A, FIG. 27 is a schematic diagram after the pattern of the third conductive layer is formed in FIG. 5A, FIG. 28 is a schematic diagram after the pattern of the third conductive layer is formed in FIG. 6A, FIG. 46 is a schematic diagram of a pattern of a third conductive layer in FIG. 7B, FIG. 47 is a schematic diagram after the pattern of the third conductive layer is formed in FIG. 7B, FIG. 48 is a schematic diagram of a pattern of a third conductive layer FIG. 7C, and FIG. 49 is a schematic diagram after the pattern of the third conductive layer is formed in FIG. 7C. In an exemplary implementation mode, the third conductive layer may be referred to as a first source-drain metal (SD1) layer.

In an exemplary implementation mode, as shown in FIGS. 26 to 28 and FIGS. 46 to 49, the pattern of the third conductive layer may at least include a light emitting initial signal line ESTV, a first light emitting clock signal line ECK1, a second light emitting clock signal line ECK2, a first light emitting power supply line EVGH, a second light emitting power supply line EVGL, a scan initial signal line GSTV, a first sub-clock signal line GCK1A of a first scan clock signal line, a third sub-clock signal line GCK2A of a second scan clock signal line, a first scan power supply line GVGH, a second scan power supply line GVGL, a first sub-initial power supply line INITL1A of a first initial power supply line, a first sub-initial power supply line INITL2A of a second initial power supply line, a first connection line CL1 to a fourth connection line CL4, first electrodes and second electrodes of a plurality of light emitting transistors, first electrodes and second electrodes of a plurality of release transistors, and first electrodes and second electrodes of a plurality of scan transistors, a first electrode MT13 and a second electrode MT14 of a first transistor, a first electrode MT23 of a second transistor, a first electrode MT43 of a fourth transistor, a first electrode MT53 of a fifth transistor, a second electrode MT64 of a sixth transistor, and a first electrode MT73 and a second electrode MT74 of a seventh transistor.

In an exemplary implementation mode, as shown in FIGS. 46 and 47, the pattern of the third conductive layer at least further includes a data connection line DL.

In an exemplary implementation mode, as shown in FIGS. 48 and 49, the pattern of the third conductive layer at least further includes a first sub-power supply line VDDA and an electrode connection line CL.

In an exemplary implementation mode, as shown in FIG. 26, the first light emitting clock signal line ECK1 may be located at a side of the light emitting initial signal line ESTV close to the display region, the second light emitting clock signal line ECK2 may be located at a side of the first light emitting clock signal line ECK1 close to the display region, the first light emitting power supply line EVGH may be located at a side of the second light emitting clock signal line ECK2 close to the display region, the second light emitting power supply line EVGL is located at a side of the first light emitting power supply line EVGH close to the display region, the first scan power supply line GVGH is located at a side of the second light emitting power supply line EVGL close to the display region, the first sub-clock signal line GCK1A of the first scan clock signal line is located at a side of the first scan power supply line GVGH is close to the display region, the third sub-clock signal line GCK2A of the second scan clock signal line is located at a side of the first scan clock signal line GCK1 close to the display region, the scan initial signal line GSTV is located at a side of the second scan clock signal line GCK2 close to the display region, and the second scan power supply line GVGL is located at a side of the scan initial signal line GSTV close to the display region.

In an exemplary implementation mode, any one of the light emitting initial signal line ESTV, the first light emitting clock signal line ECK1, the second light emitting clock signal line ECK2, the first light emitting power supply line EVGH, the second light emitting power supply line EVGL, the scan initial signal line GSTV, the first sub-clock signal line GCK1A of the first scan clock signal line, the third sub-clock signal line GCK2A of the second scan clock signal line, the first scan power supply line GVGH, the second scan power supply line GVGL, the first sub-initial power supply line INITL1A of the first initial power supply line, and the first sub-initial power supply line INITL2A of the second initial power supply line extends at least partially along the first direction D1 and is in a shape of a line.

In an exemplary implementation mode, as shown in FIG. 26, a first electrode ET13 and a second electrode ET14 of the first light emitting transistor to a first electrode ET103 and a second electrode ET104 of the tenth light emitting transistor may be located between the first light emitting power supply line EVGH and the second light emitting power supply line EVGL. A first electrode RT11 and a second electrode RT14 of the first release transistor to a first electrode RT21 and a second electrode RT24 of the second release transistor are located between the second light emitting power supply line EVGL and the first scan power supply line GVGH. A first electrode GT13 and a second electrode GT14 of the first scan transistor to a first electrode GT33 and a second electrode of the third scan transistor, a first electrode GT63 of the sixth scan transistor, and a second electrode GT74 of the seventh scan transistor may be located between the scan initial signal line GSTV and the second scan power supply line GVGL, and a first electrode GT43 and a second electrode GT44 of the fourth scan transistor to a first electrode GT53 and a second electrode GT54 of the fifth scan transistor, and a first electrode GT83 and a second electrode GT84 of the eighth scan transistor may be located between the second scan power supply line GVGL and the first initial power supply line INITL1.

In an exemplary implementation mode, an orthographic projection of the second electrode plate of the second scan capacitor on the base substrate is at least partially overlapped with orthographic projections of the second scan power supply line, the first scan clock signal line, the second scan clock signal line, the scan initial signal line, and the first scan power supply line on the base substrate.

In an exemplary implementation mode, as shown in FIG. 26, the first initial power supply line INITL1 and the second initial power supply line INITL2 are located at a side of the second scan power supply line GVGL close to the display region, and the first initial power supply line INITL1 is located at a side of the second initial power supply line INITL2 close to the display region.

In an exemplary implementation mode, as shown in FIGS. 26 to 28, the first electrode ET13 of the first light emitting transistor may be in a shape of a strip extending along the first direction D1. The first electrode ET13 of the first light emitting transistor is connected with the first region of the active layer of the first light emitting transistor through a first via.

In an exemplary implementation mode, as shown in FIGS. 26 to 28, the second electrode ET14 of the first light emitting transistor and the second electrode ET44 of the fourth light emitting transistor are of an interconnected integral structure, and may be in a shape of a strip extending along the first direction D1. The second electrode ET14 of the first light emitting transistor (also the second electrode ET44 of the fourth light emitting transistor) is connected with the second region of the active layer of the first light emitting transistor through a second via, and is connected with the second region of the active layer of the fourth light emitting transistor through a seventh via.

In an exemplary implementation mode, as shown in FIGS. 26 to 28, a first electrode ET23 of the second light emitting transistor may be in a shape of a strip extending along the first direction D1, and the first electrode ET23 of the second light emitting transistor is connected with the first region of the active layer of the second light emitting transistor through a third via, and is connected with the gate electrode of the first light emitting transistor (which is also the gate electrode of the third light emitting transistor) through a nineteenth via.

In an exemplary implementation mode, as shown in FIGS. 26 to 28, a second electrode ET24 of the second light emitting transistor and a second electrode ET34 of the third light emitting transistor are of an interconnected integral structure, and extend at least partially along the first direction D1, and may be in a shape of a polyline. The second electrode ET24 of the second light emitting transistor (also the second electrode ET34 of the third light emitting transistor) is connected with the second region of the active layer of the second light emitting transistor through a fourth via, is connected with the second region of the active layer of the third light emitting transistor through a sixth via, and is connected with the gate electrode of the fifth light emitting transistor (also the gate electrode of the sixth light emitting transistor and the first electrode plate of the first light emitting capacitor) through a twenty-first via.

In an exemplary implementation mode, as shown in FIGS. 26 to 28, a first electrode ET33 of the third light emitting transistor, the first electrode ET103 of the tenth light emitting transistor, and the second light emitting power supply line EVGL are of an interconnected integral structure, and the first electrode ET33 of the third light emitting transistor may be in a shape of a strip extending along the second direction D2, and the first electrode ET103 of the tenth light emitting transistor may be in a shape of an “n” with an opening facing the second light emitting power supply line EVGL. The first electrode ET33 of the third light emitting transistor (also the first electrode ET103 of the tenth light emitting transistor) is connected with the first region of the active layer of the third light emitting transistor through a fifth via, and is connected with the first region of the active layer of the tenth light emitting transistor through a seventeenth via.

In an exemplary implementation mode, as shown in FIGS. 26 to 28, a first electrode ET53 of the fifth light emitting transistor and the first light emitting power supply line EVGH are of an interconnected integral structure. The first electrode ET53 of the fifth light emitting transistor may be in a shape of a block. The first electrode ET53 of the fifth light emitting transistor is connected with the first region of the active layer of the fifth light emitting transistor through an eighth via.

In an exemplary implementation mode, as shown in FIGS. 26 to 28, a first electrode ET63 of the sixth light emitting transistor may be in a shape of a block. The first electrode ET63 of the sixth light emitting transistor is connected with the first region of the active layer of the sixth light emitting transistor through a ninth via, and is connected with the second electrode plate of the third light emitting capacitor through a twenty-sixth via.

In an exemplary implementation mode, as shown in FIGS. 26 to 28, a second electrode ET64 of the sixth light emitting transistor and a first electrode ET73 of the seventh light emitting transistor are of an interconnected integral structure. The second electrode ET64 of the sixth light emitting transistor (also the first electrode ET73 of the seventh light emitting transistor) extends at least partially along the first direction D1. The second electrode ET64 of the sixth light emitting transistor (also the first electrode ET73 of the seventh light emitting transistor) is connected with the second region of the active layer of the sixth light emitting transistor through a tenth via, is connected with the first region of the active layer of the seventh light emitting transistor through an eleventh via, and is connected with a second electrode plate of the first light emitting capacitor through a twenty-fourth via.

In an exemplary implementation mode, as shown in FIGS. 26 to 28, a second electrode ET74 of the seventh light emitting transistor and a second electrode ET84 of the eighth light emitting transistor are of an interconnected integral structure. The second electrode ET74 of the seventh light emitting transistor (also the second electrode ET84 of the eighth light emitting transistor) may have a shape of a horizontally reversed “7”. The second electrode ET74 of the seventh light emitting transistor (also the second electrode ET84 of the eighth light emitting transistor) is connected with the second region of the active layer of the seventh light emitting transistor through a twelfth via, is connected with the second region of the active layer of the eighth light emitting transistor through a fourteenth via, and is connected with the gate electrode of the ninth light emitting transistor (also the first electrode plate of the second light emitting capacitor) through a twenty-third via.

In an exemplary implementation mode, as shown in FIGS. 26 to 28, a first electrode ET83 of the eighth light emitting transistor, a first electrode ET93 of the ninth light emitting transistor, and the first light emitting power supply line EVGH are of an interconnected integral structure. The first electrode ET83 of the eighth light emitting transistor may be in a shape of a block, the first electrode ET93 of the ninth light emitting transistor may be in a shape of a comb, the first electrode ET83 of the eighth light emitting transistor (also the first electrode ET93 of the ninth light emitting transistor) is connected with the first region of the active layer of the eighth light emitting transistor through a thirteenth via, is connected with the first region of the active layer of the ninth light emitting transistor through a fifteenth via, and is connected with the second electrode plate of the second light emitting capacitor through a twenty-fifth via.

In an exemplary implementation mode, as shown in FIGS. 26 to 28, a second electrode ET94 of the ninth light emitting transistor may have a shape of a comb, and teeth of the comb of the second electrode ET94 of the ninth light emitting transistor may be interleaved with teeth of the comb of the first electrode ET93 of the ninth light emitting transistor. The second electrode ET94 of the ninth light emitting transistor is connected with the second region of the active layer of the ninth light emitting transistor through a sixteenth via. As shown in FIG. 27, the second electrode ET94 of the ninth light emitting transistor in FIG. 5A is connected with an output connection line through a twenty-ninth via. As shown in FIG. 28, the second electrode ET94 of the ninth light emitting transistor in FIG. 6A is connected with an output connection line through a twenty-eighth via.

In an exemplary implementation mode, as shown in FIGS. 26 to 28, a second electrode ET104 of the tenth light emitting transistor may be in a shape of an “n” with an opening departing from the second light emitting power supply line EVGL. The second electrode ET104 of the tenth light emitting transistor is connected with the second region of the active layer of the tenth light emitting transistor through an eighteenth via. As shown in FIG. 27, the second electrode ET104 of the tenth light emitting transistor in FIG. 5A is connected with an output connection line through a twenty-ninth via. As shown in FIG. 28, the second electrode ET104 of the tenth light emitting transistor in FIG. 6A is connected with an output connection line through a twenty-eighth via.

In an exemplary implementation mode, as shown in FIGS. 26 to 28, one of the first light emitting clock signal line ECK1 and the second light emitting clock signal line ECK2 is connected with the gate electrode of the first light emitting transistor (also the gate electrode of the third light emitting transistor) through a nineteenth via.

In an exemplary implementation mode, as shown in FIGS. 26 to 28, the other of the first light emitting clock signal line ECK1 and the second light emitting clock signal line ECK2 is connected with the gate electrode of the fourth light emitting transistor through a twentieth via, and is connected with the gate electrode of the seventh light emitting transistor through a twenty-second via.

In an exemplary implementation mode, as shown in FIGS. 26 to 28, the second connection line CL2 may be in a shape of a block. As shown in FIG. 27, the second connection line in FIG. 5A is connected with the output main body portion of the output line through a twenty-seventh via.

In an exemplary implementation mode, as shown in FIGS. 26 to 28, a region where the second light emitting power supply line EVGL is overlapped with the first region of the active layer of the first release transistor may be multiplexed as a first electrode of the first release transistor. As shown in FIG. 27, the first electrode of the first release transistor in FIG. 5A is connected with the first region of the active layer of the first release transistor through a thirtieth via, and the first electrode of the first release transistor in FIG. 6A is connected with the first region of the active layer of the first release transistor through a twenty-ninth via.

In an exemplary implementation mode, as shown in FIGS. 26 to 28, a second electrode ET14 of the first release transistor and a second electrode ET24 of the second release transistor are of an interconnected integral structure, and may have a shape of a horizontally reversed “L”. As shown in FIG. 27, an orthographic projection of the second electrode ET14 of the first release transistor (which is also the second electrode of the second release transistor) on the base substrate in FIG. 5A is at least partially overlapped with an orthographic projection of the output connection portion on the base substrate. An orthographic projection of the second electrode ET14 of the first release transistor in FIG. 5A (which is also the second electrode of the second release transistor) on the base substrate is not overlapped with an orthographic projection of the output line on the base substrate.

In an exemplary implementation mode, as shown in FIG. 27, the second electrode ET14 of the first release transistor in FIG. 5A (which is also the second electrode of the second release transistor) is connected with the output connection portion of the output line through a twenty-eighth via, is connected with the second region of the active layer of the first release transistor through a thirty-first via, and is connected with the gate electrode of the first release transistor through a thirty-third via. As shown in FIG. 28, the second electrode ET14 of the first release transistor (which is also the second electrode of the second release transistor) in FIG. 6A is connected with the second region of the active layer of the first release transistor (which is also the second region of the active layer of the second release transistor) through a thirtieth via, and is connected with the gate electrode of the first release transistor through a thirty-second via.

In an exemplary implementation mode, as shown in FIGS. 26 to 28, the second electrode ET21 of the second release transistor and the first scan power supply line GVGH are of an interconnected integral structure, and may have a shape of a horizontally reversed “L”. As shown in FIG. 27, the second electrode ET21 of the second release transistor in FIG. 5A is connected with the first region of the active layer of the second release transistor through a thirty-second via, and is connected with the gate electrode of the second release transistor through a thirty-fourth via. As shown in FIG. 28, the second electrode ET21 of the second release transistor in FIG. 6A is connected with the first region of the active layer of the second release transistor through a thirty-first via, and is connected with the gate electrode of the second release transistor through a thirty-third via.

In an exemplary implementation mode, as shown in FIGS. 26 to 28, the first electrode GT13 of the first scan transistor may be in a shape of a strip extending along the second direction D2. As shown in FIG. 27, the first electrode GT13 of the first scan transistor in FIG. 5A is connected with the first region of the active layer of the first scan transistor through a thirty-fifth via, and is connected with the third signal connection line through a fifty-fourth via. As shown in FIG. 28, the first electrode GT13 of the first scan transistor in FIG. 6A is connected with the first region of the active layer of the first scan transistor through a thirty-fourth via, and is connected with the third signal connection line through a fifty-third via.

In an exemplary implementation mode, as shown in FIGS. 26 to 28, the second electrode GT14 of the first scan transistor and the second electrode GT74 of the seventh scan transistor are of an interconnected integral structure, and may be in a shape of a strip extending along the second direction D2. As shown in FIG. 27, the second electrode GT14 of the first scan transistor (also the second electrode GT74 of the seventh scan transistor) in FIG. 5A is connected with the second region of the active layer of the first scan transistor (also the second region of the active layer of the seventh scan transistor) through a thirty-sixth via, and is connected with the gate electrode of the second scan transistor through a forty-seventh via. As shown in FIG. 28, the second electrode GT14 of the first scan transistor (also the second electrode GT74 of the seventh scan transistor) in FIG. 6A is connected with the second region of the active layer of the first scan transistor (also the second region of the active layer of the seventh scan transistor) through a thirty-fifth via, and is connected with the gate electrode of the second scan transistor through a forty-sixth via.

In an exemplary implementation mode, as shown in FIGS. 26 to 28, the first electrode GT23 of the second scan transistor may be in a shape of a strip extending along the first direction D1. As shown in FIG. 27, the first electrode GT23 of the second scan transistor in the display substrate provided in FIG. 5A is connected with the first region of the active layer of the second scan transistor through a thirty-seventh via, and is connected with the gate electrode of the first scan transistor (also the gate electrode of the third scan transistor) through a forty-sixth via. As shown in FIG. 28, the first electrode GT23 of the second scan transistor in FIG. 6A is connected with the first region of the active layer of the second scan transistor through a thirty-sixth via, and is connected with the gate electrode of the first scan transistor (also the gate electrode of the third scan transistor) through a forty-fifth via.

In an exemplary implementation mode, as shown in FIGS. 26 to 28, the second electrode GT24 of the second scan transistor and the second electrode GT34 of the third scan transistor are of an interconnected integral structure, and may be in a shape of a strip extending along the second direction D2. As shown in FIG. 27, the second electrode GT24 of the second scan transistor (also the second electrode GT34 of the third scan transistor) in the display substrate provided in FIG. 5A is connected with the second region of the active layer of the second scan transistor (also the second region of the active layer of the third scan transistor) through a thirty-eighth via, and is connected with the gate electrode of the fourth scan transistor (also the gate electrode of the sixth scan transistor and the first electrode plate of the first scan capacitor) through a forty-eighth via. As shown in FIG. 28, the second electrode GT24 of the second scan transistor (also the second electrode GT34 of the third scan transistor) in FIG. 6A is connected with the second region of the active layer of the second scan transistor (also the second region of the active layer of the third scan transistor) through a thirty-seventh via, and is connected with the gate electrode of the fourth scan transistor (also the gate electrode of the sixth scan transistor and the first electrode plate of the first scan capacitor) through a forty-seventh via.

In an exemplary implementation mode, as shown in FIGS. 26 to 28, a region where the second scan power supply line GVGL is overlapped with the first region of the active layer of the third scan transistor is multiplexed as the first electrode GT33 of the third scan transistor. As shown in FIG. 27, the first electrode GT33 of the third scan transistor in FIG. 5A is connected with the first region of the active layer of the third scan transistor through a thirty-ninth via.

In an exemplary implementation mode, as shown in FIGS. 26 to 28, the first electrode GT43 of the fourth scan transistor may be in a shape of a strip extending along the second direction D2. As shown in FIG. 27, the first electrode GT43 of the fourth scan transistor in the display substrate provided in FIG. 5A is connected with the first region of the active layer of the fourth scan transistor through a fortieth via, and is connected with the second electrode plate of the first scan capacitor through a fifty-second via. As shown in FIG. 28, the first electrode GT23 of the second scan transistor in FIG. 6A is connected with the first region of the active layer of the fourth scan transistor through a thirty-ninth via, and is connected with the second electrode plate of the first scan capacitor through a fifty-first via.

In an exemplary implementation mode, as shown in FIGS. 26 to 28, the second electrode GT44 of the fourth scan transistor and the second electrode GT54 of the fifth scan transistor are of an interconnected integral structure, and may have a shape of an “m” with an opening facing the second scan power supply line GVGH. As shown in FIG. 27, the second electrode GT44 of the fourth scan transistor (also the second electrode GT54 of the fifth scan transistor) in FIG. 5A is connected with the second region of the active layer of the fourth scan transistor (the second region of the active layer of the fifth scan transistor) through a forty-first via, and is connected with the second electrode plate of the second scan capacitor through a fifty-third via. As shown in FIG. 28, the second electrode GT44 of the fourth scan transistor (also the second electrode GT54 of the fifth scan transistor) in FIG. 6A is connected with the second region of the active layer of the fourth scan transistor (the second region of the active layer of the fifth scan transistor) through a fortieth via, and is connected with the second electrode plate of the second scan capacitor through a fifty-second via.

In an exemplary implementation mode, as shown in FIGS. 26 to 28, the first electrode GT53 of the fifth scan transistor may be in a shape of an “F”. As shown in FIG. 27, the first electrode GT53 of the fifth scan transistor in FIG. 5A is connected with the first region of the active layer of the fifth scan transistor through a forty-second via, and is connected with the gate electrode of the seventh scan transistor through a fiftieth via. As shown in FIG. 28, the first electrode GT53 of the fifth scan transistor in FIG. 6A is connected with the first region of the active layer of the fifth scan transistor through a forty-first via, and is connected with the gate electrode of the seventh scan transistor through a forty-ninth via.

In an exemplary implementation mode, as shown in FIGS. 26 to 28, the first electrode GT63 of the sixth scan transistor may be in a shape of a strip extending along the second direction D2. As shown in FIG. 27, the first electrode GT63 of the sixth scan transistor in FIG. 5A is connected with the first region of the active layer of the sixth scan transistor through a forty-third via, and is connected with the second electrode plate of the second scan capacitor through a fifty-second via. As shown in FIG. 28, the first electrode GT63 of the sixth scan transistor in FIG. 6A is connected with the first region of the active layer of the sixth scan transistor through a forty-second via, and is connected with the second electrode plate of the second scan capacitor through a fifty-first via.

In an exemplary implementation mode, as shown in FIGS. 26 to 28, the first electrode GT83 of the eighth scan transistor may be in a shape of a block. As shown in FIG. 27, the first electrode GT83 of the eighth scan transistor in FIG. 5A is connected with the first region of the active layer of the eighth scan transistor through a forty-fourth via, and is connected with the gate electrode of the fifth scan transistor (which is also the second electrode plate of the second scan capacitor) through a forty-ninth via. As shown in FIG. 28, the first electrode GT63 of the sixth scan transistor in FIG. 6A is connected with the first region of the active layer of the eighth scan transistor through a forty-third via, and is connected with the gate electrode of the fifth scan transistor (which is also the second electrode plate of the second scan capacitor) through a forty-eighth via.

In an exemplary implementation mode, as shown in FIGS. 26 to 28, the second electrode GT84 of the eighth scan transistor may be in a shape of a block. As shown in FIG. 27, the second electrode GT84 of the eighth scan transistor in FIG. 5A is connected with the second region of the active layer of the eighth scan transistor through a forty-fifth via, and is connected with the gate electrode of the second scan transistor through a forty-seventh via. As shown in FIG. 28, the second electrode GT84 of the eighth scan transistor in FIG. 6A is connected with the second region of the active layer of the eighth scan transistor through a forty-fourth via, and is connected with the gate electrode of the second scan transistor through a forty-sixth via.

In an exemplary implementation mode, as shown in FIG. 27, one of the first sub-clock signal line GCK1A of the first scan clock signal line and the third sub-clock signal line GCK2A of the second scan clock signal line in FIG. 5A is connected with the gate electrode of the first scan transistor (which is also the gate electrode of the third scan transistor) through a forty-sixth via. As shown in FIG. 28, one of the first sub-clock signal line GCK1A of the first scan clock signal line and the third sub-clock signal line GCK2A of the second scan clock signal line in FIG. 6A is connected with the gate electrode of the first scan transistor (also the gate electrode of the third scan transistor) through a forty-fifth via.

In an exemplary implementation mode, as shown in FIG. 27, the other of the first sub-clock signal line GCK1A of the first scan clock signal line and the third sub-clock signal line GCK2A of the second scan clock signal line in FIG. 5A is connected with the gate electrode of the seventh scan transistor through a fiftieth via. As shown in FIG. 28, the other of the first sub-clock signal line GCK1A of the first scan clock signal line and the third sub-clock signal line GCK2A of the second scan clock signal line in FIG. 6A is connected with the gate electrode of the seventh scan transistor through a forty-ninth via.

In an exemplary implementation mode, as shown in FIG. 27, the second scan power supply line GVGH in FIG. 5A is connected with the gate electrode of the eighth scan transistor through a fifty-first via. As shown in FIG. 28, the second scan power supply line GVGH in FIG. 6A is connected with the gate electrode of the eighth scan transistor through a fiftieth via.

In an exemplary implementation mode, as shown in FIG. 27, the first connection line CL1 in FIG. 5A is connected with the scan output signal line through a fifty-fifth via. As shown in FIG. 28, the first connection line CL1 in FIG. 6A is connected with the scan output signal line through a fifty-fourth via.

In an exemplary implementation mode, as shown in FIG. 27, the first sub-initial power supply line INITL1A of the first initial power supply line and the fourth connection line CL4 in FIG. 5A are connected with the first signal connection line through a fifty-sixth via. As shown in FIG. 28, the first sub-initial power supply line INITL1A of the first initial power supply line and the fourth connection line CL4 in FIG. 6A are connected with the first signal connection line through a fifty-fifth via.

In an exemplary implementation mode, as shown in FIG. 27, the first sub-initial power supply line INITL2A of the second initial power supply line and the third connection line CL3 in FIG. 5A are connected with the second signal connection line through a fifty-seventh via. As shown in FIG. 28, the first sub-initial power supply line INITL2A of the second initial power supply line and the third connection line CL3 in FIG. 6A are connected with the second signal connection line through a fifty-sixth via.

In an exemplary implementation mode, as shown in FIGS. 46 and 47, the first electrode MT13 of the first transistor is in a shape of a strip extending along the second direction D2. As shown in FIGS. 48 and 49, the first electrode MT13 of the first transistor is in a shape of a strip extending along the first direction D1. As shown in FIGS. 46 to 49, the first electrode MT13 of the first transistor is electrically connected with the first region of the active layer of the first transistor through a fifty-eighth via, and is electrically connected with the first initial signal line through a sixty-fifth via.

In an exemplary implementation mode, as shown in FIGS. 46 to 49, the second electrode MT14 of the first transistor and the first electrode MT23 of the second transistor are of an integral structure and are in a shape of a strip extending along the first direction D1. The second electrode MT14 of the first transistor (also the first electrode MT23 of the second transistor) is electrically connected with the second region of the active layer of the first transistor (also the first region of the active layer of the second transistor) through a fifty-ninth via, and is electrically connected with the gate electrode of the third transistor (also the first electrode plate of the capacitor) through a sixty-fourth via.

In an exemplary implementation mode, as shown in FIGS. 46 to 49, the first electrode MT43 of the fourth transistor is in a shape of a block. The first electrode MT43 of the fourth transistor is electrically connected with the first region of the active layer of the fourth transistor through a sixtieth via.

In an exemplary implementation mode, as shown in FIGS. 46 and 47, the first electrode MT53 of the fifth transistor extends at least partially along the first direction D1. The first electrode MT53 of the fifth transistor is electrically connected with the first region of the active layer of the fifth transistor through a sixty-first via, and is electrically connected with the second electrode plate of the capacitor through a sixty-sixth via.

In an exemplary implementation mode, as shown in FIGS. 46 to 49, the second electrode MT64 of the sixth transistor and the first electrode MT74 of the seventh transistor are of an integral structure and in a shape of a block. The second electrode MT64 of the sixth transistor (also the first electrode MT74 of the seventh transistor) is electrically connected with the second region of the active layer of the sixth transistor (the second region of the active layer of the seventh transistor) through a sixty-second via.

In an exemplary implementation mode, as shown in FIGS. 46 to 49, the first electrode MT73 of the seventh transistor is in a shape of a strip extending along the first direction D1. The first electrode MT73 of the seventh transistor is electrically connected with the first region of the active layer of the seventh transistor through a sixty-third via, and is electrically connected with the second initial signal line through a sixty-seventh via.

In an exemplary implementation mode, as shown in FIGS. 46 and 49, the data connection line DL extends at least partially along the second direction D2 and may be located between the second electrode MT64 of the sixth transistor (also the first electrode MT74 of the seventh transistor) and the first electrode MT73 of the seventh transistor.

In an exemplary implementation mode, as shown in FIGS. 48 and 49, the first sub-power supply line VDDA is in a shape of a line extending at least partially along the first direction D1. A region where the first sub-power supply line VDDA is overlapped with the first region of the active layer of the fifth transistor is multiplexed as the first electrode MT53 of the fifth transistor. The first sub-power supply line VDDA is electrically connected with the first region of the active layer of the fifth transistor through a sixty-first via, and is electrically connected with the second electrode plate of the capacitor through a sixty-sixth via.

In an exemplary implementation mode, as shown in FIGS. 48 and 49, the electrode connection line CL is electrically connected with first electrodes MT73 of seventh transistors of adjacent sub-pixels located in a same column. First electrodes MT73 of seventh transistors of adjacent sub-pixels of at least one column of sub-pixels are disposed at intervals, and first electrodes MT73 of seventh transistors of adjacent sub-pixels of at least one column of sub-pixels are electrically connected through the electrode connection line CL. Among them, first electrodes MT73 of seventh transistors of adjacent sub-pixels of a j-th column of sub-pixels are disposed at intervals, and first electrodes MT73 of seventh transistors of adjacent sub-pixels of a (j+1)-th column of sub-pixels are electrically connected through the electrode connection line CL. The electrode connection line CL may form a mesh structure with a plurality of second initial signal lines, so that signals of second initial signal lines in each sub-pixel are consistent, and a display effect of the display substrate may be guaranteed.

In an exemplary implementation mode, as shown in FIGS. 48 and 49, when first electrodes MT73 of seventh transistors of adjacent sub-pixels located in a same column of sub-pixels are disposed at intervals, a virtual straight line extending along the first direction D1 through a first electrode MT73 of a seventh transistor passes through a second electrode MT64 of a sixth transistor (which is also a first electrode MT74 of a seventh transistor). When the first electrodes MT73 of the seventh transistors of adjacent sub-pixels located in a same column of sub-pixels are connected with each other, an orthographic projection of the electrode connection line CL on the base substrate is not overlapped with an orthographic projection of the second electrode MT64 of the sixth transistor (also the first electrode MT74 of the seventh transistor) on the base substrate.

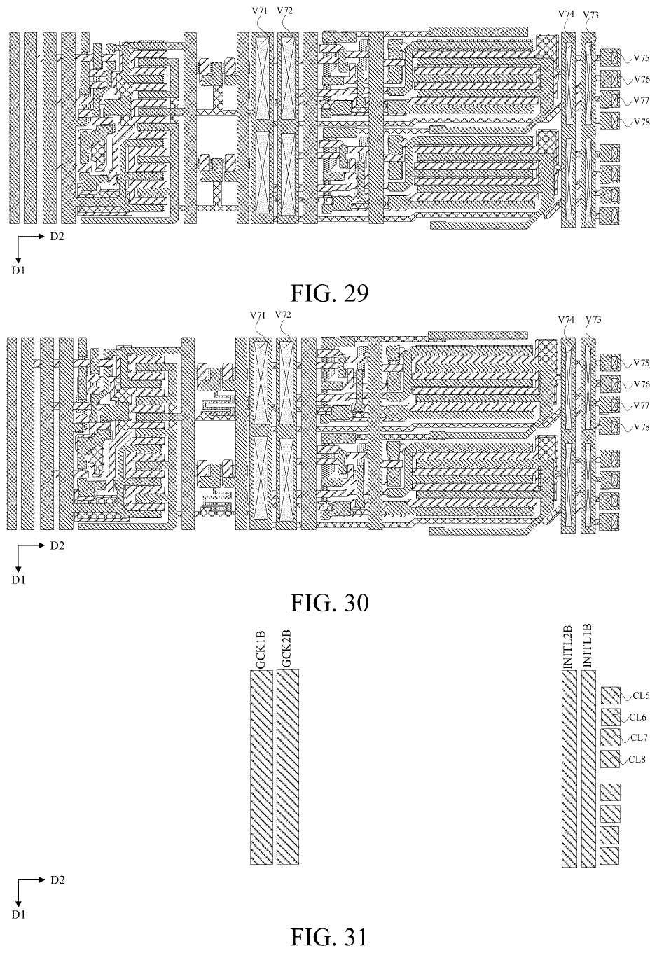

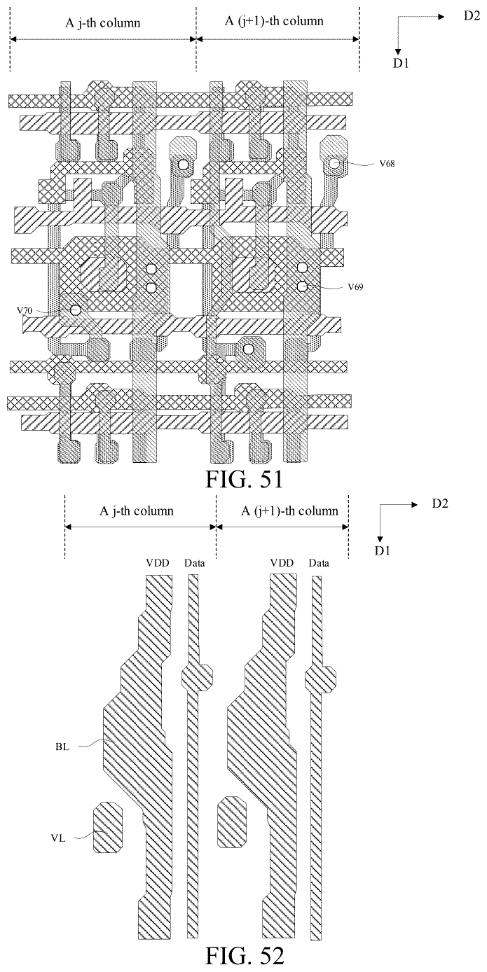

(7) Forming a pattern of a fourth insulation layer, includes: depositing a fourth insulation thin film on the base substrate on which the above-mentioned patterns are formed, coating a first planarization thin film, and patterning the fourth insulation thin film and the first planarization thin film through a patterning process to form a fourth insulation layer covering the above-mentioned structures and a pattern of a planarization layer disposed on the fourth insulation layer, wherein the planarization layer is provided with a groove and patterns of a plurality of via, as shown in FIGS. 29, 30, 50, and 51, FIG. 29 is a schematic diagram after a pattern of a planarization layer is formed in FIG. 5A, FIG. 30 is a schematic diagram after a pattern of a planarization layer is formed in FIG. 6A, FIG. 50 is a schematic diagram after a pattern of a planarization layer is formed in FIG. 7B, and FIG. 51 is a schematic diagram after a pattern of a planarization layer is formed in FIG. 7C.

In an exemplary implementation mode, as shown in FIGS. 29, 30, 50, and 51, the plurality of vias of the pattern of the planarization layer may include at least a seventy-first via V71, a seventy-second via V72, a seventy-third via V73, a seventy-fourth via V74, a seventy-fifth via V75, a seventy-sixth via V76, a seventy-seventh via V77, a seventy-eighth via V78, and a sixty-eighth via V68 to a seventieth via V70.

In an exemplary implementation mode, as shown in FIGS. 29 and 30, an orthographic projection of the seventy-first via V71 on the base substrate is within a range of an orthographic projection of the first sub-clock signal line of the first scan clock signal line on the base substrate, the fourth insulation layer within the seventy-first via V71 is etched away to expose the first sub-clock signal line of the first scan clock signal line, and the seventy-first via V71 is configured such that a second sub-clock signal line of a first scan clock signal line formed subsequently is connected with the first sub-clock signal line of the first scan clock signal line through the via.

In an exemplary implementation mode, as shown in FIGS. 29 and 30, an orthographic projection of the seventy-second via V72 on the base substrate is within a range of an orthographic projection of the third sub-clock signal line of the second scan clock signal line on the base substrate, the fourth insulation layer within the seventy-second via V72 is etched away to expose the third sub-clock signal line of the second scan clock signal line, and the seventy-second via V72 is configured such that a fourth sub-clock signal line of a second scan clock signal line formed subsequently is connected with the third sub-clock signal line of the second scan clock signal line through the via.

In an exemplary implementation mode, as shown in FIGS. 29 and 30, an orthographic projection of the seventy-third via V73 on the base substrate is within an orthographic projection of the first sub-initial power supply line of the first initial power supply line on the base substrate, the fourth insulation layer within the seventy-third via V73 is etched away to expose the first sub-initial power supply line of the first initial power supply line, and the seventy-third via V73 is configured such that a second sub-initial power supply line of a first initial power supply line formed subsequently is connected with the first sub-initial power supply line of the first initial power supply line through the via.

In an exemplary implementation mode, as shown in FIGS. 29 and 30, an orthographic projection of the seventy-fourth via V74 on the base substrate is within a range of an orthographic projection of the first sub-initial power supply line of the second initial power supply line on the base substrate, to expose the first sub-initial power supply line of the second initial power supply line, and the seventy-fourth via V74 is configured such that a second sub-initial power supply line of a second initial power supply line formed subsequently is connected with the first sub-initial power supply line of the second initial power supply line through the via.

In an exemplary implementation mode, as shown in FIGS. 29 and 30, an orthographic projection of the seventy-fifth via V75 on the base substrate is within a range of an orthographic projection of the first connection line on the base substrate, the fourth insulation layer within the seventy-fifth via V75 is etched away to expose the first connection line, and the seventy-fifth via V75 is configured such that a fifth connection line formed subsequently is connected with the first connection line through the via.

In an exemplary implementation mode, as shown in FIGS. 29 and 30, an orthographic projection of the seventy-sixth via V76 on the base substrate is within a range of an orthographic projection of the second connection line on the base substrate, the fourth insulation layer within the seventy-sixth via V76 is etched away to expose the second connection line, and the seventy-sixth via V76 is configured such that a sixth connection line formed subsequently is connected with the second connection line through the via.

In an exemplary implementation mode, as shown in FIGS. 29 and 30, an orthographic projection of the seventy-seventh via V77 on the base substrate is within a range of an orthographic projection of the third connection line on the base substrate, the fourth insulation layer within the seventy-seventh via V77 is etched away to expose the first connection line, and the seventy-seventh via V77 is configured such that a seventh connection line formed subsequently is connected with the third connection line through the via.

In an exemplary implementation mode, as shown in FIGS. 29 and 30, an orthographic projection of the seventy-eighth via V78 on the base substrate is within a range of an orthographic projection of the fourth connection line on the base substrate, the fourth insulation layer within the seventy-eighth via V78 is etched away to expose the fourth connection line, and the seventy-eighth via V78 is configured such that an eighth connection line formed subsequently is connected with the fourth connection line through the via.

In an exemplary implementation mode, as shown in FIGS. 50 and 51, an orthographic projection of the sixty-eighth via V68 on the base substrate is within a range of an orthographic projection of a first electrode of the fourth transistor on the base substrate, to expose the first electrode of the fourth transistor, and the sixty-eighth via V68 is configured such that a data signal line formed subsequently is connected with the first electrode of the fourth transistor through the via.

In an exemplary implementation mode, as shown in FIG. 50, an orthographic projection of the sixty-ninth via V69 on the base substrate is within a range of an orthographic projection of a first electrode of the fifth transistor on the base substrate, to expose the first electrode of the fifth transistor, and the sixty-ninth via V69 is configured such that a first power supply line formed subsequently is connected with the first electrode of the fifth transistor through the via.

In an exemplary implementation mode, as shown in FIG. 51, an orthographic projection of the sixty-ninth via V69 on the base substrate is within a range of an orthographic projection of the first sub-power supply line on the base substrate, to expose the first sub-power supply line, and the sixty-ninth via V69 is configured such that a second sub-power supply line formed subsequently is connected with the first sub-power supply line through the via.

In an exemplary implementation mode, as shown in FIGS. 50 and 51, an orthographic projection of the seventieth via V70 on the base substrate is located within a range of an orthographic projection of a second electrode of the sixth transistor (also a second electrode of the seventh transistor) on the base substrate, to expose the second electrode of the sixth transistor (also the second electrode of the seventh transistor), and the seventieth via V70 is configured such that an anode connection electrode formed subsequently is connected with the second electrode of the sixth transistor (also the second electrode of the seventh transistor) through the via.

In an exemplary implementation mode, a fourth insulation layer is disposed in FIG. 5A and FIG. 6A, but the fourth insulation layer disposed in FIGS. 5A and 6A has no via.

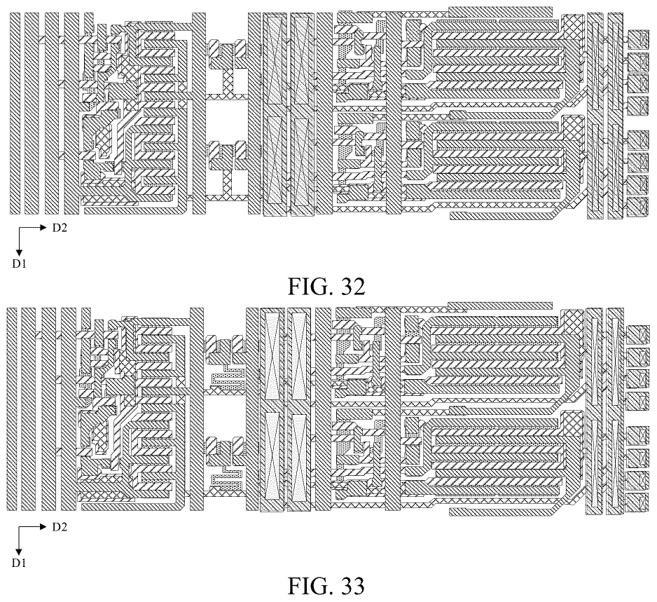

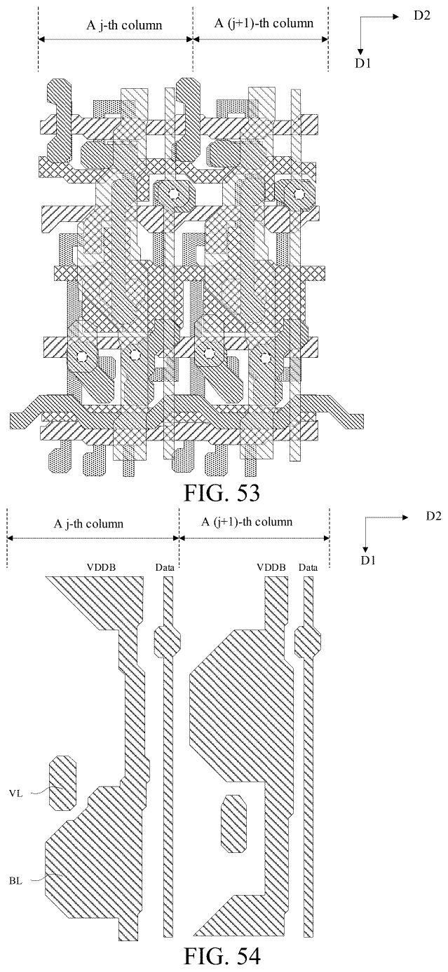

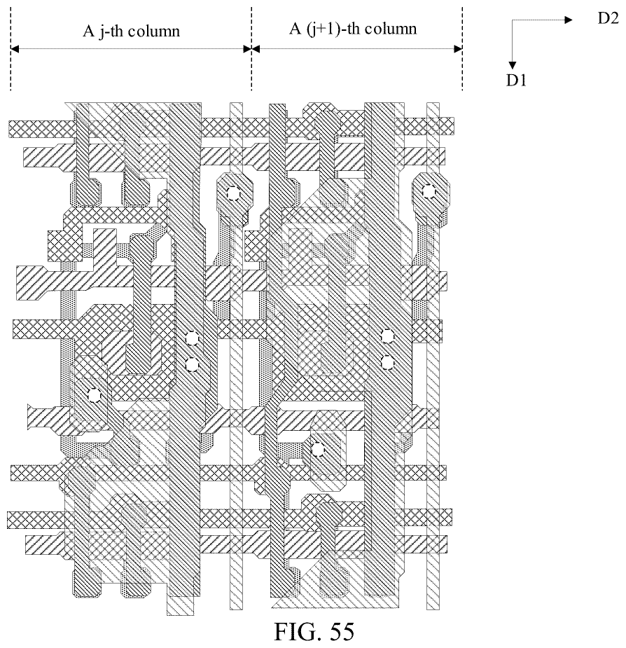

(8) Forming a pattern of a fourth conductive layer, includes: depositing a fourth conductive thin film on the base substrate on which the above-mentioned patterns are formed, and patterning the fourth conductive thin film through a patterning process to form a pattern of a fourth conductive layer, as shown in FIGS. 31, 32, 33, and 52 to 55, FIG. 31 is a schematic diagram of a pattern of a fourth conductive layer in FIG. 5A and FIG. 6A, FIG. 32 is a schematic diagram after the pattern of the fourth conductive layer is formed in FIG. 5A, FIG. 33 is a schematic diagram after the pattern of the fourth conductive layer is formed in FIG. 6A, FIG. 52 is a schematic diagram of a pattern of a fourth conductive layer in FIG. 7B, FIG. 53 is a schematic diagram after the pattern of the fourth conductive layer is formed in FIG. 7B, FIG. 54 is a schematic diagram after a pattern of a fourth conductive layer is formed in FIG. 7C, and FIG. 55 is a schematic diagram after the pattern of the fourth conductive layer is formed in FIG. 7C. In an exemplary implementation mode, the fourth conductive layer may be referred to as a second source-drain metal (SD2) layer.

In an exemplary implementation mode, as shown in FIGS. 31 to 33, the pattern of the fourth conductive layer may include at least a second sub-clock signal line GCK1B of the first scan clock signal line, a fourth sub-clock signal line GCK2B of the second scan clock signal line, a second sub-initial power supply line INITL1B of the first initial power supply line, a second sub-initial power supply line INITL2B of the second initial power supply line, a fifth connection line CL5, a sixth connection line CL6, a seventh connection line CL7, and an eighth connection line CL8.

In an exemplary implementation mode, the second sub-clock signal line GCK1B of the first scan clock signal line is in a shape of a line in the first direction D1. The second sub-clock signal line of the first scan clock signal line is connected with the first sub-clock signal line of the first scan clock signal line through the seventy-first via.

In an exemplary implementation mode, an orthographic projection of the second sub-clock signal line GCK1B of the first scan clock signal line on the base substrate is at least partially overlapped with an orthographic projection of the first sub-clock signal line of the first scan clock signal line on the base substrate.

In an exemplary implementation mode, the fourth sub-clock signal line GCK2B of the second scan clock signal line is in a shape of a line in the first direction D1. The fourth sub-clock signal line of the second scan clock signal line is connected with the third sub-clock signal line of the second scan clock signal line through the seventy-second via.

In an exemplary implementation mode, an orthographic projection of the fourth sub-clock signal line GCK2B of the second scan clock signal line on the base substrate is at least partially overlapped with an orthographic projection of the third sub-clock signal line of the second scan clock signal line on the base substrate.

In an exemplary implementation mode, the second sub-initial power supply line of the first initial power supply line is in a shape of a line in the first direction D1. The second sub-initial power supply line of the first initial power supply line is connected with the first sub-initial power supply line of the first initial power supply line through the seventy-third via.

In an exemplary implementation mode, an orthographic projection of the second sub-initial power supply line of the first initial power supply line on the base substrate is at least partially overlapped with an orthographic projection of the first sub-initial power supply line of the first initial power supply line on the base substrate.

In an exemplary implementation mode, the second sub-initial power supply line of the second initial power supply line is in a shape of a line in the first direction D1. The second sub-initial power supply line of the second initial power supply line is connected with the first sub-initial power supply line of the second initial power supply line through the seventy-fourth via.

In an exemplary implementation mode, an orthographic projection of the second sub-initial power supply line of the second initial power supply line on the base substrate is at least partially overlapped with an orthographic projection of the first sub-initial power supply line of the second initial power supply line on the base substrate.

In an exemplary implementation mode, the fifth connection line CL5 may be in a shape of a block. The fifth connection line CL5 is connected with the first connection line through the seventy-fifth via.

In an exemplary implementation mode, the sixth connection line CL6 may be in a shape of a block. The sixth connection line CL6 is connected with the second connection line through the seventy-sixth via.

In an exemplary implementation mode, the seventh connection line CL7 may be in a shape of a block. The seventh connection line CL7 is connected with the third connection line through the seventy-seventh via.

In an exemplary implementation mode, the eighth connection line CL8 may be in a shape of a block. The eighth connection line CL8 is connected with the fourth connection line through the seventy-eighth via.

In an exemplary implementation mode, as shown in FIGS. 52 to 55, the pattern of the fourth conductive layer may at least include a data signal line Data, an anode connection electrode VL, and a planarization portion BL.

In an exemplary implementation mode, as shown in FIGS. 52 and 53, the pattern of the fourth conductive layer may further include a first power supply line VDD.

In an exemplary implementation mode, as shown in FIGS. 54 and 55, the pattern of the fourth conductive layer may further include a second sub-power supply line VDDB. The second sub-power supply line VDDB and the first sub-power supply line constitute the first power supply line.

In an exemplary implementation mode, as shown in FIGS. 52 to 55, the data signal line Data extends along the first direction D1. The data signal line Data is electrically connected with the first electrode of the fourth transistor through the sixty-eighth via.

In an exemplary implementation mode, as shown in FIGS. 52 to 55, the anode connection electrode VL extends along the first direction D1. The anode connection electrode VL is electrically connected with the second electrode of the sixth transistor (also the first electrode of the seventh transistor) through the seventieth via.

In an exemplary implementation mode, as shown in FIGS. 52 and 53, the planarization portion BL and the first power supply line VDD are of an integral structure. An orthographic projection of the planarization portion BL on the base substrate is at least partially overlapped with an orthographic projection of an anode of a light emitting device on the base substrate.

In an exemplary implementation mode, as shown in FIGS. 54 and 55, the planarization portion BL and the second sub-power supply line VDDB are of an integral structure. An orthographic projection of the planarization portion BL on the base substrate is at least partially overlapped with an orthographic projection of an anode of a light emitting device on the base substrate.

In an exemplary implementation mode, as shown in FIGS. 52 and 53, the first power supply line VDD extends along the first direction D1. The first power supply line VDD is electrically connected with the first electrode of the fifth transistor through the sixty-ninth via.

In an exemplary implementation mode, as shown in FIGS. 52 and 53, the second sub-power supply line VDD extends along the first direction D1. The second sub-power supply line VDD is electrically connected with the first sub-power supply line through the sixty-ninth via.

(9) Forming a pattern of a sixth insulation layer. In an exemplary implementation mode, forming a planarization layer may include depositing a fifth insulation thin film and a fifth conductive thin film on the base substrate on which the above-mentioned patterns are formed, patterning the fifth conductive thin film using a patterning process to form a fifth insulation layer and a fifth conductive layer disposed on the fifth insulation layer, depositing a sixth insulation thin film on the base substrate on which the above-mentioned patterns are formed, and patterning the sixth insulation thin film using a patterning process to form a sixth insulation layer covering the pattern of the fifth conductive layer.

In an exemplary implementation mode, the fifth conductive layer may include an anode connection line.

So far, preparation of a drive structure layer is completed on the base substrate. In a plane parallel to the display substrate, the drive structure layer may include the semiconductor layer, the first insulation layer, the first conductive layer, the second insulation layer, the second conductive layer, the third insulation layer, the third conductive layer, the fourth insulation layer, the planarization layer, the fourth conductive layer, the fifth insulation layer, the fifth conductive layer, and the sixth insulation layer sequentially disposed on the base substrate.

In an exemplary implementation mode, the semiconductor layer may be a metal oxide layer. For the metal oxide layer, an oxide containing indium and tin, an oxide containing tungsten and indium, an oxide containing tungsten and indium and zinc, an oxide containing titanium and indium, an oxide containing titanium and indium and tin, an oxide containing indium and zinc, an oxide containing silicon and indium and tin, or an oxide containing indium or gallium and zinc, may be adopted. The metal oxide layer may be a single layer, a double-layer, or a multi-layer. An active layer thin film may be made of an amorphous Indium Gallium Zinc Oxide (a-IGZO), Zinc OxyNitride (ZnON), Indium Zinc Tin Oxide (IZTO), amorphous Silicon (a-Si), polycrystalline Silicon (p-Si), hexathiophene, polythiophene, and other materials, that is, the present disclosure is applicable to transistors manufactured based on an oxide technology, a silicon technology, and an organic matter technology.

In an exemplary implementation mode, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary implementation mode, the fifth conductive layer may be made of an Indium Tin Oxide (ITO) or Indium Zinc Oxide (IZO) material.

In an exemplary implementation mode, the first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon OxyNitride (SiON), and may be a single layer, a multi-layer, or a composite layer. The first insulation layer and the second insulation layer may be referred to as Gate Insulation (GI) layers, and the third insulation layer may be referred to as an Interlayer Dielectric (ILD) layer.

In an exemplary implementation, the planarization layer may be made of an organic material, such as resin.

In an exemplary implementation mode, after preparation of the drive structure layer is completed, a light emitting structure layer is prepared on the drive structure layer, and a preparation process of the light emitting structure layer may include following operations.

A light emitting structure layer is formed. In an exemplary implementation mode, forming a light emitting structure layer may include: depositing an anode conductive thin film on the above-mentioned patterns that are formed; patterning the anode conductive thin film using a patterning process to form an anode conductive layer disposed on the planarization layer, wherein the anode conductive layer includes at least patterns of a plurality of anodes; coating a pixel definition thin film on the base substrate on which the above-mentioned patterns are formed, patterning the pixel definition thin film using a patterning process to form a pixel definition layer; and on the base substrate on which the above-mentioned patterns are formed, forming an organic emitting layer using an evaporation process or inkjet printing process at first, then forming a cathode on the organic emitting layer, and then forming an encapsulation structure layer.

In an exemplary implementation mode, the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is disposed between the first encapsulation layer and the third encapsulation layer, which may be ensured that external water vapor cannot enter the light emitting structure layer.

In an exemplary implementation mode, a material of the pixel definition layer may include polyimide, acrylic, or polyethylene terephthalate.

In an exemplary implementation mode, an anode thin film may be made of Indium Tin Oxide (ITO) or Indium Zinc Oxide (IZO).

In an exemplary implementation mode, a cathode thin film may be made of any one or more of Magnesium (Mg), Argentum (Ag), Aluminum (Al), Copper (Cu), and Lithium (Li), or an alloy made of any one or more of the above metals.

The electrostatic release circuit in the present disclosure is formed using a same process as the gate drive circuit, which may ensure reliability of the display substrate without increasing fabrication procedure of processes.

An embodiment of the present disclosure also provides a display apparatus which may include a display substrate and a photosensitive sensor. The photosensitive sensor is located in the display substrate.

The display substrate is the display substrate according to any of the aforementioned embodiments, and has similar implementation principles and implementation effects, which will not be repeated here.

In an exemplary implementation mode, the display apparatus may be a Liquid Crystal Display (LCD for short) or an Organic Light Emitting Diode (OLED for short) display apparatus. The display apparatus may be any product or component with a display function, such as a liquid crystal panel, electronic paper, an OLED panel, an Active-Matrix Organic Light Emitting Diode (AMOLED for short) panel, a mobile phone, a tablet computer, a television, a display, a notebook computer, a digital photo frame, or a navigator.

The drawings of the embodiments of the present disclosure only involve structures involved in the embodiments of the present disclosure, and other structures may be referred to general designs.

For the sake of clarity, a thickness and a size of a layer or a micro structure are enlarged in the accompanying drawings used for describing the embodiments of the present disclosure. It may be understood that when an element such as a layer, film, region, or substrate is described as being “on” or “under” another element, the element may be “directly” located “on” or “under” the another element, or there may be an intermediate element.

Although implementation modes of the present disclosure are disclosed above, contents described are only implementation modes used for ease of understanding of the present disclosure, but not intended to limit the present disclosure. Any person skilled in the art to which the present disclosure belongs may make any modification and variation in forms and details of implementation without departing from the spirit and scope of the present disclosure. However, the patent protection scope of the present disclosure should still be subject to the scope defined in the appended claims.

1. A display substrate, comprising a base substrate and a drive structure layer disposed on the base substrate, wherein the base substrate comprises a display region and a non-display region, the drive structure layer comprises a plurality of pixel circuits located in the display region, and a gate drive circuit and an electrostatic release circuit located in the non-display region, the gate drive circuit comprises a plurality of drive circuits, and the plurality of drive circuits and the electrostatic release circuit are arranged along a direction close to the display region;
the electrostatic release circuit is disposed between two adjacent drive circuits and is electrically connected with at least one signal line of any one of the two adjacent drive circuits.

2. The display substrate according to claim 1, wherein the electrostatic release circuit comprises at least a first release transistor and a second release transistor;
a gate electrode and a second electrode of the first release transistor are connected with a first signal terminal, and a first electrode of the first release transistor is connected with a second signal terminal;
a gate electrode and a first electrode of the second release transistor are connected with a third signal terminal, and a second electrode of the second release transistor is connected with the first signal terminal.

3. The display substrate according to claim 2, wherein the plurality of drive circuits comprise: a light emitting drive circuit and a scan drive circuit, wherein the scan drive circuit is located at a side of the light emitting drive circuit close to the display region;
the drive structure layer further comprises: a light emitting initial signal line, a first light emitting clock signal line, a second light emitting clock signal line, a first light emitting power supply line, a second light emitting power supply line, a scan initial signal line, a first scan clock signal line, a second scan clock signal line, a first scan power supply line, and a second scan power supply line located in the non-display region; any one of the light emitting initial signal line, the first light emitting clock signal line, the second light emitting clock signal line, the first light emitting power supply line, the second light emitting power supply line, the scan initial signal line, the first scan clock signal line, the second scan clock signal line, the first scan power supply line, and the second scan power supply line extending along a first direction;
the light emitting drive circuit is electrically connected with the light emitting initial signal line, the first light emitting clock signal line, the second light emitting clock signal line, the first light emitting power supply line, and the second light emitting power supply line, respectively; the scan drive circuit is electrically connected with the scan initial signal line, the second scan clock signal line, the first scan clock signal line, the first scan power supply line, and the second scan power supply line, respectively;
the light emitting initial signal line, the first light emitting clock signal line, the second light emitting clock signal line, the first light emitting power supply line, the second light emitting power supply line, the first scan power supply line, the first scan clock signal line, the second scan clock signal line, the scan initial signal line, and the second scan power supply line are sequentially arranged along a direction close to the display region.

4. The display substrate according to claim 3, wherein an orthographic projection of the electrostatic release circuit on the base substrate is partially overlapped with the first scan power supply line and the second light emitting power supply line, and at least a portion of the electrostatic release circuit is located between the second light emitting power supply line and the first scan power supply line.

5. The display substrate according to claim 4, wherein the drive structure layer further comprises: a light emitting output signal line and a scan output signal line located in the non-display region, and a light emitting signal line and a scan signal line at least partially located in the display region; any one of the scan output signal line, the light emitting signal line, and the scan signal line at least partially extends along a second direction, the first direction intersecting with the second direction; a pixel circuit is respectively connected with the light emitting signal line and the scan signal line;
the light emitting drive circuit comprises a plurality of cascaded light emitting shift registers, and the scan drive circuit comprises a plurality of cascaded scan shift registers;
the light emitting output signal line is electrically connected with a light emitting shift register and at least one light emitting signal line, respectively;
the scan output signal line is electrically connected with a scan shift register and the scan signal line respectively.

6. The display substrate according to claim 5, wherein a first signal terminal of the electrostatic release circuit is electrically connected with the light emitting output signal line, a second signal terminal of the electrostatic release circuit is electrically connected with the second light emitting power supply line, and a third signal terminal of the electrostatic release circuit is electrically connected with the first scan power supply line.

7. The display substrate according to claim 3, wherein a distance between the second light emitting power supply line and the first scan power supply line is about 8 microns to 15 microns.

8. The display substrate according to claim 6, wherein the light emitting shift register comprises a plurality of light emitting transistors and a plurality of light emitting capacitors, the scan shift register comprises a plurality of scan transistors and a plurality of scan capacitors, the light emitting capacitors and the scan capacitors each comprises a first electrode plate and a second electrode plate, the drive structure layer comprises a semiconductor layer, a first conductive layer, a second conductive layer, a third conductive layer, and a fourth conductive layer sequentially stacked, the first scan clock signal line comprises a first sub-clock signal line and a second sub-clock signal line electrically connected with each other, the second scan clock signal line comprises a third sub-clock signal line and a fourth sub-clock signal line electrically connected with each other;
the semiconductor layer at least comprises: active layers of the plurality of light emitting transistors, active layers of the plurality of scan transistors, an active layer of the first release transistor, and an active layer of the second release transistor;
the first conductive layer at least comprises: a light emitting signal line, a scan signal line, gate electrodes of the plurality of light emitting transistors, first electrode plates of the plurality of light emitting capacitors, gate electrodes of the plurality of scan transistors, first electrode plates of the plurality of scan capacitors, a gate electrode of the first release transistor, and a gate electrode of the second release transistor;
the second conductive layer at least comprises: second electrode plates of the plurality of light emitting capacitors, second electrode plates of the plurality of scan capacitors, the scan output signal line, and the light emitting output signal line;
the third conductive layer at least comprises: the light emitting initial signal line, the first light emitting clock signal line, the second light emitting clock signal line, the first light emitting power supply line, the second light emitting power supply line, the scan initial signal line, the first sub-clock signal line of the first scan clock signal line, the third sub-clock signal line of the second scan clock signal line, the first scan power supply line, the second scan power supply line, first electrodes and second electrodes of the plurality of light emitting transistors, first electrodes and second electrodes of the plurality of scan transistors, the first electrode and the second electrode of the first release transistor, and the first electrode and the second electrode of the second release transistor;
the fourth conductive layer comprises at least the second sub-clock signal line of the first scan clock signal line and the fourth sub-clock signal line of the second scan clock signal line.

9. The display substrate according to claim 8, wherein the first electrodes and second electrodes of the plurality of light emitting transistors are located between the first light emitting power supply line and the second light emitting power supply line, the first electrode and the second electrode of the first release transistor to the first electrode and the second electrode of the second release transistor are located between the second light emitting power supply line and the first scan power supply line, first electrodes and second electrodes of one portion of the scan transistors are located between the scan initial signal line and the second scan power supply line, and first electrodes and second electrodes of the other portion of the scan transistors may be located at a side of the second scan power supply line close to the display region.

10. The display substrate according to claim 8, wherein at least one light emitting output signal line comprises an output connection portion extending along the first direction and at least one output line arranged along the first direction;
the output connection portion is respectively electrically connected with the light emitting shift register and at least one output line, and the output line is in one-to-one correspondence with a light emitting signal line connected with the light emitting output signal line, and is electrically connected with the corresponding light emitting signal line.

11. The display substrate according to claim 10, wherein the output line comprises an output main body portion at least partially extending along the second direction and an output connection portion extending along the first direction, the output main body portion is electrically connected with the output connection portion;
the second electrode of the first release transistor and the second electrode of the second release transistor are of an integral structure, and an orthographic projection thereof on the base substrate is at least partially overlapped with an orthographic projection of the output connection portion on the base substrate; the integral structure of the second electrode of the first release transistor and the second electrode of the second release transistor is electrically connected with the output connection portion.

12. The display substrate according to claim 11, wherein the active layer of the first release transistor and the active layer of the second release transistor are of an integral structure and extend along the second direction;
the orthographic projection of the output connection portion on the base substrate is not overlapped with an orthographic projection of the integral structure of the active layer of the first release transistor and the active layer of the second release transistor on the base substrate.

13. The display substrate according to claim 10, wherein the active layer of the first release transistor and the active layer of the second release transistor are of an integral structure, and comprise an active main body portion and an active connection portion, the active main body portion and the active connection portion are electrically connected, and the active main body portion and the active connection portion are arranged along the first direction;
the active main body portion extends along the second direction, and the active connection portion at least partially extends along the first direction;
the active connection portion is in a shape of a polyline.

14. The display substrate according to claim 13, wherein the output line at least partially extends along the second direction; the second electrode of the first release transistor and the second electrode of the second release transistor are of an integral structure;
an orthographic projection of the active connection portion on the base substrate is at least partially overlapped with orthographic projections of the integral structure of the second electrode of the first release transistor and the second electrode of the second release transistor and the output line on the base substrate, and the active connection portion is electrically connected with the integral structure of the second electrode of the first release transistor and the second electrode of the second release transistor and the output line, respectively.

15. (canceled)

16. The display substrate according to claim 8, wherein the scan shift register comprises a first scan capacitor, a second electrode plate of the first scan capacitor is electrically connected with the first scan power supply line, and the second electrode plate of the first scan capacitor extends along the second direction;
an orthographic projection of the second electrode plate of the first scan capacitor on the base substrate is at least partially overlapped with orthographic projections of the first scan power supply line, the second scan power supply line, the first scan clock signal line, the second scan clock signal line, and the scan initial signal line on the base substrate.

17. The display substrate according to claim 1, wherein the display region comprises a first display region and a second display region located on at least one side of the first display region, wherein the display substrate further comprises a light emitting device and an anode connection line located in the display region, a pixel circuit is electrically connected with the light emitting device; the pixel circuit comprises: a first pixel circuit and a second pixel circuit located in the second display region, the light emitting device comprises: a first light emitting device located in the first display region and a second light emitting device located in the second display region, the first pixel circuit is electrically connected with the first light emitting device, and the second pixel circuit is electrically connected with the second light emitting device;
an orthographic projection of the first pixel circuit on the base substrate is at least partially overlapped with an orthographic projection of the first light emitting device with which the first pixel circuit is connected on the base substrate;
the anode connection line is electrically connected with the second light emitting device and the second pixel circuit with which the second light emitting device is connected, respectively.

18. The display substrate according to claim 17, wherein the drive structure layer further comprises: a first power supply line, a data signal line, and a data connection line at least partially located in the display region; the first power supply line and the data signal line at least partially extend along a first direction, and the data connection line at least partially extends along a second direction;
the drive structure layer further comprises: a fourth conductive layer and a fifth conductive layer stacked on a third conductive layer sequentially;
the third conductive layer at least comprises: the data connection line;
the fourth conductive layer at least comprises: the first power supply line and the data signal line;
the fifth conductive layer at least comprises: the anode connection line;
the fifth conductive layer is a transparent conductive layer.

19. The display substrate according to claim 18, wherein the drive structure layer further comprises a planarization layer located between the third conductive layer and the fourth conductive layer, the planarization layer is provided with a groove;
an orthographic projection of the electrostatic release circuit on the base substrate is at least partially overlapped with an orthographic projection of the groove on the base substrate.

20. The display substrate according to claim 19, wherein the drive structure layer further comprises at least one initial power supply line located in the non-display region and at least one initial signal line at least partially located in the display region; the initial power supply line is located at a side of a scan drive circuit close to the display region, the initial power supply line at least partially extends along the first direction, and the initial signal line at least partially extends along the second direction; the initial power supply line comprises a first sub-initial power supply line and a second sub-initial power supply line electrically connected with each other;
the at least one initial signal line is in one-to-one correspondence with the at least one initial power supply line, and the initial signal line is electrically connected with the pixel circuit and the corresponding initial power supply line, respectively;
the second conductive layer at least comprises: the initial signal line;
the third conductive layer at least comprises: the first sub-initial power supply line of the initial power supply line;
the fourth conductive layer at least comprises: the second sub-initial power supply line of the initial power supply line.

21. A display apparatus, comprising a display substrate according to claim 1 and a photosensitive sensor, wherein the photosensitive sensor is located within the display substrate.
